(19) United States
(12) Patent Application Publication
(10) Pub. No.: US 2026/0310838 A1
(43) Pub. Date: Oct. 8, 2026

(54) AUTOMATED PLUMBING CODE COMPLIANCE ANALYSIS WITH INTERACTIVE USER INPUT

(71) Applicant: CodeComply.Ai, Corp., Miami, FL (US)

(72) Inventors: Michael Sheehan, Coral Gables, FL (US); Matthew Foley, Boxborough, MA (US); Patrick E Murphy, Miami, FL (US); Johnny Maghzal, Miami, FL (US)

(73) Assignee: CodeComply.Ai, Corp., Miami, FL (US)

(21) Appl. No.: 19/480,318

(22) PCT Filed: Aug. 30, 2024
(86) PCT No.: PCT/US2024/044868

§ 371 Date: Oct. 30, 2025

Related U.S. Application Data
(60) Provisional application No. 63/535,699, filed on Aug. 31, 2023.

(51) Int. Cl. G06F 30/13; G06Q 30/018

(52) U.S. Cl. CPC G06F 30/13; G06Q 30/018

(57) ABSTRACT

Methods and apparatus are provided for automated analysis and verification of plumbing code compliance in architectural design plans using artificial intelligence (AI). The system analyzes design plans, such as floor plans or architectural drawings, to identify, classify, and evaluate the placement, type, and number of plumbing fixtures, including water closets, sinks, and showers. The AI engine assesses these fixtures against applicable building and plumbing codes, evaluating spatial relationships, clearances, and pipe configurations. Where non-compliance is detected, the system offers automated suggestions for design revisions and optimizations, providing code adherence and functional efficiency before construction begins. The apparatus includes interactive tools for real-time simulation and collaboration, enabling designers, architects, and code compliance officers to make informed adjustments to the design.

### CROSS REFERENCE TO RELATED APPLICATIONS

This application is a National Stage of International Application Number PCT/US24/44868, filed Aug. 30, 2024, which claims the benefit of and priority to U.S. Provisional Application No. 63/535,699 filed Aug. 31, 2023, the entire disclosures of each of which are incorporated herein by reference.

### FIELD OF THE INVENTION

The present invention provides improved methods and apparatus for determining compliance with building codes relating to plumbing fixture placement, counts, and associated spatial requirements. More specifically, the present invention provides methods and apparatus that analyze two-dimensional references (design plans) using artificial intelligence (AI) to automatically ascertain a placement, type, and number of plumbing fixtures. It further evaluates fixture presence against relevant building and plumbing codes to determine if the design plans meet the required standards. The invention also provides automated suggestions for revisions and optimizations to address any identified non-compliance issues, so that the final design is code-compliant and functionally efficient.

### BACKGROUND OF THE INVENTION

The regulation of plumbing systems in buildings is governed by a complex framework of codes and standards designed to protect public health, safety, and welfare. These codes, particularly those in the United States, have evolved over time in response to the growing recognition of the risks associated with improper plumbing design, installation, and maintenance. The plumbing codes provide a comprehensive set of rules that dictate how plumbing systems should be designed, constructed, and maintained within a building. These rules encompass a wide range of aspects, including water supply, sewage disposal, drainage, venting, and the installation of plumbing fixtures. The primary goal of these regulations is to prevent the occurrence of issues such as backflow, contamination of drinking water, inadequate drainage, and the malfunctioning of plumbing fixtures, all of which can have serious consequences for building occupants.

In the United States, the most widely adopted plumbing codes include the International Plumbing Code (IPC) and the Uniform Plumbing Code (UPC). These codes provide detailed guidelines on various aspects of plumbing design, such as the materials that can be used for pipes, the proper sizing of pipes, the required slope for drainage pipes, and the installation of backflow prevention devices. While the IPC is commonly used in many states across the country, the UPC is often preferred in states on the West Coast and in some other regions. These codes are periodically updated to reflect new technologies, materials, and methods in plumbing, as well as to address emerging public health concerns. In addition to these codes, local jurisdictions may have their own plumbing regulations that supplement or modify the national codes to address specific regional issues, such as seismic activity or local water quality concerns.

Internationally, plumbing regulations vary widely from one country to another, depending on factors such as climate, cultural practices, and the availability of water and sanitation infrastructure. For example, the European Union has its own set of plumbing standards, which are largely harmonized across member states but allow for some variation at the national level. In India, the Uniform Illustrated Plumbing Code-India (UIPC-I) serves as the primary reference for plumbing practices, providing guidance on everything from water supply and drainage systems to the installation of sanitary fixtures. In many developing countries, however, plumbing regulations may be less stringent or less consistently enforced, leading to a higher incidence of non-compliant plumbing installations that pose risks to public health.

The need for plumbing compliance arises from the potential hazards associated with non-compliant plumbing systems. For example, if a building's water supply system is not properly designed or maintained, there is a risk of backflow, where contaminated water flows back into the potable water supply, leading to the spread of waterborne diseases. Similarly, inadequate drainage can result in the accumulation of wastewater, which can create unsanitary conditions and attract pests. The improper installation of plumbing fixtures, such as toilets, sinks, and showers, can lead to leaks, water damage, and mold growth, which not only compromise the structural integrity of a building but also pose health risks to occupants. In extreme cases, non-compliant plumbing can result in catastrophic failures, such as the bursting of pipes, which can cause significant property damage and even loss of life.

Examples of compliant plumbing installations include the use of backflow prevention devices to protect the potable water supply, the installation of properly sized and sloped drainage pipes to facilitate the efficient removal of wastewater, and the use of approved materials for pipes and fixtures that meet the required standards for durability, safety, and hygiene. In contrast, non-compliant plumbing installations involve the use of substandard materials that are prone to corrosion or leaks, the installation of improperly sized pipes that restrict water flow or lead to blockages, or the absence of necessary ventilation, which can result in sewer gases entering the building. These issues are often exacerbated by the lack of regular maintenance, leading to the gradual deterioration of the plumbing system over time.

The consequences of non-compliant plumbing can be severe, affecting not only the occupants of a building but also the wider community. For example, in areas where the water supply is limited or contaminated, non-compliant plumbing systems can exacerbate the problem by contributing to water wastage or the spread of contaminants. In addition, the presence of non-compliant plumbing in a building can lead to costly repairs and renovations, as well as legal liabilities for property owners and contractors. In some cases, buildings with significant plumbing deficiencies may be deemed uninhabitable, resulting in the displacement of occupants and the loss of property value. Furthermore, non-compliant plumbing can have environmental impacts, such as the contamination of groundwater or the release of untreated sewage into natural water bodies, which can harm wildlife and ecosystems.

Traditionally, the determination of plumbing compliance has been a manual process carried out by engineers, architects, and building inspectors. This process involves a detailed review of the design plans and specifications for a building's plumbing system, followed by on-site inspections during and after construction to verify that the installation meets the required standards. This manual approach relies heavily on the expertise and experience of the professionals involved, who must be familiar with the relevant codes and standards, as well as the specific requirements of the project. They must also be able to identify potential issues and recommend corrective actions to bring the plumbing system into compliance.

However, the manual determination of plumbing compliance has several limitations. First, it is time-consuming, as it requires a thorough examination of all aspects of the plumbing system, including the water supply, drainage, venting, and the installation of fixtures. This process can be particularly challenging in large or complex buildings, where the plumbing system may involve multiple levels, zones, and subsystems. Second, the manual approach is prone to human error, as even experienced professionals may overlook critical details or make incorrect assumptions about the design or installation. These errors can lead to the approval of non-compliant plumbing systems, which may not be detected until after the building is occupied, at which point corrective measures can be costly and disruptive.

Another challenge associated with the manual determination of plumbing compliance is the variability in interpretations of the codes. Different professionals may have different interpretations of the same code provisions, leading to inconsistencies in the application of the standards. This can result in disparities in the level of compliance across different projects, as well as disputes between contractors, inspectors, and property owners. Moreover, the manual approach does not easily lend itself to the tracking and documentation of compliance over time, which can be important for long-term maintenance and liability purposes.

The advent of digital technologies has opened up new possibilities for improving the process of determining plumbing compliance. Computer-aided design (CAD) software, building information modeling (BIM) systems, and other digital tools can facilitate the design and review of plumbing systems by allowing professionals to visualize the system in three dimensions, simulate its performance, and identify potential issues before construction begins. These tools can also help standardize the application of the codes by providing built-in checks and validations against the relevant standards. However, while these technologies represent a significant improvement over traditional manual methods, they still require significant input from skilled professionals and may not completely eliminate the risk of human error.

One of the key needs in the field of plumbing compliance is the development of automated systems that can quickly and accurately determine whether a plumbing design or installation meets the required standards. Such systems would need to be able to analyze a wide range of factors, including the layout and sizing of pipes, the placement and installation of fixtures, and the overall configuration of the plumbing system. They would also need to be capable of assessing the system's performance under various conditions, such as different water pressures, flow rates, and temperatures, to determine if it functions as intended in all scenarios.

Another area where improvement is needed is in the integration of plumbing compliance determination with other aspects of building design and construction. For example, plumbing systems are often closely related to other building systems, such as the structural, electrical, and HVAC systems. Therefore, a comprehensive approach to compliance determination should consider the interactions between these systems to identify potential conflicts or issues that could affect the overall performance and safety of the building.

In addition to improving the accuracy and efficiency of plumbing compliance determination, there is also a need to enhance the transparency and accountability of the process. This may involve the use of digital records and documentation that provide a clear and auditable trail of the compliance determination process, from the initial design review to the final inspection and approval. Such records can be used to track the performance of the plumbing system over time, identify any issues that arise after the building is occupied, and provide evidence in the event of disputes or legal challenges.

Furthermore, the development of automated plumbing compliance systems can also support the training and education of professionals in the field. By providing real-time feedback and guidance, these systems can help engineers, architects, and inspectors better understand the requirements of the codes and how to apply them in practice. This can lead to a higher standard of compliance across the industry, as well as a reduction in the number of errors and issues that arise during the design and construction process.

In conclusion, while traditional methods of determining plumbing compliance have served the industry well for many years, there is a clear need for improvement in terms of speed, accuracy, and consistency. The use of advanced digital technologies, such as AI and integrated design tools, offers the potential to transform the process of plumbing compliance determination, making it faster, more reliable, and less prone to human error. By addressing these needs, the industry can not only enhance the safety and performance of plumbing systems but also reduce the costs and risks associated with non-compliant installations, ultimately benefiting both building owners and occupants.

### SUMMARY OF THE DISCLOSURE

Accordingly, the present disclosure provides methods and apparatus for deploying artificial intelligence (“AI”) analyzing two-dimensional (sometimes referred to as “2D”) documents, such as design plans, floor plans, or other architectural drawing type document, to ascertain one or both of: a use of the building, or an area within the building (which may be referred to herein collectively as a “design plan”) and values for variables pertinent to an analysis of a number of plumbing fixtures required by an authority having jurisdiction (“authority having jurisdiction”). An AI engine is constructed and trained to review a 2D document and ascertain a use of the building and an occupant load for the building when used for the ascertained use, and to plumbing counts presented in design plans, provide meaningful analysis, and feedback results quickly, accurately, and consistently to comply with current codes.

In some embodiments of the present invention, methods are provided for analyzing plumbing compliance in building design plans using an AI-driven system. The method begins with the controller receiving a design plan that may include various architectural layouts, such as floor plans or blueprints, for at least a portion of a building. The controller then processes this design plan, breaking it down into multiple dynamic components that represent different elements of the building's layout, such as walls, rooms, doors, and plumbing fixtures. These dynamic components are displayed on a first interactive user interface, where each component's parameters, such as dimensions, positions, and types, can be adjusted by the user.

The AI engine, integrated within the controller, performs an analysis of the design plan to identify specific plumbing fixtures. These fixtures may include water closets, sinks, showers, urinals, and the associated piping layout. Once identified, the AI engine determines both the type and quantity of these fixtures within the design. For example, in a large commercial bathroom, the AI may identify multiple water closets and sinks, cataloging their exact types (e.g., wall-mounted vs. floor-mounted toilets) and determining if the number of fixtures meets the expected occupancy load.

Following this, the AI engine analyzes the spatial relationships and dimensions associated with these plumbing fixtures. It calculates critical metrics such as the distances between fixtures, their heights from the floor, and the clearance around each fixture, to determine if they meet necessary standards. For example, the AI may determine whether there is sufficient clearance around a toilet for wheelchair accessibility, in accordance with ADA regulations.

Based on either user input or AI-driven analysis of the design plan (e.g., markings on the design plan), the system determines the proposed use of the portion of the building. This may range from residential to commercial or institutional use, each carrying different plumbing requirements. The AI engine then cross-references the determined proposed use with a set of conditions mandated by the relevant building codes. These conditions may include specifics such as the minimum number of plumbing fixtures required, the acceptable types of fixtures, and the necessary spacing between them, all dictated by the authority having jurisdiction over the building's construction.

The AI engine then compares the identified plumbing fixtures in the design plan with the relevant code conditions. It assesses whether the current design complies with the requirements set forth by the jurisdictional authority. For example, the AI may check if the number of sinks in a restaurant kitchen is sufficient to meet health code standards or if the drainage system is properly vented to prevent sewer gas backflow.

The results of the compliance check are indicated within the first interactive user interface. The system visually highlights whether the building design is compliant or non-compliant with the set of conditions. For example, compliant areas may be shown in green, while non-compliant areas are marked in red, allowing users to quickly identify and address issues. If the design is found to be non-compliant, the system can provide suggestions for corrective actions, such as adding additional fixtures or adjusting the layout to achieve compliance. This interactive and automated method significantly streamlines the process of plumbing compliance analysis, so that building designs adhere to all necessary regulations before construction begins.

The present invention discloses methods and apparatus to quantify metrics for the calculation of plumbing fixture counts using artificial intelligence (sometimes referred to herein as “AI”) analysis to ensure code compliance under authorities having jurisdiction.

Specifically, the present invention uses AI to determine a correct number of plumbing fixture counts, and to ascertain whether plumbing fixture counts were calculated accurately by a skilled worker in order to be in compliance with relevant codes according to the authority having jurisdiction, such as, but not limited to, any applicable codes for the number of plumbing fixtures required for a building dependent on the use of, and occupancy load of the building represented on the design plan.

The present invention reduces inconsistencies in condition compliance analysis, such as code compliance analysis, and mistakes made by skilled workers. The present invention also provides accurate calculation of plumbing fixture counts for a particular building. Consistent feedback is available providing reasons why a building described by a two-dimensional reference is in or out of compliance with plumbing fixture count conditions, such as those set forth by an authority having jurisdiction.

Furthermore, according to some embodiments, suggestions may be made regarding how to cure non-compliance with a condition(s); or how to adopt a best practice pertaining to plumbing count analysis or design plan layout, and whether or not a best practice is required to meet an obligation dictated by a relevant code.

According to the present invention, two-dimensional references, such as those from an authority having jurisdiction, and applicable codes concerning plumbing fixture counts are input into an AI engine and the AI engine converts aspects of the code into components that may be processed by the AI engine, such as, a rasterized version of the two-dimensional renderings. These renderings are then processed with machine learning to specify portions that may be specified as discernable components. Discernable components may include dimensions and placement plumbing fixtures, and tables describing the minimum number of plumbing fixtures.

A scaling process is applied to the two-dimensional references and size descriptors are assigned to the discernable components. In addition, spatial metrics, such as the placement of fixtures, distances between fixtures, and clearance requirements, are calculated to assess compliance. In addition, distances, such as placement of fixtures are calculated.

Variables are specified from codes of authority having jurisdiction that will be used to assess compliance, and a compliance determination is made based upon values for the specified variables. In some embodiments, the variables may include some or all of the minimum number of plumbing fixtures, such as water closets, lavatories and urinals. The AI engine will generate values for some, or all of the variables referenced to determine compliance. For example, in a theater, the AI system may calculate the required number of male and female water closets based on the anticipated occupancy load and compare this with the actual fixture count in the design plan.

In some embodiments, a controller will also set forth materials and conditions required to be in compliance with plumbing fixture counts and which plumbing fixtures materials are required. Some embodiments may also include, in the case where the plumbing fixture counts were in violation of the code, the portions referenced in determining non-compliance. Still further, some embodiments may include suggested changes and/or options for sets of changes to the number of plumbing fixtures that may be implemented in order to achieve compliance, and the method of correcting such violations. For example, if a restaurant's restroom layout does not meet the required fixture count, the AI engine may suggest relocating or adding fixtures to provide compliance with local health regulations.

Using the methods and apparatus described herein, a determination of whether a plumbing fixture count is compliant for use by people with disabilities may also be generated. The present invention indicates how AI may be used in the design, construction, and compliance of plumbing fixtures meant for important advances in safety and accessibility for the handicapped community and to mitigate risk from falling or other adverse conditions.

In general, the present invention provides for apparatus and methods related to receiving as input authority having jurisdiction code, including table, drawings, and writings (either physical or electronic) and generating one or more-pixel patterns based upon automated processing of the plumbing fixture counts. The pixel patterns may include specific details, such as the layout of water closets, lavatories, and urinals, and their spatial relationships within the building design.

The pixel patterns are analyzed using computerized processing techniques to mimic the perception, learning, problem-solving, and decision-making formerly performed by human workers. For example, the AI system may recognize patterns in the pixel data that indicate non-compliance, such as insufficient clearance around a plumbing fixture, and automatically flag these areas for review.

Based upon AI analysis of pixel patterns derived from the two-dimensional references and knowledge accumulated from increasing volumes of analyzed two-dimensional references, interactive user interfaces may be generated that allow for a user to modify dynamic design plans relating to plumbing fixtures of features gleaned from the two-dimensional reference. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from one or both of: select group and learnings derived from similar previous bodies of work, whether or not a human requesting a current analysis was involved in the previous learnings.

In still another aspect, in some embodiments, enhanced interactive interfaces may include one or more of: user definable and/or editable lines; user definable and/or editable vectors; and user definable and/or editable polygons. The interactive interface may also be referenced to generate diagrams based upon the lines, vectors and polygons defined in the interactive interface. Still further, various embodiments include values for variables that are definable via the interactive interface with AI processing and human input. For example, a user may adjust the placement of a plumbing fixture within a restroom layout directly within the interface, with the AI engine recalculating compliance in real-time.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed. For example, the AI engine may learn from past compliance issues identified in similar projects and apply these learnings to new design plans, thereby improving accuracy and efficiency.

In general, the present invention provides for apparatus and methods related to receiving as input design plans (either physical or electronic) and generating one or more-pixel patterns based upon automated processing of the plumbing layout, including water closet plans and other plumbing fixtures. The pixel patterns are analyzed using computerized processing techniques to mimic the perception, learning, problem-solving, and decision-making formerly performed by human workers (sometimes referred to herein as artificial intelligence or “AI”).

Based upon AI analysis of pixel patterns derived from the two-dimensional references and knowledge accumulated from increasing volumes of analyzed two-dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from one or both of: select group and learnings derived from similar previous bodies of work, whether or not a human requesting a current analysis was involved in the previous learnings. For example, the AI engine can identify non-compliance issues with plumbing fixture placement, such as incorrect spacing between fixtures or inadequate clearance around water closets, and suggest design modifications based on historical data from similar projects.

In still another aspect, in some embodiments, enhanced interactive interfaces may include one or more of: user definable and/or editable lines; user definable and/or editable vectors; and user definable and/or editable polygons. The interactive interface may also be referenced to generate diagrams based upon the lines, vectors and polygons defined in the interactive interface. Still further, various embodiments include values for variables that are definable via the interactive interface with AI processing and human input. For instance, a user may adjust the slope of a drainage pipe within the interface, with the AI engine recalculating the pipe's compliance with relevant codes in real-time.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed. For example, the AI engine can analyze the flow patterns of plumbing systems, assess the correct placement of vent stacks, and determine if all drainage pipes meet the required slope for proper water flow.

The present invention reduces inconsistencies in design compliance analysis and mistakes by providing consistent feedback on reasons why a building design is in compliance, or which aspects of a design plan place the building design in a state of non-compliance. For example, if a restroom layout fails to meet the required number of fixtures for a specified occupancy load, the AI system will provide a detailed explanation of the non-compliance, along with suggestions for corrective actions, such as relocating fixtures or increasing fixture count.

Furthermore, according to some embodiments of the present invention, automated systems generate proposed modifications to achieve compliance with an applicable code, or to adopt a best practice whether or not the best practice is required to meet an obligation dictated by a relevant code. These modifications may include adding additional fixtures, adjusting the layout of existing fixtures, or selecting alternative fixtures that better meet code requirements. For example, the AI engine may recommend installing high-efficiency toilets to comply with water conservation regulations while also suggesting the optimal placement for easy access and maintenance.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernible components may include, for example, rooms, residential units, hallways, stairs, dead ends, windows, or other discrete aspects of a building. For plumbing compliance, discernible components may include specific plumbing fixtures, piping layouts, and spatial dimensions relevant to code requirements. For example, the AI engine may identify the precise location and type of each plumbing fixture, such as sinks, urinals, water closets, and showers, and assess their placement within the overall building design.

In some embodiments, a scaling process may be executed to determine floorplan size descriptors assigned to the discernable components. Additionally, the AI engine calculates distances relevant to plumbing compliance, such as the distance between fixtures, the distance of a fixture from the nearest wall, and the slope of drainage pipes to determine proper water flow. In addition, distances, such as, for example, a distance to a water closet or lavatory, and/or a distance of an exit path from the furthest point in a residential unit may be calculated.

Variables are specified that will be used to assess compliance and a compliance determination is made based upon values for the specified variables. In some embodiments, the variables may include some or all of: occupancy load; travel distance; travel distance from a furthest point from a point of egress; egress capacity; common path; dead end; a function of space; or other factor on which a determination of compliance and/or lack of compliance may be based. The AI engine will generate values for some, or all of the variables referenced to determine compliance. For example, the AI engine may analyze whether the number of lavatories in a restroom is sufficient for the expected occupancy load and provide feedback on whether the current layout meets code requirements.

In some embodiments, a controller will also set forth one or both of: components and conditions required to be in compliance with a set of rules or codes and where in the floorplan the components/conditions were included. Some embodiments may also include, in the case where the conditions/components were not met by a floorplan, the portions referenced in determining non-compliance. Still further, some embodiments may include suggested changes and/or options for sets of changes to the floor plan that may be implemented in order to achieve compliance. For example, the AI engine may recommend relocating a water closet to provide adequate clearance or adding a fixture to meet the minimum required number of plumbing fixtures.

Using the methods and apparatus described herein, a determination of whether a building is conducive for use by people with disabilities is generated. The present invention indicates how AI may be used in the design, construction and compliance of buildings meant for use by people to bring about profoundly important advances in safety and accessibility for the handicapped community and to mitigate risk from fire or other adverse conditions. For example, the AI system may analyze a restroom layout to determine if it meets ADA standards for accessibility, such as providing adequate space for wheelchair maneuverability and proper placement of grab bars, and allow all plumbing fixtures to be reachable and functional for users with disabilities.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (sometimes referred to herein as artificial intelligence or “AI”). The pixel patterns may represent various aspects of the plumbing layout, including fixture placement, piping routes, and spatial relationships, which are used for determining compliance with relevant building codes.

Based upon AI analysis of pixel patterns derived from the two-dimensional references and knowledge accumulated from increasing volumes of analyzed two-dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional reference. Analysis of pixel patterns and manipulatable vector interfaces and/or polygon-based interfaces is advantageous over human processing in that AI analysis of pixel patterns, vectors and polygons is capable of leveraging knowledge gained from one or both of: a select group and learnings derived from similar previous bodies of work, whether or not a human requesting a current analysis was involved in the previous learnings. For example, the AI engine may compare the current design plan against a database of past projects to identify common compliance issues and recommend solutions based on best practices, such as optimal plumbing fixture placement or efficient piping layouts.

In still another aspect, in some embodiments, enhanced interactive interfaces may include one or more of: user definable and/or editable lines; user definable and/or editable vectors; and user definable and/or editable polygons. The interactive interface may also be referenced to generate diagrams based upon the lines, vectors and polygons defined in the interactive interface. Still further, various embodiments include values for variables that are definable via the interactive interface with AI processing and human input. For example, a user may adjust the slope of a drainage pipe within the interface, with the AI engine recalculating the pipe's compliance with relevant codes in real-time.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed. For example, the AI engine may use deep learning techniques to improve its accuracy in identifying plumbing fixtures and their compliance status, thereby reducing the need for manual review and correction.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates an exemplary design plan that is illustrated with multiple dwelling units, and is used by the AI engine for compliance analyses.

FIG. 1D illustrates a set of conditions relating to plumbing fixture counts.

FIG. 1E illustrates another exemplary design plan used by the AI engine for ascertaining different spaces, plumbing aspects, and plumbing fixtures for compliance analyses.

FIG. 1F illustrates an exemplary water closet area extracted by the AI engine from a design plan for detailed plumbing compliance analyses.

FIG. 1G illustrates an exemplary portion of a design plan highlighting plumbing layout used by the AI engine for detailed plumbing compliance analyses.

FIG. 1H illustrates another exemplary water closet area extracted by the AI engine from a design plan for detailed plumbing compliance analyses.

FIGS. 2A, 2B, 2C and 2D illustrate a two-dimensional representation of a floor plan and an AI analysis of same to assess boundaries and different spaces, which are then used for compliance analyses.

FIGS. 2E-2J illustrate exemplary plumbing fixtures extracted by the AI engine from a design plan for detailed plumbing compliance analyses.

FIGS. 2G-2H illustrate exemplary water closets with different configurations of water tanks in relation to the surrounding wall structures, showcasing how the AI engine can assess and recommend the most appropriate setup for a given space.

FIG. 2I illustrates an exemplary shower connection layout that the AI engine may analyze for compliance in a plumbing system in some embodiments of the present invention.

FIG. 2J illustrates an exemplary water heater (geyser) connection layout that the AI engine may analyze for compliance in a plumbing system in some embodiments of the present invention.

FIGS. 3A-3D show various views of the AI-analyzed boundaries overlaid on the original floorplan including a table illustrated to contain hierarchical dominance relationships between area types.

FIG. 3E illustrates an exemplary portion of a design plan comprising a sprinkler system used by the AI engine for plumbing compliance analyses.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols.

FIG. 8 illustrates exemplary processor architecture for use with the present disclosure.

FIG. 9 illustrates exemplary mobile device architecture for use with the present disclosure.

FIGS. 10A-10B illustrate exemplary method steps that may be executed in some embodiments of the present invention.

FIG. 11 illustrates additional method steps that may be executed in some embodiments of the present invention.

FIGS. 12A-12B illustrate an exemplary selection of a space in a design plan for compliance analysis according to some embodiments of the present invention.

FIG. 13 illustrates a conceptual framework showing multiple layers involved in the AI-powered collaborative system for compliance analyses of design plans in accordance with the present invention.

FIG. 14 illustrates a block diagram of exemplary aspects that may be used in building or refining design models.

FIGS. 15A-15B illustrate exemplary method steps that may be included in some embodiments of the present invention.

### DETAILED DESCRIPTION

The present invention provides improved methods and apparatus for artificial intelligence-based conversion of a two-dimensional reference, such as a design plan, into an interactive user interface operative to indicate whether the design plan includes an adequate quantity, and type, of plumbing fixtures in order for the design plan to be in compliance with one or more designated codes, A designated code may be selected by a user, or based upon a building use and/or a number of permitted occupants in the building. A building location and appropriate Authority Having Jurisdiction may also be referenced in designating an applicable code.

The present invention utilizes AI to provide a level of consistency and accuracy not currently available during analysis of a design plan to ascertain compliance with an applicable code. The automated processes presented herein reduce mistakes and inconsistencies in code compliance analysis by associating patterns of pixels derived from design plan analysis to identify a number of plumbing fixtures and compare the identified number of plumbing fixtures with requirements of an applicable code. The present invention also provides accurate calculation of plumbing fixture counts for a particular building (or portion of a building), and consistent feedback that may include reasons why a plumbing fixture count for the building (or portion thereof) is in compliance with requirements set forth by an appropriate Authority Having Jurisdiction (AHJ), or in state of non-compliance. Furthermore, according to some embodiments, suggestions may be made regarding how to cure non-compliance or to adopt a best practice, and whether or not the best practice is required to meet an obligation dictated by a relevant code.

AI and machine learning may follow a design analysis to recognize and/or recommend aspects of a building relating to an acceptable number of plumbing fixtures for a design plan of a building if the building is dedicated to a stated purpose. For example, the AI engine may determine that a school building requires a certain number of water closets and lavatories based on the expected student population and allow these fixtures to be evenly distributed throughout the building.

In some embodiments, the AI and machine learning techniques may be combined with automated processes for one or both of: ascertaining a use of a design plan; ascertaining a required number of plumbing fixtures; ascertaining a required type of plumbing fixture; and ascertaining a number of plumbing fixtures set forth in a design plan. The automated processes presented herein may also be used to analyze a floorplan described by a particular two-dimensional reference and generating suggested modifications to the floorplan. In some embodiments, the suggested modifications may include modifications that will convert a non-compliant design plan into a floorplan compliant with a particular set of conditions, such as conditions to meet a code adopted by an AHJ. For example, the AI engine may suggest repositioning sinks or adding additional urinals in a public restroom to meet the required fixture count and spacing regulations.

The interactive interface is operative to generate values of variables useful to ascertain whether the submitted design plan meets or exceeds a designated building code pertaining to a geographic and/or geopolitical area, as that building code relates to a number of plumbing fixtures and/or a type of plumbing fixtures to be included in the design plan and a proposed use of a building. For example, the interface may display whether the spacing between water closets meets the minimum clearance requirements specified by the code for a commercial office building.

The interactive interface may also indicate specific requirements of a building code and indications as to whether some or all of the requirements are met. In addition, the user interface may include pictorial indications of portions of a design plan that have been associated with specific requirements of the building code during the AI analysis. The pictorial indications may include description of why a particular portion meets, exceeds, or does not meet a compliance code requirement. For example, areas that fail to comply may be highlighted in red, with an accompanying text box detailing the specific code violation, such as insufficient clearance around a lavatory.

As described herein, a design plan may be associated with an existing building or a proposed project that includes construction of a building (or other structure, herein collectively referred to as a “building”). Generation of documentation quantifying compliance or non-compliance of a design plan with specific building codes is also within the scope of the present invention. In some embodiments, automated suggested revisions to the design plan to bring the design plan into conformity with the code are also within the scope of the invention. For example, after identifying a non-compliant restroom layout, the system may automatically generate a revised plan that includes the necessary fixture adjustments to achieve compliance.

According to the present invention, a controller is operative to execute artificial intelligence (AI) processes and analyze one or more design plans of at least a portion of a building (or other structure) for which a compliance determination will be generated and provides values for variables used to ascertain a state of compliance based upon descriptive content included in the design plans. For example, the AI engine may analyze the layout of a commercial kitchen to verify that all plumbing fixtures, such as sinks and floor drains, are properly placed and connected to comply with health and safety regulations.

In some embodiments of the present invention, a method is provided for analyzing plumbing compliance in building design plans using an AI-driven system. This method enhances the accuracy and thoroughness of compliance checks by incorporating several key analytical steps that consider spatial relationships, fixture placements, and building use types. Initially, the design plan is received by the controller, where it is converted into a raster image format. This conversion allows the AI engine to process the design with a high degree of precision, enabling it to represent the design plan as multiple dynamic components. These components may include various plumbing fixtures, such as water closets, sinks, showers, and piping layouts.

The AI engine identifies these plumbing fixtures by recognizing patterns based on predetermined templates stored in an accessible database. These templates may include specifications for different fixture types, allowing the AI engine to accurately classify and assess each identified component. The AI engine then determines spatial relationships and dimensions associated with the identified plumbing fixtures, calculating critical metrics such as the distances between fixtures, distances from side walls, heights from the floor level, clearances around fixtures, and the slope of drainage pipes. These calculations are used for determining if the layout meets the necessary building and plumbing codes, particularly in areas where specific clearance or slope requirements are mandated.

The method also includes generating a first interactive user interface that displays the dynamic components, each with changeable parameters. Users can interact with the user interface to modify the location, type, height, distance, or dimension of the plumbing fixtures. This interactivity allows for real-time adjustments and refinements to the design plan, facilitating an iterative process where compliance can be continually reassessed as changes are made.

The AI engine further determines a proposed use for the portion of the building, selecting from categories such as residential, commercial, industrial, or institutional. Based on this proposed use, the AI engine identifies a set of conditions related to plumbing fixtures, which includes the minimum and maximum number of each type of fixture required, as well as specific spacing requirements as dictated by the relevant building code. These conditions are then compared against the identified fixtures in the design plan to determine whether the plan complies with the required standards.

If non-compliance is detected, the system provides automated suggestions for design modifications. These suggestions may include options for relocating fixtures, changing fixture types, or adjusting their spacing to meet the set conditions. For example, if the AI engine identifies that a restroom in a commercial building lacks the required number of sinks for its occupancy load, it may suggest adding additional sinks or reconfiguring the layout to better utilize the available space.

The method also includes the step of determining the area of the portion of the building and calculating the occupancy load based on this area. The AI engine then analyzes the plumbing compliance in relation to the occupancy load, so that the number and type of plumbing fixtures are adequate for the expected use of the space. Additionally, the AI engine determines dominance ranks for spaces within the building, prioritizing the compliance analysis for spaces with higher dominance ranks.

In some embodiments, the AI engine also analyzes compliance related to specific plumbing systems such as water heaters and sprinkler systems. For water heaters, the AI engine evaluates the piping connections to determine if they meet safety and efficiency standards, such as correct pipe diameters and proper insulation. For sprinkler systems, the AI engine assesses the count and placement of sprinklers to determine if they provide adequate coverage for fire safety compliance.

The AI engine may also analyze the routing, diameter, and connections of both water supply pipes and drainage pipes within the piping layout. This may include checking for compliance with code requirements related to pipe sizing, flow rates, and routing paths, so that the plumbing system is both efficient and compliant with the relevant building codes. By integrating these various steps, the method provides a comprehensive and automated approach to plumbing compliance analysis, significantly improving the reliability and efficiency of the design review process.

In some embodiments, the design plan may include technical drawings such as blueprints, floor plans, design plans and the like. The AI analysis may include determination of boundaries and/or features indicated in the design plan. The design plan may be a two-dimensional static reference, or a two-dimensional or three-dimensional dynamic reference, such as a Revit compatible file. This boundary determination may be used to provide useful information about a building such as, one or more of: rooms that comprise a residential unit; an area of an individual room or other area; a distance of travel to a point of egress, a width of a doorway; a width of a path or egress; a dead end path; a perimeter of a defined area; a point furthest from another point (e.g.; a point furthest from a point of egress); a common path; and the like. For example, the AI engine may calculate the distance from a water closet to the nearest exit to ensure compliance with health and safety codes. Based upon values of parameters derived from two-dimensional references, the AI engine may generate additional values related to code compliance, such as, one or more of: an egress capacity; an occupancy load; a function for a space; alternative paths of egress; dead end double back distances; or other parameters. For example, the AI engine may determine the occupancy load of a restroom based on its area and the number of plumbing fixtures, to determine if the layout complies with both occupancy and fixture count requirements.

In the following sections, detailed descriptions of examples and methods will be given. The description of both preferred and alternative examples, though thorough, are exemplary only. It is understood to those skilled in the art that various modifications and alterations may be apparent and within the scope of the present invention. Unless otherwise indicated by the language of the claims, the examples do not limit the broadness of the aspects of the underlying invention as defined by the claims.

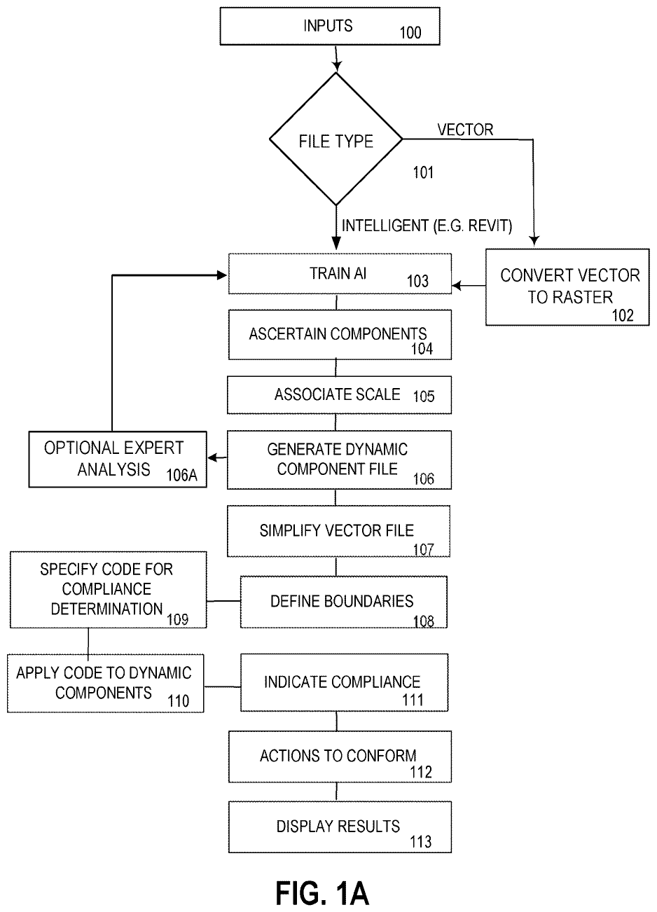

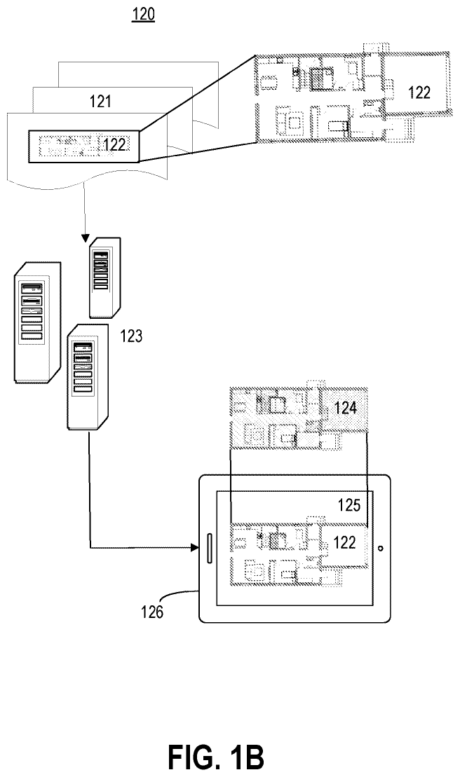

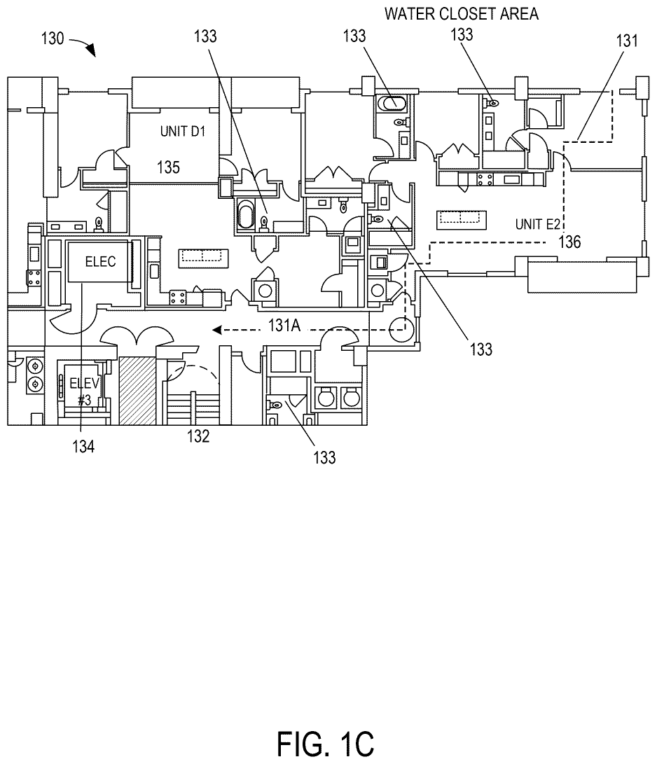

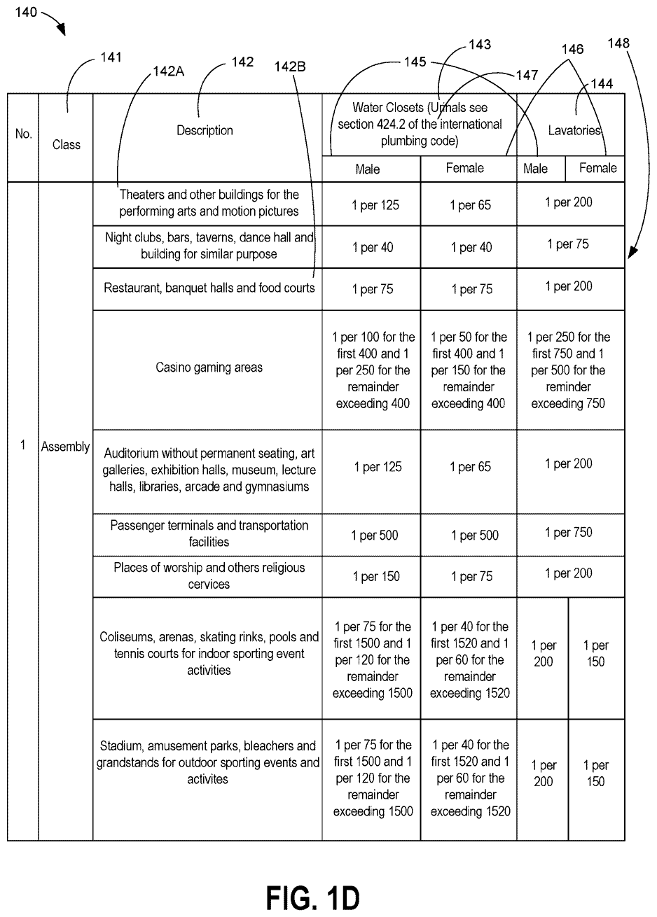

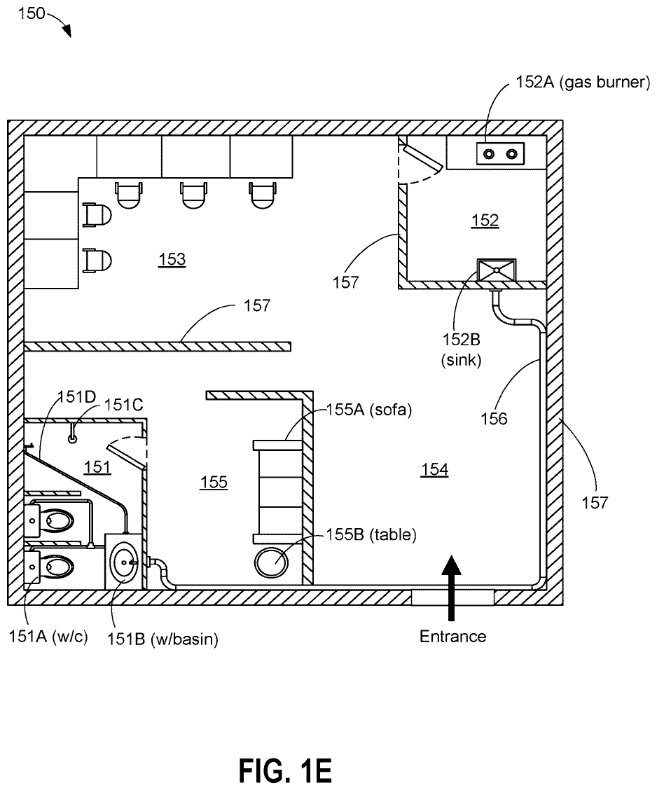

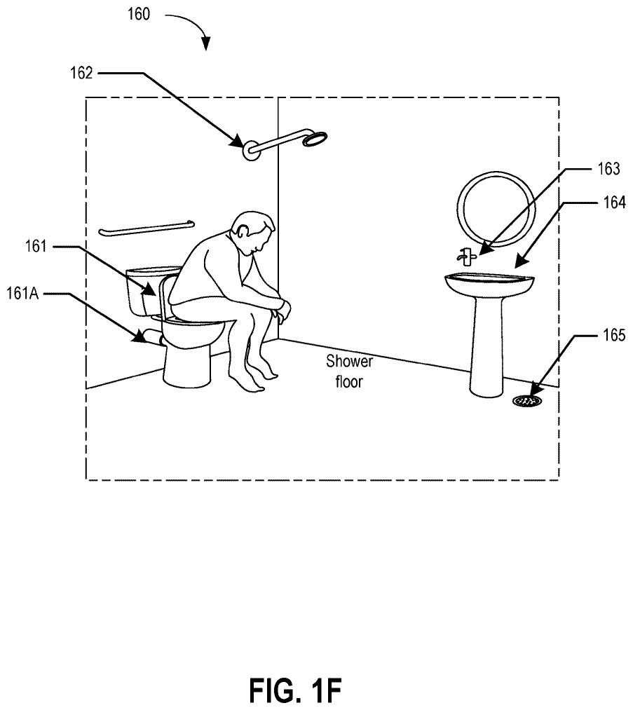

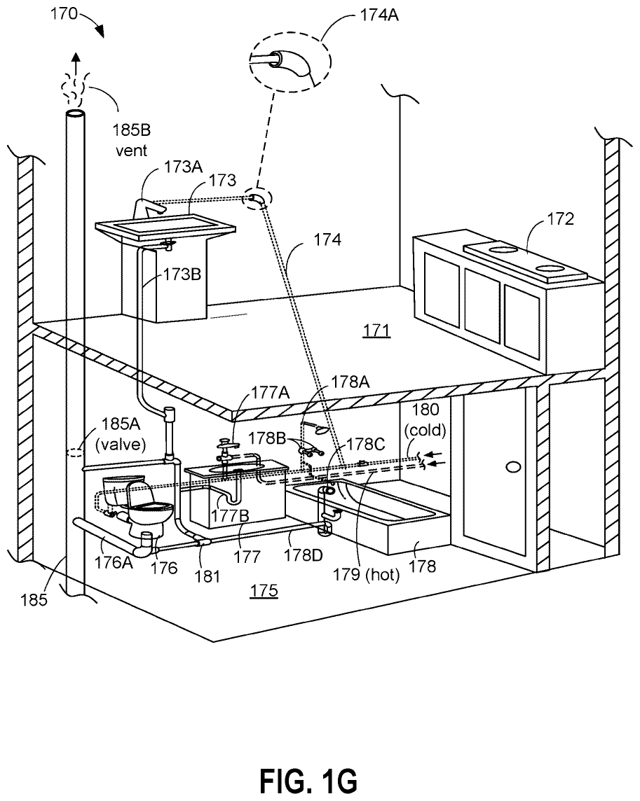

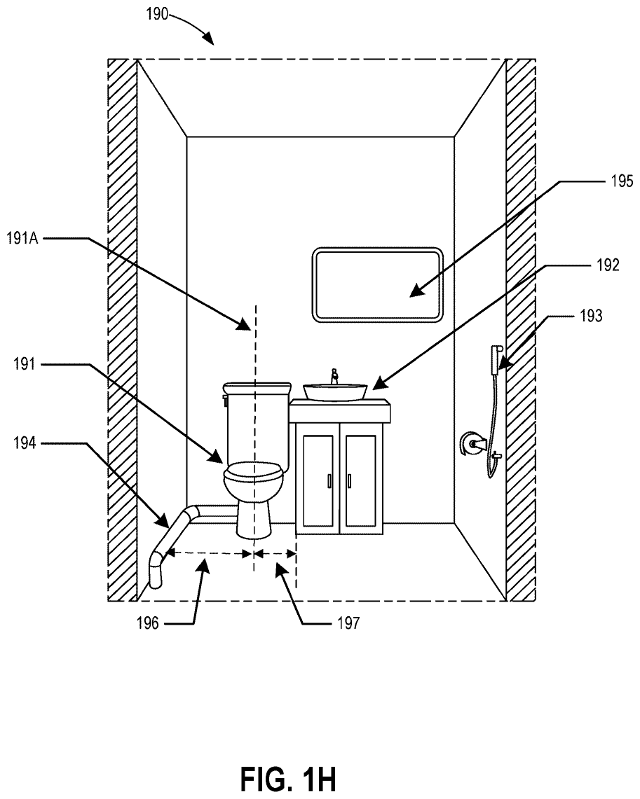

Referring now FIG. 1A, a general flow diagram showing some preferred embodiments of the present invention is illustrated. At step 100, a design plan (which may be a static design plan or dynamic architectural design file (e.g., a Revit® compatible file)) indicating aspects of a building; is input into a controller or other data processing system using a computing device. The design plan may include an item of a known size, such as, by way of non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide).

Input of the two-dimensional reference into the controller may occur, for example, via known ways of rendering an image as a vector diagram, such as via a scan of paper-based initial drawings; upload of a vector image file (e.g., encapsulated postscript file (epf file); adobe illustrator file (ai file); or portable document file (pdf file). In other examples, a starting point for estimation may be drawing file in an electronic file containing a model output for an architectural floor plan. In still further examples, other types of images stored in electronic files such as those generated by cameras may be used as inputs for automated processes that determine compliance with plumbing and building code requirements.

In some embodiments, the design plan may be files extensions that include but are not limited to: DWG, DXF, PDF, TIFF, PNG, JPEG, GIF, or other type of file based upon a set of engineering drawings. Some design plans may already be in a pixel format, such as, by way of non-limiting example a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged couple device to create the file containing the image on the smart device.

In some embodiments, a degree of the processing as described herein may be performed on a controller, which may include a cloud server, a standalone computing device or a smart device. In many examples, the input file may be communicated by the smart device to a controller embodied to a remote server. In some embodiments, the remote server, which is preferably a cloud server, may have significant computing resources that may be applied to AI algorithmic calculations analyzing the image for plumbing compliance determination.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software only embodiments of the AI engine may be run on one or more of: local computers, cloud servers, or on smart device processing environments.

At step 101, a controller may determine if a design received into the controller includes a vector diagram. If a file type of the received design plan, such as an input architectural floor plan technical drawing, includes at least a portion that is not already in raster graphics image format (for example that it is in vector format), then the input architectural floor plan technical drawing may be transformed to a pixel or raster graphics image format in step 102. The transformation process may be helpful in uniform analysis across various file formats. Vector-to-image transforming software may be executed by the controller, or via a specialized processor and associated software.

In some embodiments, the controller may determine a pixel count of a resulting rasterized file. The rasterized file will be rendered suitable for a controller hosting an artificial intelligence engine (“AI engine”) to process, where the AI engine may be optimized for detecting plumbing elements and analyzing compliance criteria. The AI engine may function best with a particular image size or range of image size and may include steps to scale input images to a pixel count range in order to achieve a desired result. Pixel counts may also be assigned to a file to establish the scale of a drawing—for example, 100 pixels equals 10 feet.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metric.

At step 103, training (and/or retraining) of the AI engine is performed. Training may include, for example manual identification of patterns in a rasterized version of an image included in a design plan that correspond with architectural aspects, walls, plumbing fixtures, piping, piping, duct work, wiring or other features that may be present in the two-dimensional reference. The training may also include one or more of: identification of relative positions and/or frequencies and sizes of identified patterns in a rasterized version of the image included in the design plan.

In some embodiments, and in a non-limiting sense, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, plumbing fixtures, stairs, and the like.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. Using deep artificial neural networks, original architectural floor plans (along with any labeled boundaries) may be used to train AI models to make predictions about what is inside a boundary. For plumbing-specific applications, additional training data including labeled plumbing fixtures and piping configurations may be incorporated. In exemplary embodiments, the AI model may be given over ~50,000 similar architectural floor plans to improve boundary-prediction capabilities.

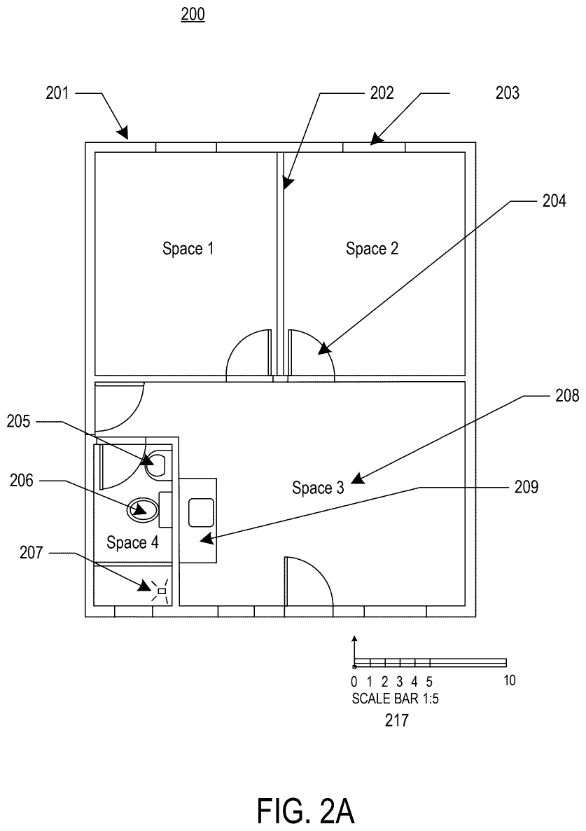

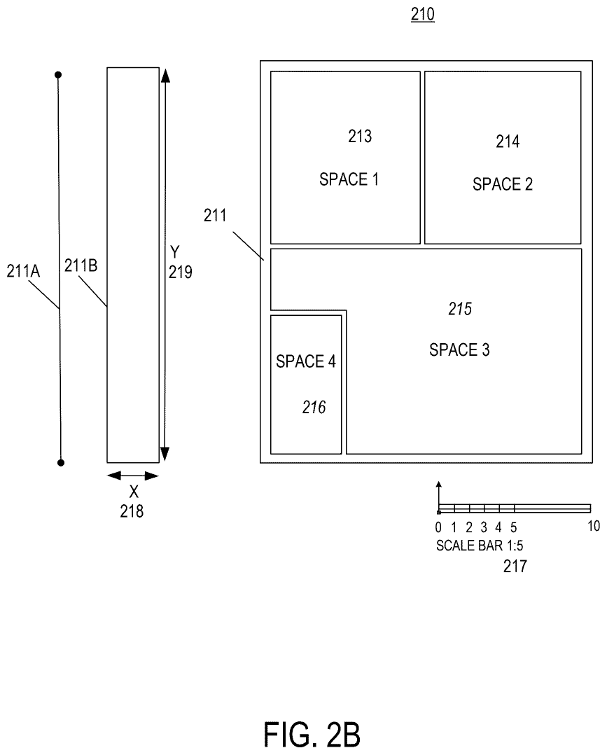

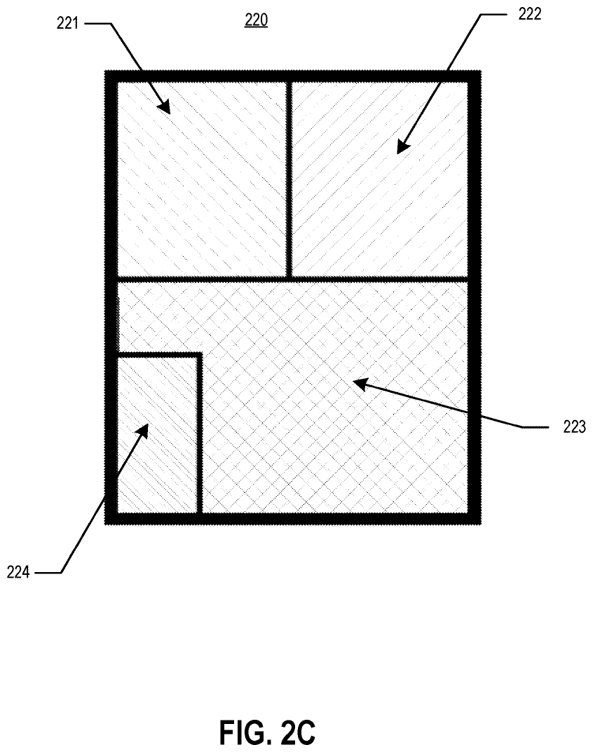

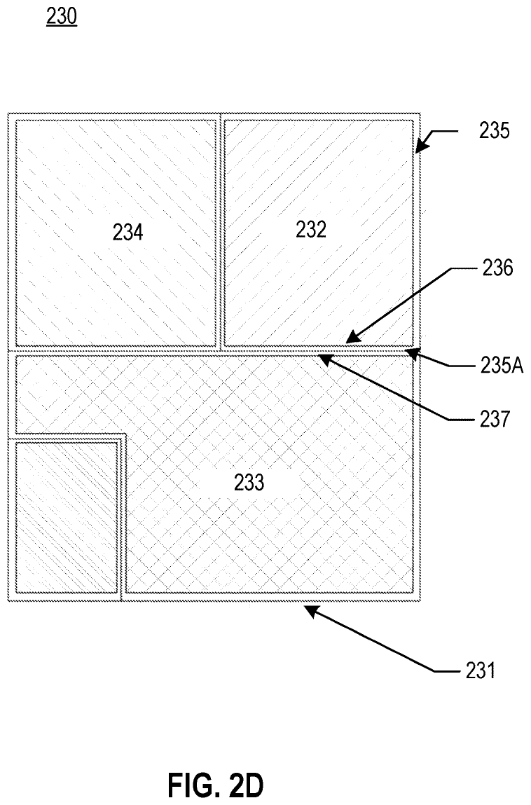

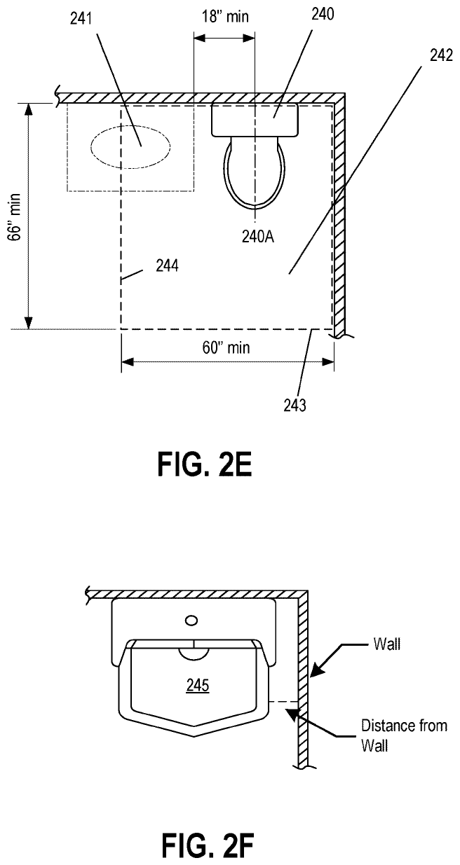

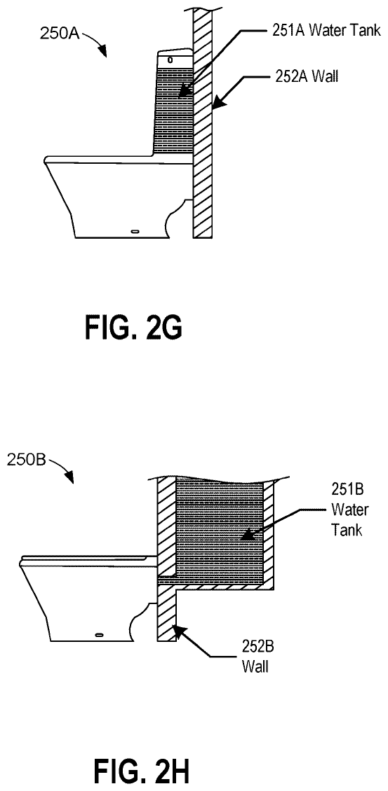

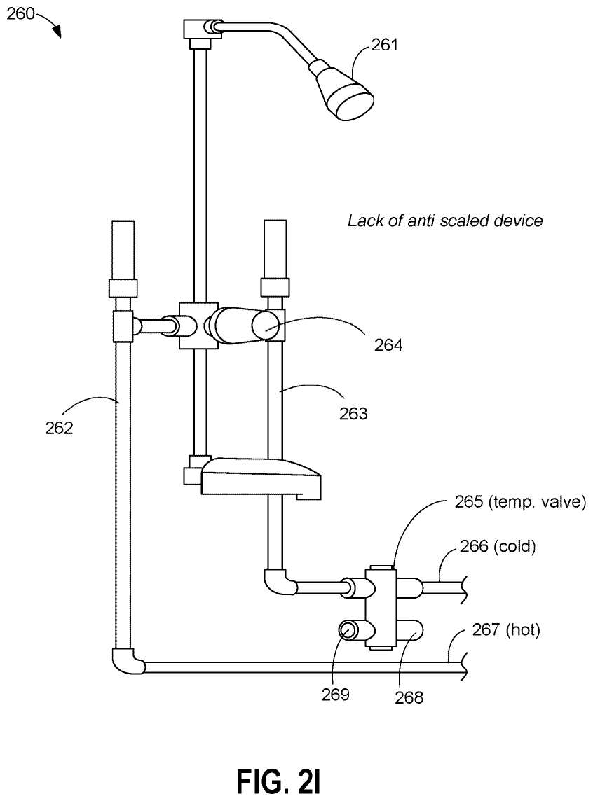

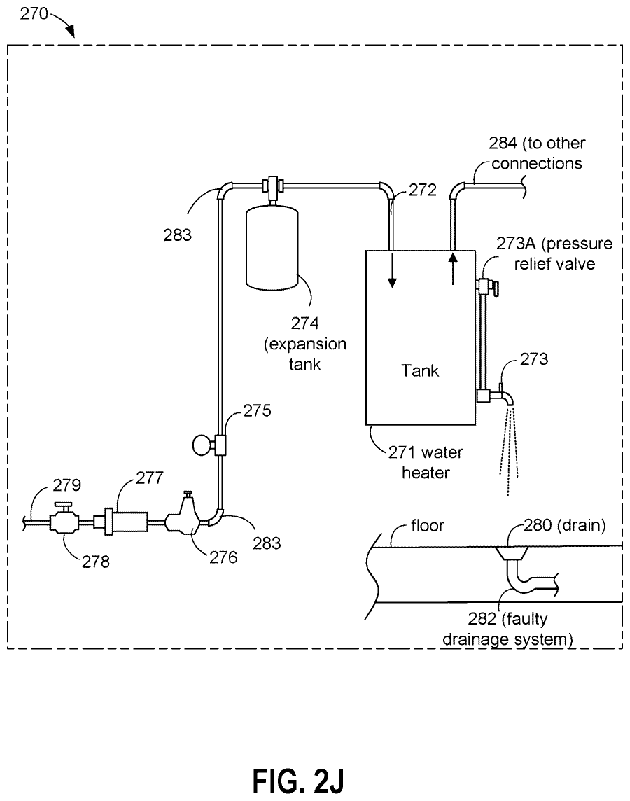

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. The training database can be specialized to focus on plumbing-related elements and compliance criteria. (An exemplary AI-processed two-dimensional reference that includes a design pan and/or a floorplan 210, with boundaries 211 predicted, is shown in FIG. 2B, based on the floorplan of FIG. 2A.)

In still another aspect, in some embodiments, a controller may access data from various types of BIM and Computer Aided Drafting (CAD) design programs and import dimensional and shape aspects of select spaces or portions of the designs as they related to a design plan. This capability allows the AI engine to integrate various data sources for a more comprehensive plumbing compliance analysis.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects, plumbing fixtures, piping, duct work, wiring, or other item included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shape.

At step 105, a scale (e.g.; FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale for a particular image, drawing or other two-dimensional reference. The drawing scale, may for example, be in inches: feet, centimeters: meters, or any other appropriate scale.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. (FIG.

At step 106, a controller is operative to generate a user interface with dynamic components that may be manipulated by one or both of user interaction and automated processes. Any or all of the components in a user interface may be converted to a version that allows a user to modify an attribute of the component, such as the length, size, beginning point, end point, thickness, or other attribute. In some embodiments, a boundary may be treated as a component and manipulated in like manner.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or end point, associate a pattern of pixels with a predefined shape corresponding with a known component or otherwise modify a shape formed by a pattern of pixels.

In addition, some embodiments that utilize the recognition step transforms features such as windows, doorways, vias and the like to other features and may be remove them and/or replace them as elements-such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons.

In another aspect, in some embodiments, one or both of a user and a controller may indicate a component type for a boundary. Component types by include, for example, one or more of line segments, polygons, multiple line segments, multiple polygons, and combinations of line segments and polygons.

At step 106A, In some embodiments, components presented in an interactive user interface may be analyzed by a user and refinements may be made to one or more components (e.g., size, shape and/or position of the component). In some embodiments, user modifications may also be input back to the AI engine train the AI engine. User modifications provided back to the AI Engine may be referenced to make subsequent AI processes more accurate and/or enable additional types of AI processes.

At step 108, a controller (such as, by way of non-limiting example, a cloud server) operative as an AI engine may create AI-predicted dynamic boundaries that are arranged to form a representation of submitted design plan that does not include the boundaries that bound it.

In various embodiments, a boundary may be used to define a unit, such as a residential unit, a commercial office unit, a common area unit, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may in turn be used as a basis for modifying an occupant load, defining an egress path, classifying a space, evaluating plumbing fixture requirements, or other purposes.

For example, a change in a boundary may make an area larger. The larger area may be a basis for an increase in occupancy load. The larger area may also result in a longer path from the furthest point in the defined area to a point of egress (e.g.; if a user chooses to use a worst case in determining an egress route).

At step 109, one or both of the user and an automated process on a controller may specify a code for which a compliance determination based upon the AI generated boundaries. In some embodiments, a selection of a set of codes to apply to the floor plan may be automated, for example, based upon a geographic or geopolitical area in which the building resides or will be constructed. In other embodiments, a user may specify a set of codes, such as, for example, a drop-down menu may indicate available codes, and a user may select one or more sets of codes to apply to the floor plan. Accordingly, by way of non-limiting example, a user may select that a set of floorplans be analyzed with the AI engine to assess compliance with Americans with Disabilities Act (ADA) compliance, National Fire protection Association code, International Plumbing Code (IPC), Uniform Plumbing Code (UPC), or other codes adopted by an authority having jurisdiction.

At step 110, a set of parameters or conditions for a selected set of code (e.g., related to plumbing compliance) is applied to some or all of the dynamic components generated via the AI engine. This step may be used for determining compliance with plumbing-specific requirements, such as fixture spacing, pipe sizes, and drainage slopes.

At step 111, the user interface or other output may be caused to display an indication of whether a design plan is in compliance with the selected set(s) of codes. In some preferred embodiments, a list of conditions required in order for a building to be in compliance, and an indication of why one or more of the conditions is met may be illustrated within a user interface or other output. For example, if the ADA is the basis for a set of codes to ascertain compliance with, a set of floorplans may be input into an AI engine and the AI engine will determine a value, and/or a range of values, which may be compared to the code requirements and a determination may be generated indicating whether the design plans describe a building that is in compliance with a selected set of codes. The ADA may require that a building described in the design plan have accessible routes that are at least thirty-six (36) inches wide. The AI engine may analyze a design plan and generate boundaries that may be manipulated by a user and then generate values for variables required to assess whether a condition the code sets forth is present in the design plan, such as the 36-inch-wide routes.

In generating a value for such as variable, the AI engine and/or the user may need to that one or more boundaries define a specific type of area, such as a bedroom, a hallway, or a stairwell. Each specific type of area may have specified variables associated with it. By way of non-limiting example, the user interface may employ a simple yes/no indicator for compliance with a requirement of a selected code. In other embodiments, the user interface may visually indicate portion of the design plan that was referenced in determining a state of compliance or on-compliance, e.g.; a doorway that is thirty-six inches or more and therefore in compliance or a hallway that is only twenty-four inches wide and therefore not in compliance.

Some specific embodiments may include a first portion of a user interface with delineated conditions for code compliance, such as, for example, a listing of sections of a code, an ability for a user to select a specific section of the code, and a link that brings up an interface with visual indicators illustrating a state of compliance (or non-compliance as the case may be) with the user selected section of code.

At step 112, in another aspect, the present invention may use the AI to generate suggested modifications to a design plan in order to transition the design plan from a state of non-compliance to a state of compliance. The modifications may include adjusting fixture locations, increasing or decreasing pipe sizes, or modifying drainage slopes to meet plumbing-specific requirements. In addition, the user interface may indicate other actions, in addition to a modification to the design plan, (e.g., reduce an occupant load) in order to conform to code.

At step 113, a conclusion of whether a design plan is in compliance may be displayed as a user interface in an integrated fashion in relation to a replication of the two-dimensional reference (such as the design plan, architectural floor plan or technical drawing). The user interface may also be shown in a form that includes user modifiable elements, such as, but not limited to: polylines, polygons, arcs, circles, ellipses, splines, line segments, icons, points and other drawing features or combinations of lines and other elements. This comprehensive display allows users to interact with and refine their designs based on the AI-generated compliance analysis, for example, for plumbing-related aspects of the building design.

Referring now to FIG. 1B, a high-level diagram illustrates components included in a system 120 that uses AI to generate an interactive user interface 125 and programmable apparatus (controller) 123 operative to execute method steps useful in determining compliance with a design plan or other architectural description. The system 120 integrates advanced AI algorithms that may specifically be designed for analyzing plumbing elements within architectural plans.

According to some embodiments of the present invention, a two-dimensional reference 121, such as a design plan, floorplan, blueprint, or other document includes a pictorial representation 122 of at least a portion of a building. The pictorial representation 122 may include, for example, a portable document format (PDF) document, jpeg, png, or other essential non-dynamic file format, or a hardcopy document. The pictorial representation 122 includes an image descriptive of architectural aspects of the building, such as, by way of non-limiting example, one or more of: walls, doors, doorways, hallways, rooms, residential units, office units, bathrooms, stairs, stairwells, windows, plumbing fixtures, real estate accouterments, and the like. This representation serves as the foundation for AI-driven compliance analysis, particularly focusing on plumbing code adherence.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. The AI engine may be optimized for interpreting architectural and plumbing features and cross-referencing them with relevant plumbing codes. Presentation of the two-dimensional reference may include, for example, scanning a hardcopy version of the two-dimensional document into electronic format and transmitting the electronic format to the controller 123 running the AI engine.

The controller is operative to generate a user interface 125 on a user computing device 126. The user computing device may include a smart device, workstation, tablet, laptop or other user equipment with a processor, storage, and display. The user interface 125 is designed to facilitate real-time interaction with the design plan, allowing users to review and modify design aspects including those related to plumbing compliance.

The user interface 125 includes a reproduction of the pictorial representation 122 and an overlay 124 with one or more user manipulatable components, such as, by way of non-limiting example: boundaries, line segments, polygons, images, icons, points, and the like. These components may represent critical elements of the plumbing system, such as pipe routes, fixture locations, and drainage layouts. The line segments may have calculated lengths that may be mathematically manipulated and/or summarized. Aspects such as polygons, line segments, shapes, icons, and points may be counted, added, subtracted, extrapolated, and other functions perform on them. This functionality may particularly be useful for evaluating the spatial requirements of plumbing codes, such as minimum distances between fixtures or pipe diameters.

In addition, renditions of the user interface 125 may be created and saved, and/or communicated to other users, or controllers, compared to subsequent interface renditions, archived and/or submitted to additional AI analysis. These renditions may allow for iterative refinement of the design plan, so that each revision aligns more closely with the relevant plumbing codes.

In some embodiments, a first user interface 125 rendition may be modified by a user to create a second user interface 125 and submitted to AI analysis to ascertain compliance with a selected code. This feature enables users to weigh the financial and logistical impacts of making the necessary modifications to achieve plumbing compliance. Some embodiments may also calculate costs, expenses, man hours or other variable associated with changes to a design plan in order to bring the design plan into compliance. Change order renditions provided as options to bring a design plan into compliance with a selected code may also be provided with a unique identifier, time and/or date stamped to create a continuum of work, as related to original projects and compliance-initiated changes. Each of the items in the continuum of work may be stored and subsequently used for ascertaining eventual compliance of a building with each selected code. This creates a transparent, traceable history of design iterations, making it easier to demonstrate compliance to regulatory authorities.

Referring now to FIG. 1C, an exemplary design plan 130 serves as a foundational document for compliance analysis performed by a controller equipped with an AI engine. The design plan 130, representing a floor layout of a building, may be input into the system for a comprehensive analysis of architectural and plumbing elements. The controller, through its AI capabilities, assesses various features of the design plan 130 to determine its compliance with relevant building codes, particularly those related to plumbing.

The AI engine begins by identifying the overall structure and layout of the design plan 130. It recognizes the various dwelling units, such as Unit D1 135 and Unit E2 136, which are designated living spaces within the building. These units may include rooms such as bedrooms, living rooms, office spaces, or kitchens. The identification of these spaces is based on the layout, walls, and other architectural elements present in the design plan. The AI engine also determines the presence of multiple water closet areas 133 distributed across the building, which are then used for determining plumbing compliance.

Within the dwelling units 135 and 136, the AI engine may identify specific rooms and spaces by analyzing the configuration and types of fixtures present. For example, the system detects a kitchen area 134 within Unit D1 135, based on the presence of kitchen-related fixtures such as sinks, countertops, and stove placements. Similarly, it recognizes a stairwell 132 that provides vertical access within the building. The AI engine also identifies various paths 131 connecting different spaces within the floor plan, such as corridors and hallways, which may be used for understanding the flow of occupants and the distribution of plumbing fixtures.

The controller further analyzes the paths 131 for their lengths and connectivity. It calculates path distances 131A, which represent the distances between different spaces, such as from a bedroom to a water closet area 133 or from the kitchen 134 to the nearest stairwell 132. These path distances may also be used for compliance analysis, particularly in determining if plumbing fixtures are accessible within reasonable distances. For example, the AI engine checks that the distance from any living space to the nearest water closet does not exceed code-prescribed limits, thereby facilitating easy access to plumbing facilities.

In addition to recognizing and analyzing dwelling units, the AI engine identifies other spaces within the design plan that are common in residential and commercial buildings. For example, it may identify office spaces, living rooms, utility rooms, and storage areas based on their location, size, and the presence of specific fixtures. In an office space, the system may look for desks, chairs, and workstations, while in a living room, it can recognize sofas, entertainment units, and coffee tables. These identifications help the AI engine categorize spaces accurately for further compliance checks.

The AI engine also ascertains the number and type of plumbing fixtures within each identified space. For example, within the water closet areas 133, it recognizes fixtures such as toilet seats, urinals, and sinks. These fixtures are then analyzed to determine if they meet the necessary requirements for the space. For example, the AI engine may calculate whether the number of sinks in a water closet area is sufficient to handle the expected occupancy load of the building, based on the total number of occupants that the design plan 130 suggests.

Furthermore, the controller can automatically identify the type of a space based on the fixtures commonly found within that space. For example, the presence of multiple water closets, urinals, and sinks in a specific area indicates that the space is a bathroom or restroom. Similarly, the presence of a sink, oven, and refrigerator indicates a kitchen area 134. The AI engine may use this information to confirm the intended use of each space and determine if the design plan 130 meets the relevant code requirements for that type of space.

In some cases, the AI engine may determine the type of space based on markings or annotations present on the design plan itself. For example, labels such as “Living Room,” “Kitchen,” or “WC” (Water Closet) on the design plan guide the AI engine in accurately categorizing spaces. These annotations help the AI engine to cross-reference the design with code requirements more effectively, so that each space is evaluated correctly based on its intended use.

Once the AI engine identifies and categorizes all the spaces within the design plan 130, it proceeds with a detailed compliance analysis. For plumbing analysis, the AI engine focuses on the plumbing fixtures within each space. It checks the number, type, and placement of fixtures against the relevant plumbing codes. For example, it verifies that each water closet area 133 has the required number of toilet seats and sinks based on, for example, the occupancy load and the space classification.

The AI engine also analyzes the size and shape of plumbing fixtures to determine if they meet code specifications. For example, the system can measure the dimensions of a sink to confirm that it meets the minimum size requirements for a bathroom in a residential unit. It also checks the spacing between fixtures, such as the distance between a toilet and a sink, to determine if there is sufficient clearance for accessibility and functionality.

In addition to individual fixture analysis, the AI engine evaluates the overall layout of plumbing systems within the building. It examines the placement of plumbing lines, drainage systems, and water supply routes to determine if they are efficiently and safely integrated into the building design or not. For example, the AI engine may assess whether the water supply lines or pipes are appropriately sized to deliver adequate water pressure to all fixtures, especially during peak usage times.

The AI engine also considers the accessibility of plumbing fixtures, particularly for spaces that must comply with the Americans with Disabilities Act (ADA). It checks that water closets and sinks are placed at the appropriate height and that there is adequate space around them for wheelchair access. For example, the AI engine determines if the pathway leading to a water closet area 133 is wide enough to accommodate a wheelchair, and that the fixtures themselves are positioned to allow for easy use by individuals with disabilities.

Another aspect of the analysis involves verifying the ventilation and drainage systems associated with plumbing fixtures. The AI engine checks that each water closet area 133 is equipped with proper ventilation to prevent the buildup of moisture and odors. It also analyzes the drainage systems to determine if wastewater is efficiently removed from the building, with no risk of backflow or blockages. For example, the AI engine may check that the slope of the drainage pipes is sufficient to allow for gravity-assisted flow, as required by plumbing codes.

The AI engine is also capable of performing a load analysis on the plumbing systems within the design plan. It calculates the expected water usage based on the number and type of fixtures in each space, as well as the anticipated occupancy load. This information is used to determine whether the building's water supply and drainage systems are adequately sized to handle the expected demand. For example, if the AI engine identifies a high concentration of water-intensive fixtures, such as multiple showers or commercial kitchen equipment, it may recommend increasing the diameter of the supply pipes to prevent low water pressure.

The AI engine may also cross-reference the design plan 130 with local and national plumbing codes to identify any deviations or non-compliance issues. If the design plan 130 includes features that do not align with the required codes, such as insufficient fixture counts or improper fixture placement, the system flags these issues for correction. For example, if the design plan 130 shows only two sinks in a water closet area 133 that requires four, the AI engine highlights this discrepancy and suggests adding the necessary fixtures.

In cases where the design plan includes annotations or markings that specify the intended use of certain spaces, the AI engine uses this information to refine its analysis. For example, if a space is labeled as “Employee Restroom,” the AI engine adjusts its compliance checks based on the specific requirements for employee facilities, such as the need for separate male and female restrooms, as dictated by the applicable plumbing codes.

Once the AI engine completes its analysis, it generates a detailed report summarizing its findings. This report may include a visual representation of the design plan 130, with highlighted areas indicating compliance or non-compliance with plumbing codes. For example, the report may show a green highlight around water closet areas 133 that meet all code requirements, and a red highlight around those that require modifications. The report also provides actionable recommendations for bringing the design plan 130 into compliance. These recommendations may include adding or relocating fixtures, adjusting plumbing lines, or reconfiguring spaces to improve accessibility and functionality.

In addition to the compliance report, the AI engine can generate a cost estimate for implementing the recommended changes. This estimate includes the cost of materials, labor, and any additional expenses associated with modifying the plumbing systems. For example, if the system suggests adding two additional sinks to a water closet area 133, it provides an estimate of the cost for purchasing the sinks, installing them, and making any necessary plumbing adjustments.

The AI engine also offers a feature for real-time interaction with the design plan. Users can modify the layout directly within the interface, and the AI engine immediately reanalyzes the updated design. This feature allows for quick iterations and adjustments, helping designers optimize the layout for both functionality and compliance. For example, if a designer moves a sink to a different location within a water closet area 133, the AI engine recalculates the distances and rechecks compliance with the relevant codes.

The system is also capable of integrating with other building information modeling (BIM) tools, allowing for seamless data exchange and coordination between different aspects of the building design. For example, plumbing compliance data from the AI engine can be integrated with structural analysis tools to determine if the placement of heavy fixtures compromises the building's structural integrity.

In some embodiments, the AI engine is regularly updated with the latest plumbing codes and standards, so that its analysis is always based on the most current regulations. This feature is particularly valuable in regions where codes are frequently amended, as it eliminates the need for manual updates and research. For example, if a new regulation is introduced that requires all public restrooms to have touchless faucets, the AI engine automatically incorporates this requirement into its analysis.

Referring now to FIG. 1D, a data set 140 with factors relating to plumbing fixture counts 148 that may be ingested into an AI engine is illustrated. The AI engine, which is embedded within a controller, is operative to analyze a design plan (for example, design plan 130 in FIG. 1C) and ascertain aspects described in the design plan that are pertinent to the conditions 140. In some embodiments, the factors 140 may be closely related to, or literally based upon, codes adopted by an Authority Having Jurisdiction (AHJ), such as the International Plumbing Code, the Uniform Plumbing Code, or the International Building Code. Such embodiments utilize a table to assign minimum fixture counts based upon the intended use of the building and the number of occupants it will serve. For example, under the International Plumbing Code, a theater must have at least one water closet (WC) for every 125 male occupants and one WC for every 65 female occupants. The AI engine leverages this table to analyze design plans across various building types, each with their own fixture ratios, to determine compliance.

The present invention deploys a controller acting as an AI engine to determine the number of plumbing fixtures 148 required for a building or space within a building. Multiple factors 140 are ascertained that are pertinent to determining the appropriate number of fixtures 148, such as, by way of non-limiting example, the classification 141 of the space, a description of the intended use 142, the type of plumbing fixture, such as a water closet 143 or a lavatory 144, the type of building, building size, occupancy classification, and occupancy load. The specific code 147 used to provide a set of conditions, such as a plumbing code or regulation enforced by an AHJ, is also considered. The AI engine correlates these factors to the table 140, automating the otherwise labor-intensive task of cross-referencing fixture counts with code requirements.

Determining whether a building meets plumbing compliance standards, particularly regarding fixtures, depends on both the proposed use and occupancy of the building. For example, a theater 142A may require a different number of water closets 143 and lavatories 144 compared to a restaurant 142B. Therefore, the AI engine first ascertains the specific use of the building or building area, which is critical in determining how many fixtures need to be installed. This process may be linked to, and dependent upon, the calculated building occupancy load, which the AI engine automatically estimates by analyzing the architectural layout and correlating it with established codes. For example, the AI engine may analyze a theater's seating arrangement, calculate the expected number of occupants, and then determine the required number of plumbing fixtures based on code specifications.

Consequences for non-compliance with plumbing fixture requirements can vary depending on the AHJ and the severity of the violation. The AI engine is also capable of providing an indication of remedies that may be required by property owners to correct a violation. Examples of these remedies may include adding fixtures, modifying existing fixtures, or restricting access to certain areas until compliance is achieved. For example, if a design plan reveals that a restroom in a theater lacks sufficient water closets, the AI may suggest adding additional fixtures or redesigning the space to meet the compliance standards. The AI engine may also indicate the potential consequences of failing to address non-compliance, which could include fines, penalties, revocation of permits, or legal action by the AHJ. In more severe cases, repeat offenders may face criminal charges. The system can track violations associated with specific legal entities and provide recommendations to mitigate the risks associated with non-compliance.

The data set 140 of factors associated with compliance, particularly concerning the minimum number of required plumbing fixtures, may be specific to an AHJ and associated with the location and intended use of the building as described in the design plan. For example, a design plan for a large conference center in a densely populated city may trigger different fixture requirements than a similar structure in a rural area, depending on the local code specifications. The AI engine adjusts its analysis accordingly to meet the specific requirements of the relevant jurisdiction.

As codes are frequently amended, the rules governing plumbing fixture counts are subject to periodic revisions and updates. Traditionally, skilled workers must stay updated on these changes across all applicable jurisdictions, which demands extensive research. In contrast, the AI engine is regularly updated with the latest code revisions, automatically integrating new requirements into its analysis. This eliminates the need for manual research, and the AI based compliance analysis remains current and accurate.

Regulations for plumbing fixture counts are designed to maintain public health and hygiene standards by preventing issues such as long waiting times, unsanitary conditions, or inadequate access to plumbing facilities. There is a significant demand for a method that can quickly calculate plumbing fixture counts, provide meaningful analysis, and accurately align with current codes. The present invention addresses this demand by using AI to determine whether a building described in a design plan meets or exceeds the requirements of a set of conditions involving the quantity and placement of plumbing fixtures for a given purpose. For example, the AI engine can automatically verify that in employee and public toilet rooms, a required lavatory is located in the same room as a required water closet, as specified by certain codes.

In some embodiments of the present invention, the system is utilized to automate the analysis of a building's plumbing compliance, particularly focusing on the requirements for plumbing fixtures based on the following non-limiting examples—proposed use, number and types of spaces, occupancy load and building use. The system employs an AI engine, integrated within a controller, to process a design plan and determine whether the number, type, and placement of plumbing fixtures meet the specific requirements outlined by the relevant plumbing codes, such as the International Plumbing Code (IPC) or Uniform Plumbing Code (UPC).

Consider a practical example involving a new design for a theater complex. The design plan is input into the system as a digital file (e.g., a DWG or PDF format), which the AI engine analyzes. The system first identifies the classification of the building as “Assembly” under the plumbing codes, which categorizes spaces intended for public gatherings, such as theaters, restaurants, or exhibition halls.

Based on the architectural layout provided in the design plan, the AI engine calculates the theater's total seating capacity and, subsequently, the maximum occupancy load. For instance, the theater has a seating capacity of 1,000 seats. According to the IPC (or a relevant plumbing code), for an assembly building like a theater, the plumbing code specifies that there must be:
Water Closets (WCs) for Male Occupants: At least 1 WC per 125 occupants.
Water Closets (WCs) for Female Occupants: At least 1 WC per 65 occupants.
Lavatories for Male Occupants: At least 1 lavatory per 200 occupants.
Lavatories for Female Occupants: At least 1 lavatory per 200 occupants.

The AI engine then performs the following calculations:
For 1,000 male occupants, the required number of WCs is calculated as:

$$WCs for Males = \frac{1000}{125} = 8 water closets$$

For 1,000 female occupants, the required number of WCs is:

$$WCs for Females = \frac{1000}{65} \approx 15.38 ( rounded up to 16 water closets )$$

For 1,000 male occupants, the required number of lavatories is:

$$Lavatories for Males = \frac{1000}{200} = 5 lavatories$$

For 1,000 female occupants, the required number of lavatories is also:

$$Lavatories for Females = \frac{1000}{200} = 5 lavatories$$

Next, the AI engine examines the spatial arrangement within the restroom areas of the theater. The AI engine measures the distances between fixtures, such as the distance between each water closet and adjacent walls and verifies that each fixture is adequately spaced to allow for accessibility, in accordance with the ADA requirements, and that the restrooms are compliant with the minimum fixture clearances outlined in the plumbing codes. For example, the code may specify that there must be at least 15 inches from the centerline of a toilet to any side wall or partition, and at least 21 inches of clearance in front of each toilet.

In addition, the AI engine assesses the total floor area of the restroom and determines whether the space is sufficient to accommodate the required number of fixtures. It checks that the placement of lavatories, urinals, and other plumbing fixtures adheres to code-mandated spatial guidelines, such as maintaining a minimum distance between lavatories and that the urinals are separated by partitions to maintain privacy.

After performing the calculations and spatial analysis, the AI engine generates a compliance report that includes a visual representation of the restroom layout, highlighting areas that meet the code requirements and flagging any deviations. For example, if the system detects that the current design only includes 12 water closets for female occupants (where 16 are required), it will flag this as a non-compliant issue. The report may also suggest specific modifications, such as adding additional water closets or reconfiguring the restroom layout to meet the required clearances and fixture counts.

In cases where non-compliance is detected, the system provides actionable recommendations, such as adding additional fixtures, expanding restroom areas, or adjusting the layout to accommodate the required number of fixtures. These recommendations are based on the specific conditions and requirements outlined in the applicable plumbing codes and are aimed at bringing the design plan into full compliance.

In another embodiment, the user can interact with the system via a user interface to make adjustments to the design plan in real-time. For example, if the AI engine suggests adding four more water closets to the female restroom, the user can modify the layout directly within the interface. The AI engine will then immediately reanalyze the updated design and provide feedback on whether the changes bring the design into compliance. This iterative process allows for efficient fine-tuning of the design, reducing the need for multiple revisions and speeding up the overall design process.

Referring now to FIG. 1E, it illustrates another exemplary design plan 150, which is utilized by the AI engine to ascertain different spaces 151-155, boundaries 157, plumbing aspects, and various fixtures for compliance analysis. The design plan 150 represents a small apartment (e.g., a portion of a building), where the AI engine begins by identifying and categorizing the different functional spaces within the layout. These spaces may include a water closet area 151, a kitchen area 152, a living space 155, an office space 153, and another general-purpose area 154. Each of these spaces comprises specific fixtures and elements that the AI engine analyzes in detail to determine whether the design meets relevant building and plumbing codes.

The AI engine first identifies the water closet area 151 located in the lower-left corner of the design plan 150. The water closet area 151 includes several plumbing fixtures such as water closets 151A, a sink or wash basin 151B, a shower 151C, and the associated piping structure 151D. The AI engine recognizes these fixtures by analyzing their shapes, sizes, and positions within the space 151. The water closets 151A, for example, are identified based on their characteristic shape and their location adjacent to the wall. The AI engine also examines the piping structure 151D, which connects these fixtures to the building's plumbing system, to determine if it is adequate for the expected water flow and complies with plumbing codes regarding pipe sizing and material.

In addition to the water closet area, the AI engine identifies the kitchen area 152 situated in the upper-right corner of the design plan 150. Within the kitchen area 152, the AI engine recognizes several key fixtures, including a gas burner 152A and a sink 152B. The gas burner 152A is identified by its rectangular shape and its connection to a gas line, while the sink 152B is recognized by its position relative to the countertop and the presence of a water supply line. The AI engine may also examine other potential fixtures in this area, such as a refrigerator, dishwasher, or additional counter space, if present. Each fixture's placement and connection to utilities are analyzed to determine if the kitchen layout adheres to relevant safety and plumbing codes, for example, those related to gas line safety and water drainage.

The AI engine proceeds to analyze the living space 155, which is centrally located in the design plan 150. In this area, the AI engine identifies a sofa 155A and a table 155B. These items are recognized based on their shapes and sizes, as well as their typical placement within a living room setting. The AI engine assesses the arrangement of the furniture in relation to the walls, windows, and other architectural elements to determine if the space is used efficiently and if there are any potential issues with accessibility or egress. For example, the AI engine checks that the sofa 155A is not blocking any doors or windows and that there is sufficient space around the table 155B for movement.

In the office space 153, located at the upper-left corner of the design plan 150, the AI engine identifies seating arrangements and other office-related fixtures. The seating layout, which includes chairs and desks, may be analyzed for compliance with ergonomic standards and space utilization. The AI engine may also identify other elements such as bookshelves, filing cabinets, or computers, depending on the level of detail in the design plan. Each of these elements is considered in the context of the office's functionality and compliance with building codes, particularly those related to workplace safety and accessibility. Similarly, the AI engine may also examine the general-purpose area 154, located adjacent to the living space 155.

Beyond identifying and categorizing spaces and fixtures, the AI engine determines specific measurements, including sizes, shapes, and associated distances. For example, the AI engine calculates the distance from the water closet 151A to the adjacent wall, for determining that it meets the minimum clearance requirements specified by plumbing codes. The distance between the sink 152B and the gas burner 152A may also be measured to confirm that there is adequate separation to prevent safety hazards, as required by kitchen safety regulations. The AI engine may further assess the height of the sink 152B from the floor level, verifying that it complies with accessibility standards.

The AI engine uses a scale (such as scale 217 discussed in FIG. 2B below) provided on the design plan 150, to accurately measure these distances and heights. The scale indicates the ratio of the drawing's measurements to real-world dimensions, such as 1 inch equaling 10 feet. The AI engine counts the number of pixels between two points on the design plan and then applies the scale to convert this pixel count into a real-world measurement. For example, if the distance between the water closet 151A and the wall is measured as 200 pixels on the design plan, and the scale indicates that 100 pixels equal 5 feet, the actual distance would be 10 feet.

In the kitchen area 152, the AI engine checks the placement of the gas burner 152A in relation to the sink 152B to determine if the layout adheres to code requirements for kitchen safety. The engine may calculate the height of the gas burner 152A above the countertop and the clearance between it and any overhead cabinets or ventilation systems. These measurements are compared against the relevant codes, which specify minimum and maximum distances to prevent fire hazards and facilitate proper ventilation.

Another aspect of the AI engine's analysis involves assessing the layout of the plumbing systems within the design plan 150. The AI engine examines the connections between the plumbing fixtures and the building's water supply and drainage systems. It checks that the piping structure 151D is appropriately sized to handle the expected water flow without causing pressure drops or backups. The AI engine also analyzes the slope of drainage pipes to confirm that they are steep enough to allow for gravity-assisted drainage, as required by plumbing codes.

In addition to the spatial analysis, the AI engine checks the alignment and symmetry of fixtures and furniture within each space. It verifies that elements such as sinks, toilets, and tables are aligned with walls and other architectural features, so that the design is aesthetically pleasing and functional. The AI engine may also identify any design elements that are off-center or misaligned, suggesting adjustments to improve the overall layout.

The AI engine may further analyze the boundaries 157 of the design plan 150, which define the edges of each space and the overall structure of the room or apartment. The AI engine checks that these boundaries are consistent with the building's structural requirements and that they provide adequate support for the fixtures and furniture within each space. For example, the AI engine may verify that the walls surrounding the water closet area 151 are thick enough to support the installation of plumbing fixtures and that the doorways are wide enough to accommodate accessibility requirements.

The AI engine may also assess the safety features within the design plan 150, such as the placement of fire alarms, smoke detectors, and emergency exits. It checks that these safety features are strategically located to provide maximum protection for the occupants. For example, the AI engine may verify that there is a smoke detector installed in the kitchen area 152, near the gas burner 152A, and that there is a clear path from the living space 155 to the nearest emergency exit.

The AI engine may also consider the potential for future modifications or expansions within the design plan 150. It checks that the layout is flexible and that there is room for adding or relocating fixtures and furniture as needed. For example, the AI engine may verify that the living space 155 can accommodate additional seating or that the kitchen area 152 has space for future appliance upgrades. The AI engine may also suggest design strategies that allow for easy modifications, such as using modular furniture or creating open-plan spaces that can be reconfigured as needed.

The AI engine further evaluates the accessibility of the design plan 150, considering how well the layout accommodates individuals with disabilities or special needs. It checks that the design meets accessibility standards and that the spaces are usable by all occupants. For example, the AI engine may verify that the water closet area 151 includes grab bars and accessible fixtures or that the entrance to the building is step-free and wide enough for wheelchair access.

In some embodiments of the present invention, the AI-driven system is specifically adapted to analyze plumbing compliance in buildings based on their proposed use, particularly in specialized environments such as theaters, taverns, restaurants, and places of worship. For example, when the proposed use of the portion of the building is a theater, the AI engine may apply relevant building codes that may require the inclusion of at least one male water closet per 125 occupants and at least one female water closet per 65 occupants.

Similarly, when the building's proposed use is identified as a tavern, the AI engine may enforce the code requiring at least one male and one female water closet per 40 occupants. This may particularly be important in environments where frequent use of restrooms is anticipated due to the nature of the establishment. For restaurants, the AI engine may apply the code requiring at least one male and one female water closet per 75 occupants, so that the restroom facilities are sufficient for patrons during peak dining hours. In places of worship, where large congregations may gather, the AI engine may analyze compliance by requiring at least one male and one female water closet per 150 occupants, thereby facilitating smooth flow and accessibility during services.

In addition to determining the required number of fixtures, the method includes indicating the placement and shape of walls that encompass the water closets within the first interactive user interface. This feature allows architects and designers to visualize the restroom layout in detail, to verify that the spatial configuration meets both functional and compliance requirements. For example, the AI engine may suggest adjusting the shape of the enclosing walls to optimize space or improve accessibility, which can be critical in high-occupancy areas.

The method also includes determining the geopolitical locality and the authority having jurisdiction over the building's site. The AI engine incorporates this information into the set of conditions, so that all relevant local codes and regulations adopted by the jurisdiction are included in the compliance analysis.

Further, the method allows for dynamic modification of the design plan within the interactive user interface. For example, if one of the dynamic components is represented as a polygon, the user can modify the shape or other parameters of the polygon directly through the interface. Additionally, line segments representing elements like walls or partitions can also be modified through the interactive user interface. The AI engine responds to user instructions by adjusting the line segments, thereby allowing for real-time updates to the design. For example, a user may extend a wall to create additional space for an accessible stall or shorten a partition to improve the flow of movement within the restroom.

These capabilities make the system highly adaptable and responsive to the needs of designers, allowing building plans to be quickly adjusted to meet compliance requirements while maintaining functionality and user comfort. By integrating these various steps, the AI-driven method offers a comprehensive tool for analyzing plumbing compliance in buildings with specific use cases, from theaters and restaurants to places of worship and beyond.

Referring now to FIG. 1F, it illustrates an exemplary water closet area 160, which is extracted by the AI engine from a design plan (e.g., 150) for detailed plumbing compliance analysis. FIG. 1F showcases a typical bathroom setting, where various plumbing fixtures are placed in a layout that the AI engine meticulously examines to determine if the design adheres to the relevant building codes and standards. The AI engine identifies and analyzes key fixtures within the water closet area 160, including a water closet 161, a shower 162, a tap 163, a wash basin 164, a shower drain 165, and the closet drainage pipe 161A.

The AI engine evaluates the water closet 161 in terms of its placement within the water closet area 160. It checks the distance from the centerline of the toilet to the adjacent walls to determine if it meets the minimum clearance requirements. For example, building codes often specify that there must be at least 15 inches from the centerline of the toilet to any side wall or partition, allowing sufficient space for comfortable use. Additionally, the AI engine measures the clearance in front of the toilet to determine if there is enough room for a user to sit and stand comfortably, typically requiring a minimum of 21 inches of clear space in front of the toilet bowl.

Adjacent to the water closet 161, the shower 162 is another critical fixture that the AI engine analyzes. The placement of the shower 162 is determined for both usability and compliance with water containment and drainage regulations (e.g., relevant codes). The AI engine checks that the showerhead is installed at an appropriate height, which is generally around 80 inches from the floor, to accommodate users of varying heights. The AI engine also examines the dimensions of the shower area to verify that it provides sufficient space for a user to move comfortably, typically requiring a minimum shower area of 30 inches by 30 inches. Additionally, the AI engine also evaluates the slope of the shower floor to determine proper drainage, as a slope of ¼ inch per foot is often required to direct water flow towards the drain 165.

The tap 163, positioned on the wall within the water closet area 160, is another fixture that the AI engine scrutinizes. The height of the tap 163 is analyzed to determine if it is accessible and easy to use, typically installed at a height of 36 to 40 inches from the floor. The AI engine also checks the proximity of the tap 163 to the wash basin 164, determining if the water flow from the tap is directed appropriately into the basin 164 without causing splashing or water wastage. The AI engine may also evaluate the flow rate of the tap 163, verifying that it meets water efficiency standards.

The wash basin 164, often referred to as a sink, is a vital component of the water closet area 160, providing a place for users to wash their hands and face. The AI engine analyzes the placement of the wash basin 164 to determine if it is ergonomically positioned within the space. The AI engine measures the height of the basin 164 from the floor, which is generally required to be around 34 inches for accessible use, particularly in compliance with the Americans with Disabilities Act (ADA). The AI engine also assesses the clearance around the basin, verifying that there is sufficient space on either side of the basin for users to place toiletries, typically requiring at least 4 inches of clearance on both sides.

The shower drain 165, located on the floor of the water closet area 160, is required for proper water removal from the bathroom. The AI engine examines the placement of the drain 165 to determine if it is positioned at the lowest point of the floor, allowing for effective water drainage. The AI engine checks the size of the drain, for determining if it is large enough to handle the water flow from the shower 162, typically requiring a drain diameter of at least 2 inches. The AI engine also evaluates the connection of the drain 165 to the building's plumbing system, verifying that it is properly vented and connected to prevent sewer gases from entering the bathroom.

The closet drainage pipe 161A, connected to the water closet 161, is another fixture that the AI engine analyzes in detail. The AI engine checks the diameter of the drainage pipe 161A, which is typically required to be at least 3 inches for a toilet, to determine if it can handle the waste flow without causing blockages. The AI engine also examines the slope of the drainage pipe 161A, which is generally required to be at least ¼ inch per foot, to facilitate proper gravity-assisted flow of waste materials. Additionally, the AI engine assesses the venting of the drainage pipe to determine if it is adequately vented, preventing the buildup of negative pressure that could disrupt the flow of wastewater.

The AI engine further analyzes the overall layout of the water closet area 160, evaluating the spatial relationships between the various fixtures. The AI engine checks that the water closet 161, shower 162, tap 163, wash basin 164, and shower drain 165 are arranged in a manner that allows for efficient use of the space while maintaining compliance with building codes. For example, the Ai engine verifies that the distance between the water closet 161 and the wash basin 164 is sufficient to allow for easy movement between the fixtures, typically requiring at least 30 inches of clearance. The AI engine also checks that the shower 162 is positioned in a way that prevents water from splashing onto the toilet 161 or basin 164, potentially causing hygiene issues.

In addition to analyzing the placement and spacing of the fixtures, the AI engine may also evaluate the materials used for each fixture and the associated plumbing components. The Ai engine checks that the materials are durable, water-resistant, and compliant with plumbing codes. For example, the AI engine verifies that the water closet 161 and wash basin 164 are made of ceramic or porcelain, materials that are commonly required by plumbing codes for their durability and ease of cleaning. The AI engine also checks that the pipes and fittings used for the drainage system are made of PVC or copper, materials that are resistant to corrosion and meet code requirements.

The AI engine also considers the safety aspects of the water closet area 160, particularly in terms of slip and fall prevention. The AI engine checks the flooring material in the shower area 162 and around the wash basin 164 to determine if it is slip-resistant, as required by building codes. The AI engine may recommend the installation of additional safety features, such as grab bars near the shower 162 and water closet 161, to assist users with mobility challenges.

The AI engine further assesses the ventilation of the water closet area 160, which is critical for preventing the buildup of moisture and odors. The AI engine checks that there is an exhaust fan installed in the bathroom, typically required to provide at least 50 cubic feet per minute (CFM) of air movement, or that the bathroom has a window that can be opened to provide natural ventilation. The AI engine also evaluates the placement of the exhaust fan or window in relation to the shower 162 and water closet 161, to determine if moist air is effectively removed from the space.

In addition to ventilation, the AI engine analyzes the water supply to the fixtures in the water closet area 160. The AI engine checks that the water supply lines are adequately sized to deliver sufficient water pressure to the tap 163, shower 162, and water closet 161. The AI engine typically verifies that the supply lines are at least ½ inch in diameter, as required by plumbing codes, and that they are connected to the building's main water supply in a manner that prevents backflow contamination. The AI engine may also evaluate the temperature of the water supplied to the tap 163 and shower 162, determining that it can be adjusted to provide a safe and comfortable range, typically between 100 and 120 degrees Fahrenheit.

The AI engine also considers the hygiene aspects of the water closet area 160. The AI engine checks that the surfaces of the fixtures, including the water closet 161, wash basin 164, and shower 162, are smooth and easy to clean, with no crevices or joints that could harbor bacteria. The AI engine may recommend the use of antimicrobial materials or coatings on the fixtures to further enhance hygiene. The AI engine also evaluates the placement of the drain 165 in relation to the shower 162 and wash basin 164, to determine if wastewater is efficiently removed from the bathroom without pooling on the floor.

The AI engine also assesses the functionality of the water closet area 160, analyzing how well the fixtures work together to provide a convenient and comfortable bathroom experience. The AI engine checks that the water closet 161, wash basin 164, and shower 162 are positioned in a logical sequence that facilitates the typical use of the bathroom. For example, the AI engine may verify that the wash basin 164 is located near the entrance to the bathroom, making it easy for users to wash their hands before leaving. The AI engine also considers the convenience of the tap 163, so that it is within easy reach of the wash basin 164 and that the water flow is directed properly into the basin 16.

The AI engine may also evaluate the maintenance requirements of the water closet area 160. The AI engine checks that the fixtures are designed for easy maintenance, with accessible parts that can be quickly cleaned or repaired. The AI engine may recommend the use of fixtures with removable components, such as pop-up drains or snap-on faucet aerators, to simplify maintenance tasks. The AI engine also considers the maintenance of the plumbing system, so that the drainage pipes, venting system, and water supply lines are installed in a way that minimizes the risk of clogs, leaks, or other issues that could require frequent maintenance.

The AI engine also assesses the safety of the water closet area 160, particularly in terms of electrical safety. The AI engine checks that any electrical outlets or switches in the bathroom are installed at a safe distance from the water sources, such as the wash basin 164 and shower 162, typically requiring at least 3 feet of separation to prevent electrical hazards. The AI engine also verifies that the bathroom is equipped with ground fault circuit interrupter (GFCI) outlets, which are required by code to prevent electrical shock in wet areas. The AI engine may recommend the installation of additional safety features, such as waterproof light fixtures or tamper-resistant outlets, to further enhance safety.

The AI engine may also consider the cost-effectiveness of the water closet area 160, analyzing the cost of the fixtures and materials in relation to their quality and durability. The AI engine checks that the fixtures provide good value for money, balancing initial cost with long-term savings in terms of maintenance, energy efficiency, and water conservation. The AI engine may recommend cost-effective alternatives to high-end fixtures, such as mid-range products that offer similar functionality and durability at a lower price point. The AI engine also evaluates the overall cost of the bathroom installation, including labor and materials, so that it fits within the project's budget.

In some embodiments, the AI engine may also evaluate the aesthetics of the water closet area 160, considering how the design and materials contribute to a visually appealing bathroom environment. The AI engine checks that the fixtures are stylish and that their design complements the overall theme of the bathroom. The AI engine may recommend the use of decorative elements, such as custom tile patterns or designer fixtures, to enhance the bathroom's visual appeal. The AI engine also considers the color scheme of the bathroom, so that the colors of the fixtures, tiles, and walls work together to create a cohesive and attractive design.

Referring now to FIG. 1G, it illustrates an exemplary portion 170 of a design plan, focusing on the plumbing layout, which is analyzed by the AI engine for detailed plumbing compliance assessments. The design portion 170 showcases two exemplary spaces of a building: a kitchen area 171 and a bathroom area 175. Each of these spaces contains essential fixtures and plumbing connections, which the AI engine meticulously evaluates to determine compliance with relevant building codes.

The kitchen area 171 features a gas burner 172 and a sink 173. The sink 173 is equipped with a water tap 173A and a drain pipe 173B. The water tap 173A connects to a water supply pipe 174, which in turn is linked to a cold water source pipe 180. The AI engine analyzes the diameters of both the drain pipe 173B and the water supply pipe 174, for determining proper function. The drain pipe 173B typically needs to be at least 1.5 inches in diameter to facilitate adequate drainage and prevent clogs. The water supply pipe 174 generally requires a diameter of at least ½ inch to maintain sufficient water pressure for the sink 173. The AI engine also inspects any joints or bends, such as bend 174A, in the water supply pipe 174. Bends or joints in pipes must be carefully designed to avoid restricting water flow, which can cause pressure loss or create points of potential leaks. The AI engine checks that any bends are gradual and that joints are securely fitted to prevent such issues.

The bathroom area 175 includes several fixtures: a water closet 176, a sink 177, and a bathtub 178. The water closet 176 is connected to a cold water source pipe 180, which supplies water to the toilet's tank. The AI engine examines the connection between the water closet's tank and the cold water supply 180, to determine if it is secure and free of leaks. The water closet's drainage is managed by a closet drainage pipe 176A, which connects to a main stack vent pipe 185. The AI engine assesses the diameter and slope of the closet drainage pipe 176A, as these factors are used for ensuring proper waste removal. The drainage pipe 176A must typically have a diameter of at least 3 inches, with a slope of ¼ inch per foot, to facilitate gravity-assisted waste flow.

The sink 177 in the bathroom 175 is equipped with a tap 177A and a water drain pipe 177B. The AI engine identifies a significant issue with the connection between the tap 177A and the hot water source pipe 179: while the connection pipe is routed towards the tap 177A (from source pipe 180), the connection is incomplete, leaving the tap 177A without a hot water supply. The AI engine may flag this as non-compliant since bathroom sinks may be required to have both hot and cold water supplies to meet code requirements in some cases. The tap 177A is also missing a connection to the cold-water source pipe 180, another violation of standard plumbing codes. The AI engine recommends corrective actions, such as completing the necessary connections to both hot and cold water supply lines 179-180.

The bathtub 178 in the bathroom, featuring a shower 178A, shower knobs 178B, an excess water drain pipe 178C, and a waste water drain pipe 178D. The AI engine analyzes the connections to the shower 178A, confirming whether it is correctly linked to both the hot-water source pipe 179 and the cold-water source pipe 180, or not. This helps users to adjust the water temperature as needed. The AI engine also checks for the presence of safety features such as temperature valves and pressure relief valves, which are needed for preventing scalding and hence providing consistent water pressure. These valves must be installed correctly to maintain both user safety and system integrity.

The AI engine also scrutinizes the various joints and bends within the piping structure, such as joint 181. Joints and bends in plumbing systems must be carefully designed to maintain the strength and continuity of the pipe network. Poorly designed joints can be weak points prone to leaks or bursts under pressure. The AI engine checks that all joints are securely sealed, using appropriate materials such as solvent-welded fittings for PVC pipes or soldered joints for copper pipes. Bends must be gentle enough to allow smooth water flow and minimize the risk of clogs or pressure loss.

The AI engine further evaluates the overall layout of the plumbing system in portion 170, considering the efficiency of water distribution and waste removal. The AI engine checks that the water supply lines are properly routed to minimize pressure drops and that the drainage system is designed to facilitate gravity flow without requiring excessive pipe lengths or unnecessary bends. The AI engine may also assess the potential for future maintenance, so that all pipes and valves are accessible for repairs or inspections.

Water drain pipes 177B, 178C-178D, and 173B, connected to the sink, bathtub, and kitchen sink respectively, are shown connected to the closet drainage pipe 176A. The AI engine analyzes this configuration to determine if it complies with standard plumbing practices. Typically, connecting multiple drain pipes to a single drainage line can lead to issues like cross-contamination or blockages if not designed properly. The AI engine checks that the pipe sizes and slopes are adequate to handle the combined flow and that proper venting is in place to prevent siphoning or backflow.

The stack vent pipe 185, connected to the drainage system, maintains proper air pressure in the drain lines and allowing sewer gases to escape safely. The AI engine examines the configuration of the stack vent pipe 185, which includes a valve 185A. This valve may serve as a backflow protection valve, designed to prevent wastewater from re-entering the clean water supply system. The AI engine confirms if this valve is correctly installed and functions properly to protect the plumbing system from contamination.

Additionally, the stack vent pipe 185 is equipped with a vent stack 185B, which allows odors and gases to escape from the drainage system and dissipate into the atmosphere. The AI engine verifies that the vent stack 185B is of adequate height above the roofline, typically required to be at least 6 inches, to provide proper ventilation and prevent odors from settling near windows or air intakes. The AI engine also checks that the vent 185B is free from obstructions, as blockages can lead to pressure imbalances and disrupt the function of the entire drainage system.

The AI engine may also look at the insulation of hot water pipes, such as the hot water source pipe 179, to provide energy efficiency and safety. Uninsulated hot water pipes can lead to significant heat loss, reducing the efficiency of the heating system and potentially leading to scalding hazards if the pipes are exposed. The AI engine checks that all hot water pipes are properly insulated, particularly in areas where they pass through unheated spaces or near cold water pipes, which could lead to condensation and corrosion.

The AI engine also evaluates the pressure balance within the water supply system, particularly in areas where both hot and cold water are supplied, such as the sink 177 and bathtub 178. Uneven water pressure can lead to issues such as sudden temperature changes, which can be dangerous for users. The AI engine checks that pressure-balancing valves are installed in fixtures where both hot and cold water are mixed, so that the temperature remains consistent even if there is a fluctuation in water pressure.

Another aspect the AI engine examines is the potential for water hammer, a phenomenon that occurs when a valve closes suddenly, causing a pressure surge in the pipes. This can lead to loud banging noises and even damage to the plumbing system. The AI engine checks that water hammer arrestors are installed in suitable locations, such as near the water closet 176 or the sink 173, to absorb the shock and prevent damage.

In addition to water supply and drainage, the AI engine also considers the potential for backflow in the plumbing system. Backflow occurs when water flows backward through the system, potentially contaminating the clean water supply. The AI engine checks that backflow prevention devices, such as the valve 185A on the stack vent pipe 185, are installed in all necessary locations, particularly where there is a connection between the plumbing system and external water sources.

In some embodiments, the AI engine may evaluate the thermal expansion within the water supply system, particularly in hot water lines like pipe 179. Thermal expansion can cause pipes to expand and contract, leading to stress and potential leaks over time. The AI engine checks that expansion tanks or loops are installed in hot water systems to absorb this expansion and prevent damage to the pipes.

Referring now to FIG. 1H, it illustrates another exemplary water closet area 190 extracted by the AI engine from a design plan for detailed plumbing compliance analysis. The water closet area 190 presents several key bathroom fixtures, including a water closet 191, a sink 192, a bidet or closet water jet 193, a closet drainage pipe 194, and a mirror 195. Each of these components is subject to a thorough examination by the AI engine, which assesses their locations, placements, sizes, shapes, distances, and heights to determine compliance with applicable building codes.

The water closet 191 is a central fixture in this layout, and its placement relative to the surrounding walls and other fixtures is critically assessed by the AI engine. The distance 196 from the centerline 191A of the water closet 191 to the nearest side wall is measured to verify compliance. According to most plumbing codes, this distance should be at least 15 inches, allowing for adequate space on either side of the toilet for user comfort and accessibility. The AI engine confirms that this dimension is compliant, indicating that the water closet 191 has been positioned correctly in this regard.

However, the AI engine identifies several compliance issues in this layout. One such issue is the placement of the water jet 193, which is intended for use with the water closet 191. The AI engine notes that the water jet 193 is positioned too far from the water closet 191, which makes it inconvenient or difficult for users to operate. Typically, a water jet should be placed within easy reach of someone seated on the toilet, generally no more than 12 to 18 inches away. The AI engine flags this as non-compliant and suggests relocating the water jet 193 closer to the water closet 191 to improve usability and compliance.

The sink 192 and the mirror 195 are also examined by the AI engine. The AI engine detects that these two elements are not aligned, which can affect both the functionality and aesthetics of the bathroom. The mirror 195 should ideally be centered over the sink 192 to provide proper reflection for users while they are washing their hands or grooming. The AI engine may recommend adjusting the position of the sink 192 or the mirror 195 to achieve better alignment, which may enhance both the visual appeal and the practicality of the space.

Another compliance issue identified by the AI engine is the distance 197 between the water closet 191 and the sink 192. This distance is used for determining if there is enough room for users to move comfortably between fixtures. According to standard plumbing codes, the minimum distance between the front edge of a toilet and any opposite fixture, such as a sink, should be at least 21 inches. The AI engine measures this distance and determines that it falls short of the required minimum, flagging it as non-compliant. The AI engine may suggest moving either the sink 192 or the water closet 191 to increase the distance, thereby meeting the necessary code requirements.

To provide optimal automated suggestions, the AI engine carefully considers the impact of any proposed changes on the overall layout and compliance. For example, if the AI engine needs to recommend moving the water closet 191 to increase the distance between it and the sink 192, it also evaluates the consequences of this adjustment. The AI engine recognizes that such a move may still leave the sink 192 misaligned with the mirror 195 or bring the water closet 191 closer to the side wall, potentially creating new compliance issues. Therefore, before finalizing any suggestion, the AI engine assesses all related factors, so that the proposed modifications improve the layout without compromising the alignment of other fixtures or violating any other compliance requirement. This holistic approach allows the AI engine to offer the most effective solutions that maintain or enhance the overall functionality and compliance of the design.

The closet drainage pipe 194 is another area of concern. The AI engine observes that this pipe is exposed, which is often considered non-compliant in residential bathrooms. Exposed drainage pipes can pose several problems, including potential damage, unsightly appearance, and difficulties in cleaning. Most plumbing codes require that drainage pipes be concealed within walls or appropriately boxed in to prevent these issues. The AI engine recommends enclosing the closet drainage pipe 194 within a wall or cabinet to bring this aspect of the design into compliance.

The AI engine also evaluates the overall layout of the water closet area 190, considering how well the fixtures work together in the space. The AI engine analyzes the spatial relationships between the water closet 191, the sink 192, the water jet 193, and the mirror 195, so that each element is placed for maximum functionality and compliance. For example, the sink 192 should be positioned at a comfortable height, typically around 34 inches from the floor, to make it easily accessible for users of all ages. The AI engine checks the height of the sink 192 and provides recommendations for adjustment if necessary.

In addition to spatial relationships, the AI engine examines the sizes and shapes of the fixtures to determine if they are appropriate for the space. The water closet 191, for example, should be of a size that fits comfortably within the designated area without crowding other fixtures. The AI engine verifies if the dimensions of the water closet 191 are suitable for the room and if it meets all relevant code requirements for size and placement.

The AI engine further examines the safety aspects of the water closet area 190, particularly in relation to the exposed closet drainage pipe 194. Exposed pipes can pose a safety risk, especially in a bathroom where water and moisture are present. The AI engine recommends enclosing the pipe to reduce the risk of accidents or injuries, such as tripping over the pipe or contact with sharp edges.

The AI engine further assesses the plumbing connections in the water closet area 190, particularly the connections between the sink 192 and the plumbing system. The AI engine checks that the connections are secure and free from leaks, providing recommendations for any necessary repairs or adjustments.

The AI engine evaluates the overall design of the water closet area 190 for compliance with local building codes. The AI engine checks that the layout, fixtures, and materials all meet the required standards and provides recommendations for bringing any non-compliant aspects into compliance.

Finally, the AI engine provides a comprehensive report on the water closet area 190, detailing any issues found and offering suggestions for improvement. The report includes recommendations for bringing the design into compliance with building codes, improving usability and safety, and enhancing the overall functionality and appearance of the bathroom.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references. For example, the AI engine may identify the locations of toilets and sinks to determine if they are positioned correctly relative to walls and doorways for compliance with plumbing codes.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; complexity of features (e.g. a number of angles or curves included in a perimeter of an area; a type of hardware that may be used to construct a portion of a building, a quantity of a type of hardware that may be used to construct a portion of the building; or other variable value. For example, the AI engine may calculate the total number of plumbing fixtures in a given area and compare it with the requirements set by the relevant code.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). Other features may be removed, such as the text 208, the plumbing features and other internal appliances and furniture which may be shown on drawings used as input to the processing. Again, such feature recognition may be useful to accomplish other goals, but for a goal of boundary 211 definition that delineates a floorplan 210 as illustrated in FIG. 2B a pictorial representation may be purposefully devoid of such features, as illustrated. This simplification allows the AI engine to focus on essential structural elements, so that boundary definitions are precise and unencumbered by unnecessary details.

Referring now to FIG. 2B, a boundary 211 is illustrated around a grouping of defined spaces 213-216. Spaces are areas within a boundary (which may include, but are not limited to rooms, hallways, stairwells etc.). For example, the AI engine may identify a bathroom area and outline its boundary, to determine if all required plumbing fixtures are within this space and correctly positioned relative to one another.

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A. This distinction is critical for the AI engine to accurately determine the spatial relationships between plumbing fixtures and other structural elements to evaluate compliance with building codes.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. Boundaries that include polygons are useful, for example in creating a three-dimensional representation of a design plan. This three-dimensional representation can then be analyzed for plumbing compliance, to determine if all plumbing fixtures are placed within appropriate spaces and meet spatial requirements such as clearance and accessibility.

According to the present invention, a boundary may be represented on a user interface as one or both of: one or more line segments, and one or more polygons. In addition, a feature may be represented as a single point, a polygon, an icon, or a set of polygons. In some embodiments, a point may be placed in a centroid position for the feature and the centroid points may be counted, summarized, subtracted, averaged, or otherwise included in mathematical processes. For example, the AI engine may place a centroid at the center of a sink and calculate its distance from nearby walls to verify compliance with clearance requirements.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. Extrapolation of a two-dimensional reference into a three-dimensional representation may be supported with a boundary that includes polygons. This capability allows the AI engine to perform complex spatial analyses, such as verifying that plumbing fixtures are correctly spaced within a room and that their placement adheres to code requirements.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Typical units referenced in a scale include inches: feet, centimeters: meters, or any other appropriate unit. For example, if the scale indicates that each pixel represents one inch, the AI engine can accurately calculate the distance between a toilet and a sink to determine compliance with spacing requirements specified by the relevant plumbing code.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. This scaling process is essential for the AI engine to accurately assess the size and spacing of plumbing fixtures within the design plan, to determine if they comply with all relevant codes and regulations.

Referring now to FIG. 2C, a user interface 220 is illustrated with multiple regions 221-224. The multiple regions 221-224 may be presented via different hatch representations or other distinguishing pattern (in some embodiments regions may also be represented as various colors etc.). During training of AI engines, and in some embodiments, when a submitted design drawing includes highly customized or unique features, a user may wish to adjust an automated identification of boundaries and automated filling of space within the boundaries. For example, if the AI engine incorrectly identifies a kitchen area as a bathroom due to unusual layout features, the user can manually adjust these boundaries in the interface.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine. This allows users to make manual corrections where the AI engine's automatic boundary assignments are not accurate enough, especially in complex areas like multi-functional rooms where plumbing fixtures may serve multiple purposes.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, or change an aspect of polylines, polygons, arcs, circles, ellipses, splines, NURBS or predefined subsets of the interface. The user can thereby “correct” an assignment error made by the AI engine, or simply rearrange aspects included in the interface for a particular purpose or liking. For example, if a user needs to adjust the boundary of a bathroom area to accommodate a specific number of fixtures, the user interface allows these adjustments to be made easily, thereby enhancing the accuracy of the plumbing compliance analysis.

In some embodiments, modifications and/or corrections of this type can be documented and included in training datasets of the AI model, also in processes described in later portions of the specification. This feedback loop allows the AI engine to improve over time, becoming more accurate in identifying and categorizing spaces and plumbing fixtures in future analyses.

Discrete regions may be regions associated with an estimation function. A region that is contained within a defined wall feature may be treated in different ways such as ignoring all area in a boundary, to counting all area in a boundary (even though regions do not include boundaries). If the AI engine counts the area, it may also make an automated decision on how to allocate the region to an adjacent region or regions that the region defines. For example, if a bathroom and a hallway share a boundary, the AI engine may allocate space between these areas so that plumbing fixtures like sinks and toilets have sufficient clearance.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. Regions with similar dominance rank may share space, or regions with higher dominance rank may be automatically assigned to a boundary. For example, a kitchen may take precedence over a pantry in terms of space allocation, so that all necessary plumbing fixtures are correctly placed. In general, a dominance ranking schema will result in an area being allocated to the space with the higher dominance rank. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified.

In some embodiments, an area 235A between interior boundaries 236-237 and an exterior boundary 235 may be fully assigned to an adjacent region 232-234. An area between interior boundaries 235A may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. Parameters may also be based upon items that are automatically counted using AI analysis of pixel patterns that identifies a pattern as an item, such as, by way of non-limiting example, one or more of: doors or other paths of egress; plumbing fixtures; fixed obstacles; stairs; inclines; and declines. For instance, if a bathroom is identified as a dominant space, the AI engine may allocate more area to accommodate additional plumbing fixtures, providing compliance with relevant codes.

In some examples, a boundary 235-237 and associated area 235A may be allocated to a region 232-234 according to an allocation schema, such as, for example, an area dominance hierarchy, to a prioritize a kitchen over a bathroom, or a larger space over a smaller space. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region as illustrated in FIG. 2D. In various embodiments, different calculated features are included in a user interface floorplan model 231 such as features representing aspects of a wall, such as, for example, center lines, the extents of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence a decision on compliance with a local code.

Once boundaries have been defined a variety of calculations may be made by the system. A controller may be operative to perform method steps resulting in calculation of a variable representative of a floorplan area, which in some embodiments may be performed by integrating areas between different line features that define the regions. For example, the AI engine may calculate the total floor area allocated for restrooms to determine if the number of plumbing fixtures is adequate for the expected occupancy load.

Alternatively, or in addition to method steps operative to calculate a value for a variable representative of an area, a controller may be operative to generate a value for element lengths, which values may also be calculated. For example, if ceiling heights are measured, presented on drawings, or otherwise determined, then volume for the room and surface area calculations for the walls may be made. There may be numerous dimensional calculations that may be made based on the different types of model output and the user inputted calibration factors and other parameters entered by the user. These calculations may include determining the slope of drainage pipes or the height of sinks and toilets from the floor to confirm that these fixtures meet code requirements.

In some embodiments, a controller may be provided with two-dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects, further enhancing the accuracy of plumbing compliance analysis by considering vertical clearances and the routing of plumbing pipes across different floors.

Referring now to FIGS. 2E-2F, these figures illustrate exemplary plumbing fixtures extracted by the AI engine from a design plan for the purpose of conducting detailed plumbing compliance analyses.

FIG. 2E depicts a water closet 240, accompanied by a lavatory 241, with precise measurements required for compliance with relevant codes. The centerline 240A of the water closet 240 is situated at a minimum distance of 80″ from the lavatory 241, which may be a standard requirement (as per some codes) to provide sufficient separation between these two fixtures. This distance is necessary to maintain a functional and accessible layout, allowing users ample space to maneuver between the fixtures without obstruction. The AI engine determines if this minimum distance is maintained to avoid any non-compliance issues that could arise from overcrowded or poorly planned bathroom layouts.

In addition to the lateral spacing, FIG. 2E also specifies the required front clearance 242 from the water closet 240. The front clearance 242 is another critical feature for providing sufficient room in front of the water closet 240 for ease of use, whether the user is sitting or standing. FIG. 2E indicates that there must be a minimum width of 60″ (243) in the front area, along with a minimum length of 66″ (244). These dimensions are required for the water closet area to be accessible and comfortable for all users, including those with mobility aids such as wheelchairs.

FIG. 2F presents a lavatory 245, which is positioned at a specific distance from the side wall. This minimum distance is required for maintaining accessibility and usability of the lavatory 245 in bathroom designs. Although the exact measurement is not provided in the description, typical plumbing codes often require that a lavatory be positioned at least 15 to 18 inches away from a side wall to allow sufficient space for the user to comfortably access and use the sink 245. This clearance is important for avoiding any physical constraints that could hinder the functionality of the lavatory or create discomfort for the user.

The AI engine analyzes these measurements to verify that the design complies with all applicable building codes. By verifying that the proper spacing and alignment of fixtures like the water closet 240 and the lavatory 245, the AI engine helps to create bathroom layouts that are both functional and code-compliant. This process may involve checking that the distances between fixtures, as well as the clearances around them, meet the required standards to avoid any issues that may compromise the safety or usability of the space.

Referring now to FIGS. 2G-2H, these figures illustrate exemplary water closets with different configurations of water tanks in relation to the surrounding wall structures, showcasing how the AI engine can assess and recommend the most appropriate setup for a given space.

FIG. 2G depicts a water closet 250A equipped with a water tank 251A positioned directly in front of a wall 252A. This configuration is commonly referred to as an exposed or front-mounted water tank. In this setup, the water tank is fully visible and attached to the rear of the toilet 250A, with the wall serving as a simple backdrop. The AI engine assesses this type of water tank installation to determine whether it meets compliance requirements, particularly in terms of space utilization, accessibility for maintenance, and overall aesthetic considerations. An exposed water tank like the one shown in FIG. 2G is often easier to install and maintain since all components are readily accessible. However, it occupies more space and may not be ideal in smaller bathrooms where every inch of space is valuable.

FIG. 2H, on the other hand, illustrates a different setup where the water closet 250B features a water tank 251B that is located behind a wall 252B. This configuration is known as a concealed or in-wall water tank. The water tank is hidden within the wall 252B, with only the toilet bowl 251B visible. The AI engine evaluates this setup for its benefits in terms of space-saving and modern aesthetics. Concealed water tanks, as shown in FIG. 2H, are often preferred in contemporary bathroom designs where a minimalist appearance is desired. This setup frees up floor space, making the bathroom appear larger and less cluttered. However, concealed tanks may require more complex installation procedures and can be more challenging to access for repairs, which the AI engine may take into account when determining compliance or recommending this type of tank.

The AI engine may recommend a concealed water tank, like the one in FIG. 2H, in situations where space optimization is a priority, such as in small apartments or bathrooms with limited floor area. The AI engine may assess the available space, the structural integrity of the wall intended to house the tank, and the accessibility needs for maintenance. For example, if the bathroom design prioritizes a sleek, modern look with clean lines, the AI engine may suggest opting for the concealed tank to enhance the visual appeal and create a more open environment.

Conversely, the AI engine may recommend an exposed water tank, as shown in FIG. 2G, in settings where ease of access for maintenance is a top concern or where the bathroom has ample space that does not require the compactness of a concealed setup. Exposed tanks are generally easier to install and repair, as all components are immediately accessible without the need to remove wall panels or tiles.

Furthermore, the AI engine may suggest a hybrid approach depending on the specific needs of the design. For example, in a high-end residential project, the AI engine may recommend a concealed tank for the main bathroom to achieve a luxurious, modern aesthetic, while suggesting exposed tanks in secondary bathrooms where maintenance considerations are more pressing. The AI engine balances the following factors: space, aesthetics, ease of maintenance, and cost, before providing a final recommendation.

Additionally, the AI engine may evaluate the compliance of each setup with local plumbing codes and standards. For example, it may check the structural requirements for supporting a concealed tank within a wall, such as the need for reinforced framing to bear the weight of the tank and water. It may also assess whether the exposed tank provides sufficient clearance around the toilet for comfortable use and meets any specific code requirements regarding the distance between the tank and other bathroom fixtures.

Referring now to FIG. 2I, it illustrates an exemplary shower connection layout 260 that the AI engine may analyze for compliance or fault detection in the plumbing system. The layout 260 includes a showerhead 261, which is connected to both hot and cold water inlets, 262 and 263 respectively. The flow of water to the showerhead 261 is controlled by a knob 264, which regulates the mix of hot and cold water to achieve the desired temperature.

A cold water supply pipe 266 is connected to the cold water inlet 263 via a temperature valve 265. The valve 265 plays a vital role in regulating the water temperature by mixing the hot and cold water flows to prevent scalding. The temperature valve 265 is designed to control the maximum temperature of the water delivered to the showerhead 261, which is typically set to a safe limit, such as 120° F. (49° C.), to protect users from the risk of burns.

However, the AI engine detects a significant issue in this layout: the hot water inlet 262 is directly connected to the hot water supply pipe 267 without passing through the temperature valve 265. The correct configuration should involve the hot water supply pipe 267 being routed through the temperature valve 265 before it reaches the hot water inlet 262, using the designated inlet 268 and outlet 269 on the valve. The absence of this connection introduces a non-compliant and potentially hazardous situation, as it allows hot water to flow directly to the showerhead 261 without any temperature regulation.

The direct connection of the hot water supply pipe 267 to the hot water inlet 262 bypasses the critical safety mechanism provided by the temperature valve 265. Without the temperature valve, the hot water can reach dangerously high temperatures, posing a significant risk of scalding to users. The AI engine recognizes this flaw in the connection layout 260 and flags it as non-compliant with safety standards that require the use of temperature-regulating devices in shower installations to protect users.

The temperature valve 265 automatically adjusts the proportion of hot and cold water mixed in the shower, maintaining a consistent and safe water temperature. If the valve detects that the water temperature is rising beyond the safe limit, it reduces the flow of hot water and increases the flow of cold water to prevent the water from becoming too hot. This safety feature is especially important in households with young children, elderly individuals, or others who may be more vulnerable to burns.

Given the non-compliance detected in FIG. 2I, the AI engine may provide recommendations to rectify the issue. The AI engine may suggest rerouting the hot water supply pipe 267 through the temperature valve 265, utilizing a temperature valve inlet 268 and temperature valve outlet 269 specifically designed for this purpose. The correction would allow both the hot and cold water supplies to be properly regulated by the temperature valve 265 before reaching the showerhead 261, thus making the system safe and compliant with relevant building codes.

Moreover, the AI engine may recommend a review of the entire plumbing setup to identify any similar issues elsewhere in the system. This may involve checking other water outlets, such as sinks or bathtubs, to determine that they are also equipped with temperature-regulating devices. Additionally, the AI engine may suggest the installation of pressure-balancing valves in conjunction with the temperature valve to further enhance the safety and functionality of the shower system by maintaining consistent water pressure.

In addition to safety concerns, the AI engine may also evaluate the long-term reliability of the system. Direct connections that bypass safety devices not only pose immediate risks but can also lead to wear and tear on the plumbing components due to unregulated water temperature fluctuations. Over time, this can result in leaks, pipe damage, or failure of the showerhead 261 and other components. The AI engine's recommendation to correct the hot water connection through the temperature valve may help to prevent these issues, prolonging the lifespan of the shower system and reducing maintenance costs.

Finally, the AI engine may also suggest upgrading the temperature valve 265 to a modern thermostatic mixing valve if the existing valve is outdated or not functioning optimally. Thermostatic valves offer more precise temperature control and quicker response times to temperature changes, further enhancing the safety and comfort of the shower experience.

Referring now to FIG. 2J, it illustrates an exemplary water heater (geyser) connection layout 270, which the AI engine may analyze for compliance and to detect any potential faults in the connection. The water heater 271 is depicted with several critical connections and safety features designed to regulate the water heating process and protect the plumbing system from potential hazards.

The water heater 271 features a cold water inlet 272, where cold water enters the heater, and a hot water outlet 273, from which heated water exits and may be distributed throughout the building. A first pressure relief valve 273A is installed near the hot water outlet 273. The pressure relief valve 273A is used for preventing the buildup of excessive pressure within the water heater 271. If the water inside the heater 271 reaches a temperature or pressure beyond the safe limit, the pressure relief valve 273A automatically opens to release some of the water, thereby reducing the pressure and preventing a potential explosion or rupture of the tank. The AI engine carefully evaluates the placement and functionality of the pressure relief valve 273A to determine if it is installed correctly and is capable of responding effectively in an overpressure situation.

The cold water inlet 272 is connected to a cold water supply line 279, which is equipped with several control elements to manage water flow and maintain system safety. One of these elements is the expansion tank 274. The expansion tank 274 is designed to absorb the excess water volume that results from the thermal expansion of water as it heats up in the water heater 271. Without an expansion tank, the increased pressure from expanding water can cause stress on the water heater 271 and the surrounding plumbing, leading to potential leaks or system failures. The AI engine analyzes the expansion tank's size and installation to determine if it is adequate for the capacity of the water heater 271 and the demands of the plumbing system.

In addition to the expansion tank 274, the cold water supply line 279 may include a pressure gauge 275, which monitors the water pressure within the system. The pressure gauge 275 allows for real-time observation of pressure levels, helping to identify any issues that may arise, such as a sudden increase in pressure that can indicate a malfunction in the system. The AI engine checks the calibration and placement of the pressure gauge to verify that it provides accurate readings and is positioned where it can be easily accessed and monitored.

A second pressure relief valve 276 may also be installed in the cold water supply line 279, adding another layer of protection against excessive pressure. The second pressure relief valve 276 works similarly to the first pressure relief valve 273A, but its location on the cold water side provides additional security by releasing pressure before it even reaches the water heater 271. The AI engine evaluates the necessity and functionality of this second pressure relief valve 276, particularly in high-pressure systems where multiple safety mechanisms are required to manage water pressure effectively. The water supply line 279 may also comprise a backflow prevention valve 277 for preventing hot water from the geyser 271 flowing back to the water supply line 279.

A water supply on/off knob 278 allows the user to shut off the water supply to the heater 271 for maintenance, repairs, or emergency situations. The AI engine checks that this knob is easily accessible and that it functions smoothly, allowing for quick shutoff when needed. Proper placement and functionality of the on/off knob 278 are required for user safety and for the maintenance of the water heating system.

The water heater 271 may also comprise a top outlet 284, which may be used for various purposes, such as connecting to additional plumbing fixtures or systems that require hot water. The AI engine may assess whether the use of this outlet is necessary and whether it is properly connected so that it does not compromise the integrity of the overall system. The correct utilization of this outlet is important for maintaining balanced water distribution and preventing any unnecessary strain on the water heater 271.

Joints 283 in the piping system are another focus of the AI engine's analysis. These joints, where pipes are connected, can be potential weak points in the system if not properly installed or maintained. Faults in these joints, such as leaks or improper sealing, can lead to water damage, reduced system efficiency, and increased maintenance costs. The AI engine examines each joint for signs of wear, improper installation, or potential failure, providing recommendations for repair or reinforcement where necessary to maintain system integrity.

Apart from analyzing the water heater connections, the AI engine also evaluates the floor drain 280 and its associated drainage system. The floor drain 280 is designed to collect any water that may spill from the water heater or other nearby fixtures, directing it safely to the drainage system. However, the AI engine may identify that the drainpipe 282 connected to the floor drain 280 is faulty e.g., having uneven turns, bends or connections. This can manifest as a blockage, improper slope, or even a leak, all of which may prevent the floor drain 280 from functioning properly. A faulty drain can lead to water pooling on the floor, creating a slip hazard and potentially causing water damage to the surrounding area.

Based on the analysis, the AI engine may provide several recommendations to address the faults detected in this connection layout. For the pressure relief valves 273A and 276, the AI engine may suggest regular testing and maintenance so that they remain functional over time, as well as checking for any signs of corrosion or blockage that can impair their operation. For the expansion tank 274, the AI engine may recommend verifying that it is properly sized for the system and checking the internal bladder for signs of wear that may reduce its effectiveness.

Regarding the faulty drainpipe 282, the AI engine may recommend a thorough inspection to identify the exact nature of the fault, followed by appropriate corrective action. This may involve clearing a blockage, repairing a leak, or adjusting the slope of the drain pipe to provide proper drainage. The AI engine may also suggest adding a secondary drainage route as a backup in case the primary drain fails, particularly in high-risk areas where water damage can be costly or difficult to repair.

The AI engine may also recommend a review of the entire water heating system to identify any other potential issues or areas for improvement. This may include upgrading the water heater itself, particularly if it is an older model that lacks modern safety features or energy efficiency standards. The AI engine may suggest installing additional temperature controls, insulating pipes to reduce heat loss, or even integrating the system with a building management system for better monitoring and control.

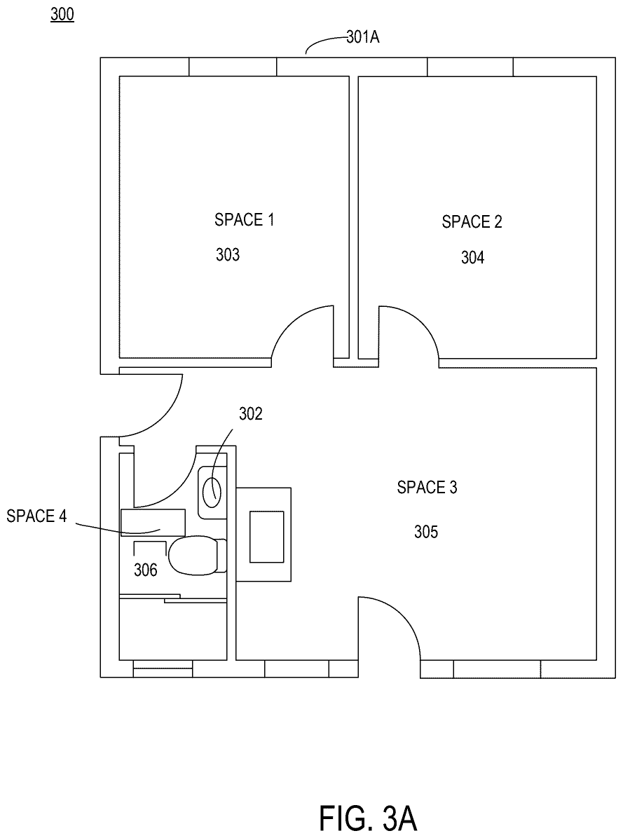

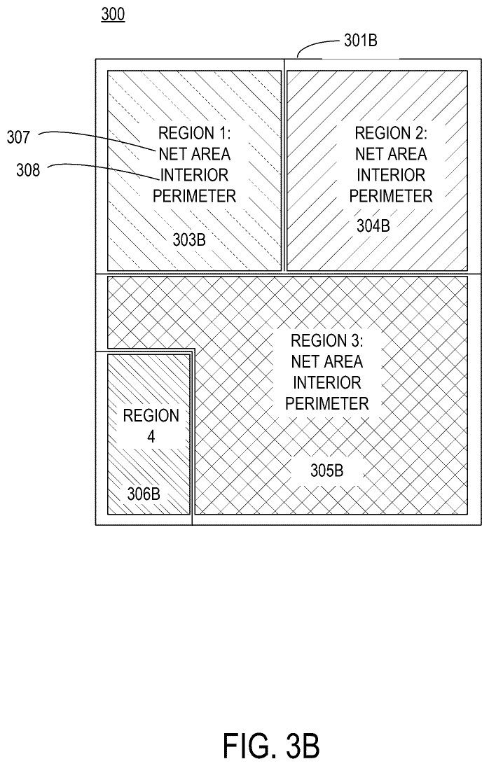

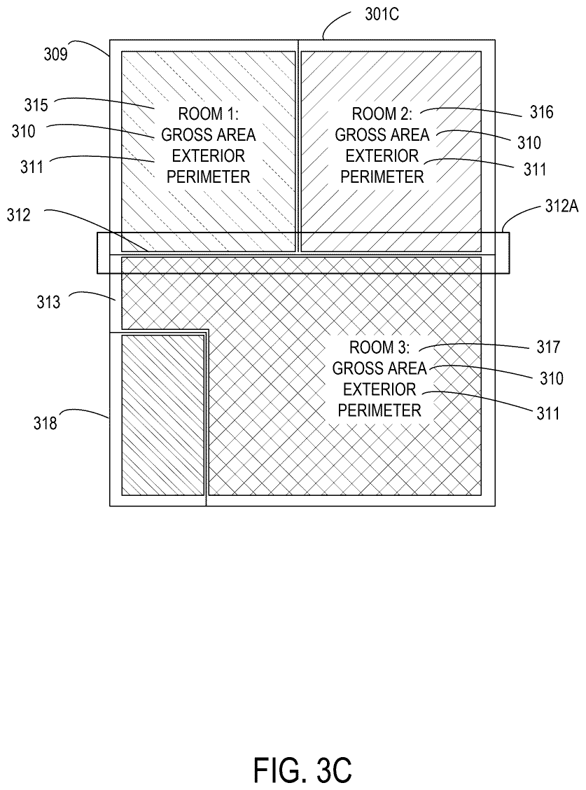

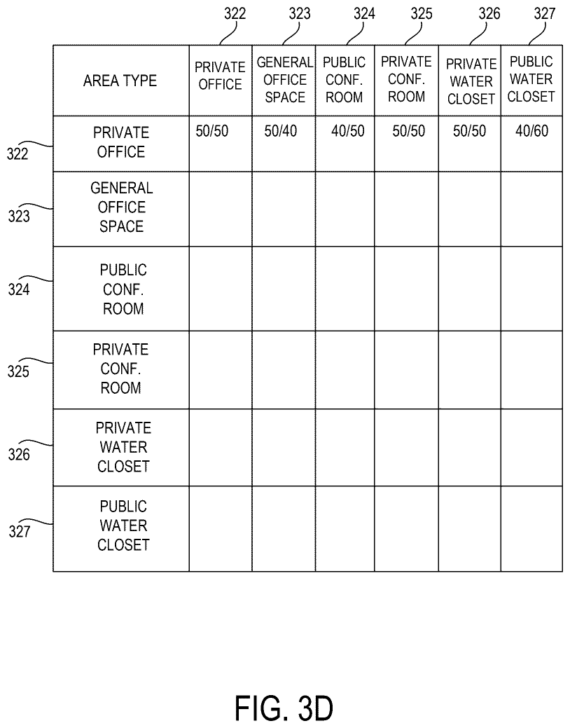

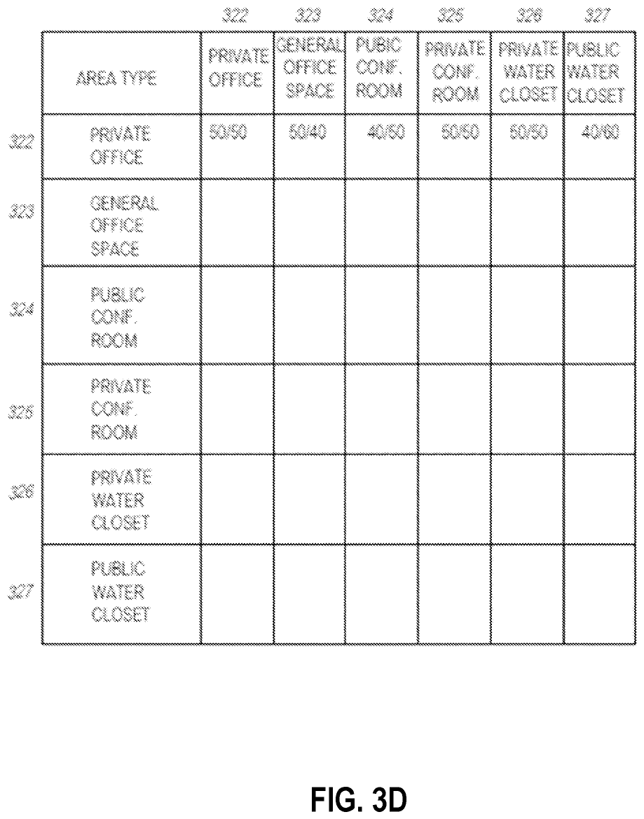

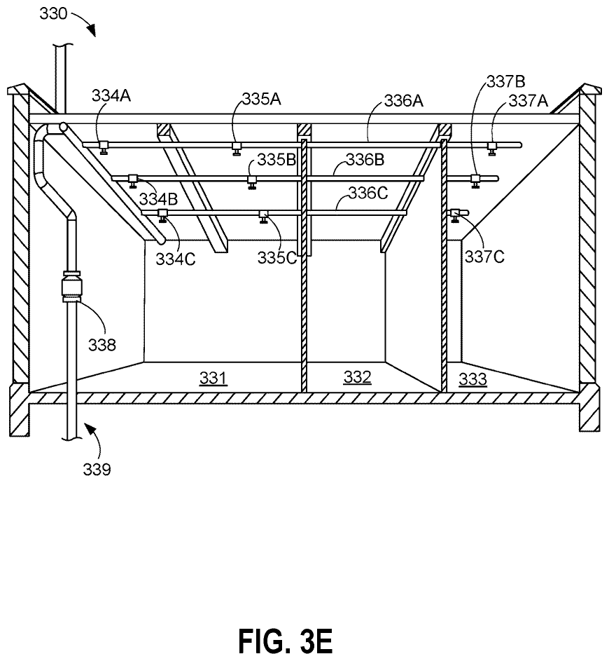

Referring now to FIGS. 3A-3C a user interface 300 may generate multiple different user views, each view has different aspects related to the two-dimensional reference drawing inputted. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, these spaces may represent different rooms or areas within a building, such as bathrooms, kitchens, or utility rooms, which the AI engine will later analyze for plumbing compliance. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. For example, if the AI engine does not recognize a newly designed water closet, the user can manually classify it as such, allowing the system to tally this fixture type accurately. The controller may generate a tally of multiple fixtures 302 identified in the two-dimensional reference. The tally of multiple fixtures 302 may include some or all of the fixtures identified in the two-dimensional reference and be used to generate an estimate for completion of a project illustrated by, or otherwise represented by, the two-dimensional reference.

Referring now to FIG. 3B, wherein in the user interface 300, a user may specify to a controller that a one of multiple views available to presented via the interface. For example, a user may designate via an interactive portion of a screen displaying the user interface 300 that a region view 301B be presented. The region view 301B may identify one or more regions and/or spaces 303B-306B identified via processing by a controller, such as for example via an AI engine running on the controller. The AI engine may, for example, automatically delineate a bathroom area based on the clustering of plumbing fixtures like sinks, toilets, and showers, presenting this in the region view for further analysis. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated as a bathroom, and the system may automatically suggest waterproof flooring and wall materials based on this designation.

Referring now to FIG. 3C a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space, but may be less useful to an occupant than a net interior area 307 and interior perimeter 308. For plumbing compliance, the AI engine may analyze both net and gross areas to determine whether sufficient space is available for required plumbing fixtures, so that bathrooms have adequate floor area for compliance with accessibility standards. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior). For example, if the AI engine detects that a bathroom's ceiling height is below the minimum required for proper ventilation or fixture installation, it may flag this as a compliance issue, providing suggestions for rectifying the situation.

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms. These outputs are particularly useful in verifying that sufficient space has been allocated for plumbing systems, so that large commercial restrooms have enough gross area to meet code requirements for the number of fixtures and user capacity.

In some embodiments, the present invention calculates an area bounded within a series of polygon elements (such as, for example, using mathematical principals or via pixel counting processes), and/or line segments. For example, the AI engine may calculate the area of a bathroom based on its polygonal boundaries and determine whether it is large enough to accommodate the necessary number of plumbing fixtures while maintaining code-mandated clearances around each fixture.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like. These calculations are used for determining whether spaces such as restrooms or kitchens meet spatial requirements for plumbing fixtures, particularly when dealing with complex room shapes or layouts.

These views may be used in generating estimation analysis documents. Estimation analysis documents may rely on fixtures, region area, or other details. By assisting in generating net area, estimation documents may be generated more accurately and quickly than is possible through human-engendered estimation parameters. For example, the system may generate a report estimating the materials needed to install a complete plumbing system in a new residential development, including piping, fixtures, and related hardware, based on the analyzed floor plan.

With reference now again to FIGS. 3B and 3C, regions 303B-306B defined by an AI engine may include one or more Rooms in FIG. 3B subsequently have regions assigned as “Rooms” in FIG. 3C. For example, if the AI engine identifies a region as a kitchen in FIG. 3B, it will carry over this classification into FIG. 3C for further detailed analysis, such as determining whether the kitchen has sufficient plumbing infrastructure to support appliances like dishwashers and sinks.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example adjacent areas (e.g., area 315 and area 317 or area 317 and area 318). This hierarchical relationship may be used to prioritize the allocation of space between different functional areas in a building, such as prioritizing a larger restroom area over a smaller storage room to comply with building codes. The hierarchical relationship may be used to generate a dominance ranking of one area of another area, or to ascertain factors useful in determining whether a building is in compliance with an applicable code. For example, a dominance ranking may allocate space used to calculate one or more of: an occupancy load; a width and/or area of an egress path; a width and/or area of a common path; a length of a dead end; egress capacity; and travel distance from a furthest point.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ration, but a private office adjacent to a general office space may be allocated 60 percent of an area included in a border region, and so on. This feature allows for fine-tuning of space allocation, so that each area meets its intended purpose while also complying with plumbing and building codes. Dominance associated with various areas may be systemic throughout a project, according to customer preference, indicated on a two-dimensional reference by two-dimensional reference basis or another defined basis.

Referring now to FIG. 3E, it illustrates an exemplary portion 330 of a design plan featuring a sprinkler system, which the AI engine uses for conducting plumbing compliance analyses. The design portion 330 consists of three distinct spaces 331, 332, and 333, which may represent different rooms, zones, or sections within a building. These spaces may vary in purpose, such as a storage area, an office, or a corridor, each requiring specific water sprinkler coverage to meet fire safety regulations. The sprinkler system is an integral part of the building's fire protection strategy, and the AI engine assesses whether the sprinkler system is adequately designed to function effectively during an emergency.

The sprinkler system is supplied with water through a main water supply line 339, which distributes water to the sprinkler system across multiple floors of the building. The water supply line 339 is responsible for maintaining consistent water pressure and flow to the sprinklers, allowing that they activate properly in the event of a fire. The AI engine may analyze the main water supply line 339 to verify that it is correctly sized, free from obstructions, and capable of delivering the necessary volume of water to all connected sprinklers throughout the building. The system's capacity is critical in determining whether the sprinklers can sustain water flow long enough to control or extinguish a fire.

In its analysis, the AI engine examines the configuration and placement of sprinklers within each space to assess their effectiveness. For example, the AI engine verifies that spaces 331 and 333 have an adequate number of sprinklers installed at strategic locations, denoted as sprinklers 334A, 334B, 334C, 335A, 335B, 335C in space 331, and 337A, 337B, 337C in space 333. These sprinklers are positioned to provide maximum coverage, so that in the event of a fire, the water disperses evenly across the entire area. The AI engine assesses the spacing between each sprinkler, checking that it adheres to building codes, which often stipulate a maximum distance between sprinklers to prevent any gaps in coverage.

However, the AI engine may identify a significant issue in space 332, where it detects that the necessary sprinklers at points 336A, 336B, and 336C are missing. This omission poses a serious risk, as the absence of sprinklers in a specific area can result in uncontrolled fire spread, leading to greater damage and potentially endangering lives. The AI engine flags this deficiency and suggests immediate corrective action, such as the installation of sprinklers to meet the coverage requirements for that particular space. The AI engine also provides detailed recommendations on the precise placement or location of the new sprinklers to optimize fire suppression efficiency.

In addition to identifying missing sprinklers, the AI engine also checks for any sprinklers that may be improperly placed. For example, sprinklers should not be positioned too close to walls, beams, or other obstructions that can impede the water spray pattern. If the AI engine detects any such misplacement, it may recommend relocating the affected sprinklers to more appropriate positions, so that they can operate effectively in case of a fire. The AI engine's analysis is guided by stringent building codes that dictate the minimum and maximum distances for sprinkler placement relative to walls, partitions, and other potential obstructions.

Moreover, the AI engine also evaluates whether the sprinklers installed in spaces 331, 332, and 333 are of the correct type and capacity for the specific environment they are intended to protect. For example, certain areas may require high-temperature-rated sprinklers if they are exposed to higher ambient temperatures, such as in a boiler room or kitchen. The AI engine checks that the correct sprinkler types are used and that they are rated appropriately for the conditions they will face. If an incorrect sprinkler type is detected, the AI engine may recommend replacement with a more suitable model to comply with fire safety standards.

The AI engine also scrutinizes the overall design of the sprinkler system, including the routing and connections of pipes, to identify any potential weaknesses or points of failure. Joints 283, where pipes are connected, are carefully examined for any signs of leaks, corrosion, or improper installation. Leaks at these joints can lead to reduced water pressure, which in turn may impair the performance of the sprinkler system during a fire. The AI engine assesses whether all joints are properly sealed and securely fastened, and it may suggest reinforcement or replacement if any deficiencies are found.

Additionally, the AI engine evaluates the main water supply line 339 for adequate capacity and pressure. If the line is too small or if the pressure is insufficient, the entire sprinkler system may be compromised. The AI engine may simulate various fire scenarios to determine if the system can maintain the necessary pressure and flow rate to keep all sprinklers operational. It may recommend upgrading the main supply line or adding booster pumps if the current setup is deemed inadequate.

The AI engine may also consider the layout of each space in relation to the sprinkler coverage. For example, in space 331, if there are large obstructions such as shelving units or machinery, the AI engine may assess whether these can block the water spray from reaching certain areas. It may then recommend adjustments to the sprinkler layout or suggest alternative fire protection measures, such as additional sprinklers installed around the obstruction or the use of high-pressure nozzles to penetrate the blockage.

In its comprehensive analysis, the AI engine also evaluates the integration of the sprinkler system with other fire protection systems, such as alarms, smoke detectors, and fire control panels. It also verifies that the sprinkler system is synchronized with these components, enabling a coordinated response in the event of a fire. For example, the AI engine checks that the activation of sprinklers triggers the appropriate alarms, and that the system is monitored by the building's fire control panel for real-time status updates.

Additionally, the AI engine may simulate different fire scenarios to assess the sprinkler system's effectiveness under various conditions. This simulation helps identify any potential weaknesses in the system's design, such as areas where the water coverage is insufficient or where the system may be slow to activate. Based on these simulations, the AI engine provides detailed recommendations to enhance the system's performance, so that it can effectively contain or extinguish fires in all possible scenarios.

The AI engine also considers the impact of maintenance practices on the sprinkler system's reliability. Regular inspections and testing are critical to maintaining the system's readiness. The AI engine may recommend a maintenance schedule based on the system's age, usage patterns, and environmental conditions. It may also suggest specific tests, such as flow tests or pressure checks, to verify that the system remains in optimal working condition.

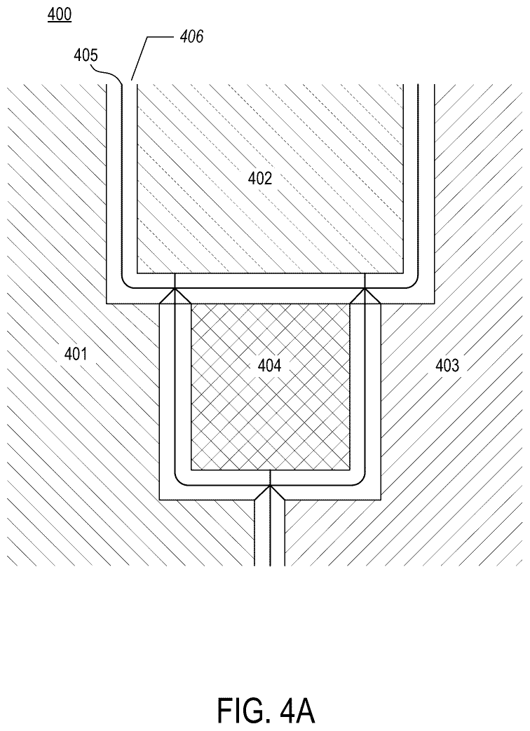

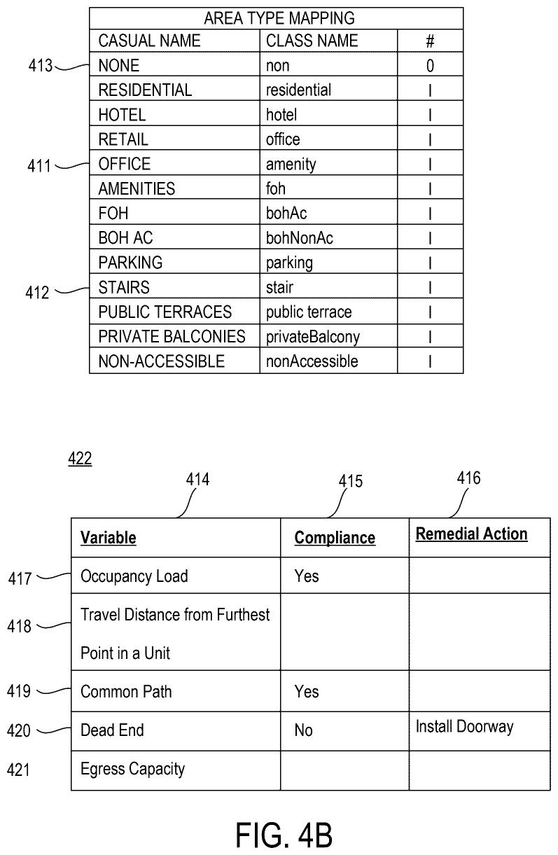

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure. For example, the AI engine may analyze these boundaries to determine how different regions such as bathrooms, kitchens, and utility spaces are defined and interconnected, providing a foundation for further compliance checks.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. For example, a bathroom may be ranked higher in dominance than a storage room if plumbing compliance is the primary focus, thereby influencing how boundary space is allocated and analyzed. Different classes or types of spaces or areas may be scored to be equal to, dominant (e.g., above) others or subservient (e.g., below) others.

Referring now to FIG. 4B, an exemplary table A indicating classes of space types and their associated ranks. In some embodiments, a controller may be operative via execution of software to determine relative ranks associated with a region on one or either side of a boundary. For example, area 402 may represent office space and area 404 may represent a stair well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas. For example, a report may highlight how the reallocation of space affects overall plumbing fixture counts or compliance with ADA requirements.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect compliance with conditions that must be met in order to be compliant with a code, such as, for example, compliance and remedial actions. For example, occupancy load 417 may dictate the number of plumbing fixtures required in a particular space, while travel distance from a furthest point 418 may influence the placement of fixtures so that they are within code-specified proximity. Variables 417-421 may include occupancy load 417, travel distance form a furthest point 418, Common path 419, dead end 420, and egress capacity 421.

### Area Takeoff Classification

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. This process may, for example, classify different regions within a floor plan as residential, commercial, or mixed-use based on the dominant features detected within each region, influencing subsequent compliance checks. As mentioned, this can be important to support processes executed by a controller that assign boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. For example, an AI engine may classify all bathroom spaces within a building, allowing the user to quickly verify whether these spaces collectively meet the building's plumbing requirements for fixture counts and spacing. There may be numerous functionalities and purposes for automatic classification of regions from an input drawing.

An AI engine or other process executed by a controller may be refined, trained, or otherwise instructed to utilize a number of recognized characteristics to accomplish area classification. For example, the AI engine may learn to classify rooms based on their geometric shapes, typical sizes, or the presence of specific fixtures like sinks or toilets, which are commonly associated with bathrooms. An AI engine may base predictions for a type “/“category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of recognized text may provide direct evidence upon which to infer a decision. For example, a recognized textual label such as “Restroom” in a region may allow the AI engine to automatically assign this area as a bathroom, and accordingly, classify neighboring spaces like adjoining corridors or lobbies with relevant categories for further analysis. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces, like rectangular kitchens or square utility rooms, may be well-represented in training sets used to instruct the AI engine, thereby enhancing the accuracy of space classification. Common shapes of certain spaces may allow a training set to train a relevant AI engine to classify a space with added accuracy. Furthermore, certain space classes may typically fall into ranges of areas which also may aid in the identification of a region's class. Accordingly, it may be important to influence the makeup of training sets for classification that contain common examples of various classes as well as common variations on that theme.

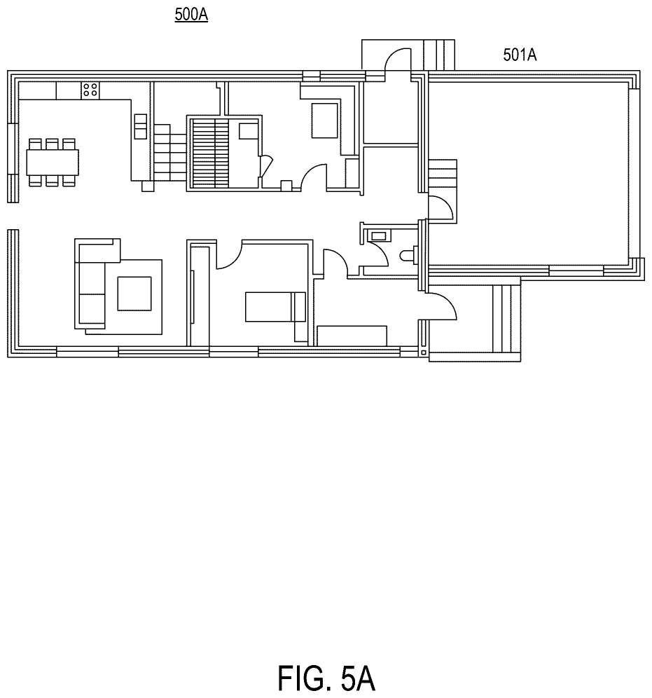

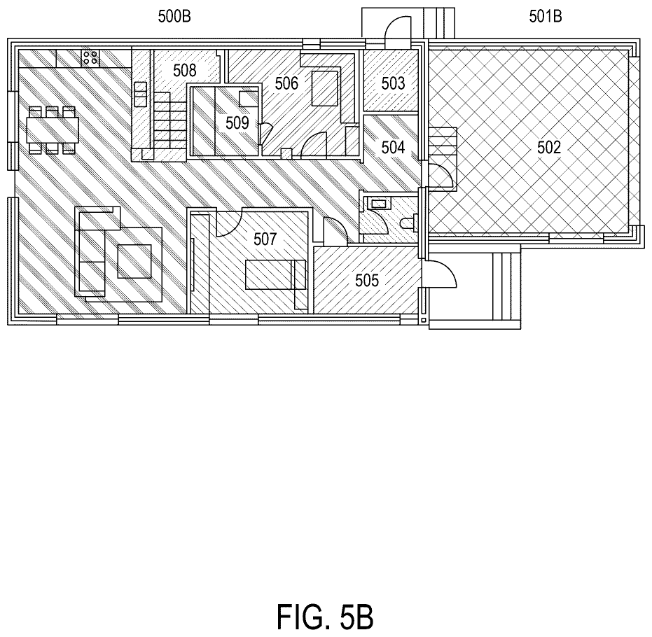

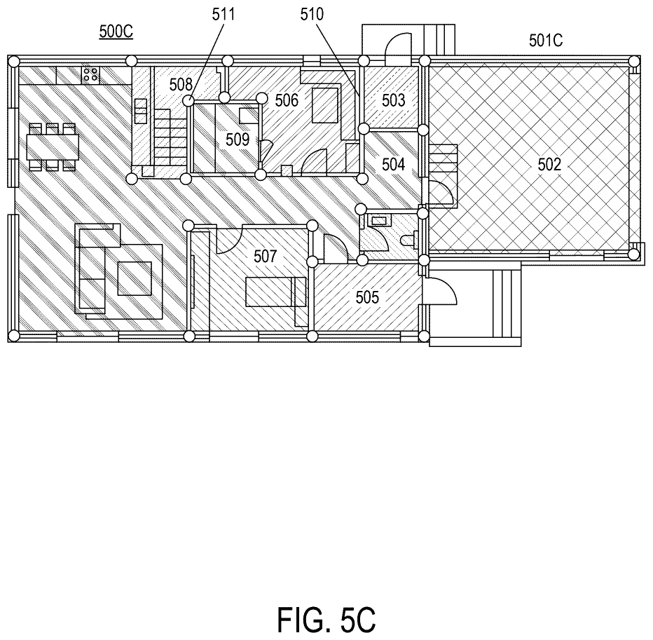

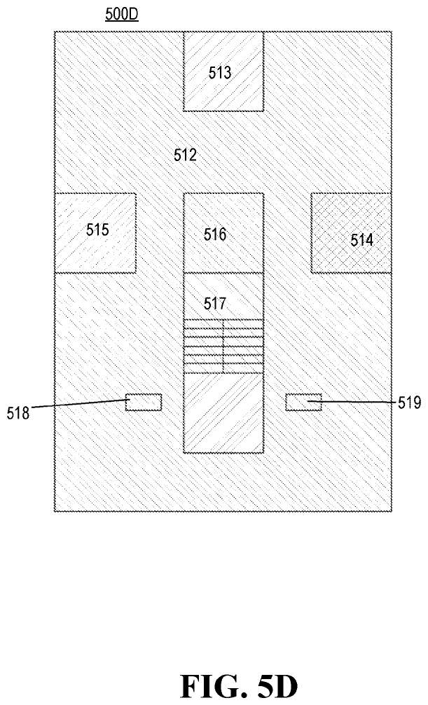

Referring now to FIGS. 5A-5D, a progressive series of outputs that may be included in various user interface are illustrated and provides examples of a recognition process that may be implemented in some embodiments of the present invention. Referring now to FIG. 5A, a relatively complex drawing of a floorplan may be input as a design plan 501A into a controller running an AI engine. This design plan may represent a detailed layout of a building, including various rooms, fixtures, and structural elements, which the AI engine will analyze to extract relevant features for further processing. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon to a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of: regions; spaces; patterned portions; line segments; polygons; symbols; icons or other portions of the user interfaces may be assembled and presented in a user output and our user interface, or as input into another automated process. This may be used to create a detailed report for architects or engineers, highlighting how different spaces are utilized and where potential compliance issues may arise, especially in areas such as plumbing fixture placement and accessibility.

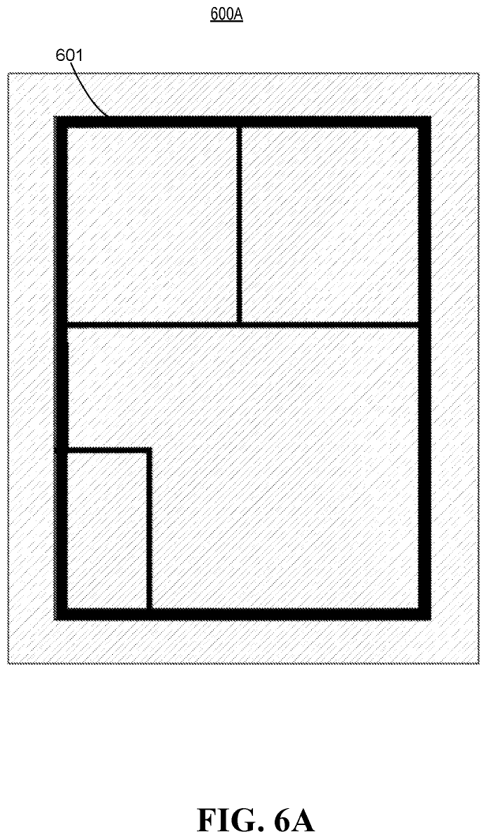

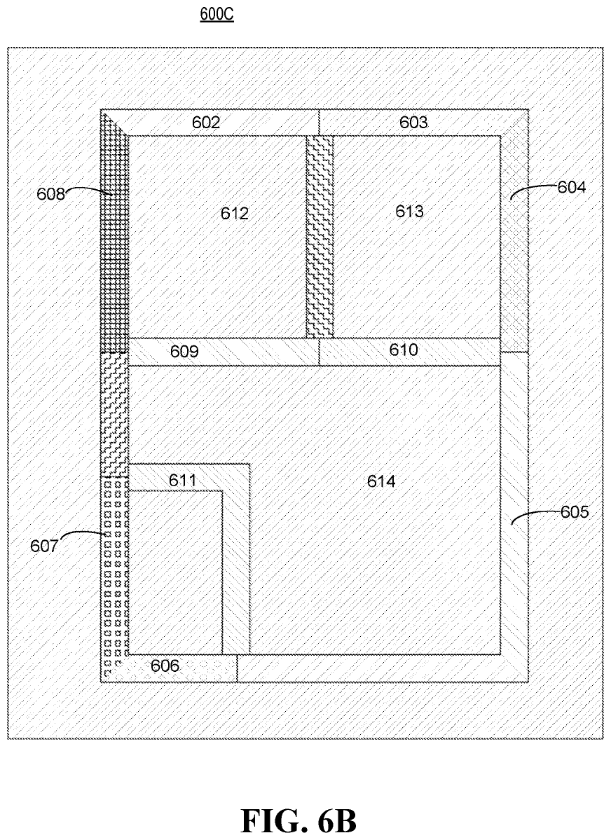

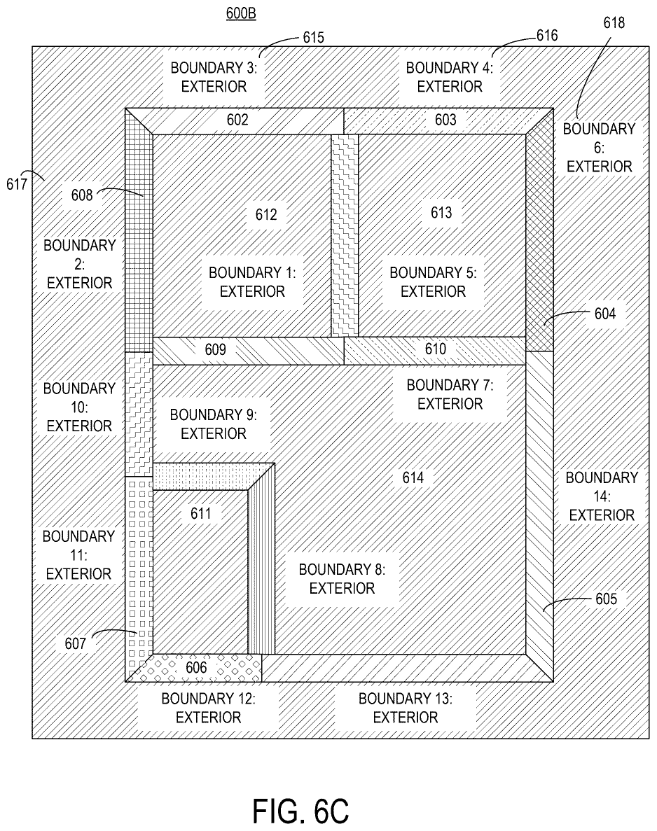

Referring now to FIGS. 6A-6C, in some embodiments, automated and/or user-initiated processes may include refinement of regions, spaces, or areas may involve one or both of a user and a controller identifying individual wall segments 211A from previously defined boundaries. For example, a user may need to refine the boundary of a restroom so that all plumbing fixtures are accurately accounted for in the compliance analysis.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C. For example, a segment may be labeled as a “fire-rated wall” or “soundproof partition,” providing immediate visual feedback to the user regarding the wall's compliance status and necessary attributes.

In some embodiments, functionality may be allocated to classified individual line segments 602-611, such as, by way of non-limiting example, a process that generates an estimated materials list for a region or an area defined by a boundary, based on the regions or area's characteristics and its classification.

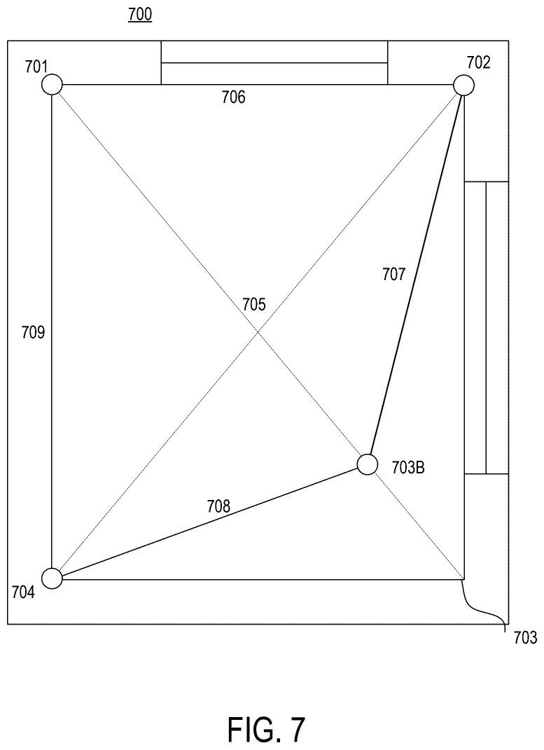

Referring now to FIG. 7 in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments. For example, a user may drag a boundary line to redefine the limits of a kitchen area, triggering the AI engine to reclassify the adjacent spaces and adjust the corresponding material and fixture requirements.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance.

### Model Training Procedures

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

### Estimation Automation

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied on a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. As well, a text input or other narrative may be recognized to provide more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, a user interface or other output display or on reports, different layers may be illustrated at different times along with associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with a set of codes, standards and the like and review the discovered design elements for compliance. In some embodiments, a list of variances or discovered potential issues may be presented to a user on a display or in a report form. In some embodiments, a function may be offered to remove user entered data and other personally identifiable information associated in the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

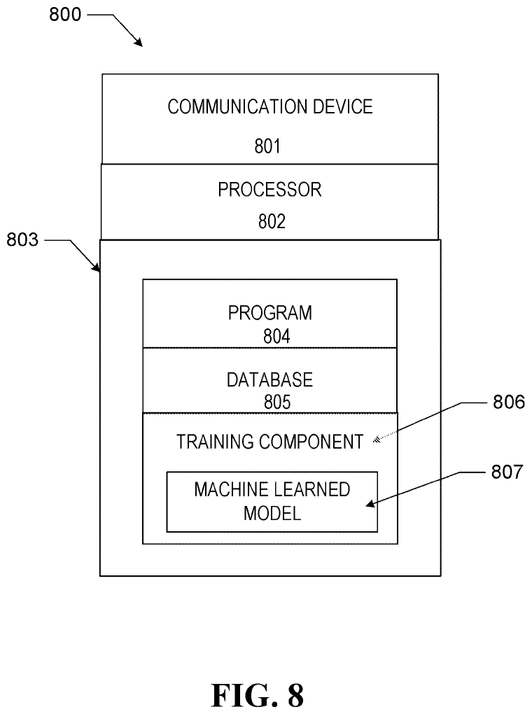

Referring now to FIG. 8 an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

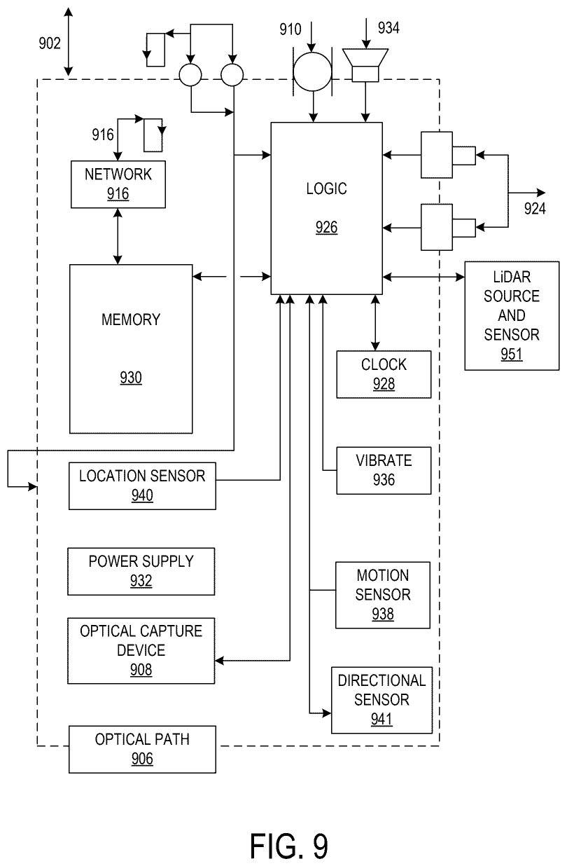

Referring now to FIG. 9, a block diagram of an exemplary mobile device 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record time and strength of returned signal that is reflected off of surfaces in the environment of the mobile device 902. In some embodiments, as have been described herein, a 2 dimensional drawing or representation may be used as the input data source and, vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBie. Features in the BIM or CAD datafile may already have defined boundary aspects having innate definitions such as walls and ceilings and the like. An interactive interface may be generated that receives input from a user indicating a user choice of types of innate boundary aspects a user provides instruction to the controller to perform subsequent processing on.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determine classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

User Interface with Single and Multiple Layers

In some embodiments, the user may be given access to movement of boundary elements and vertices of boundary elements. In examples where lines or vectors are used to represent boundaries and surrounding area, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a feature or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

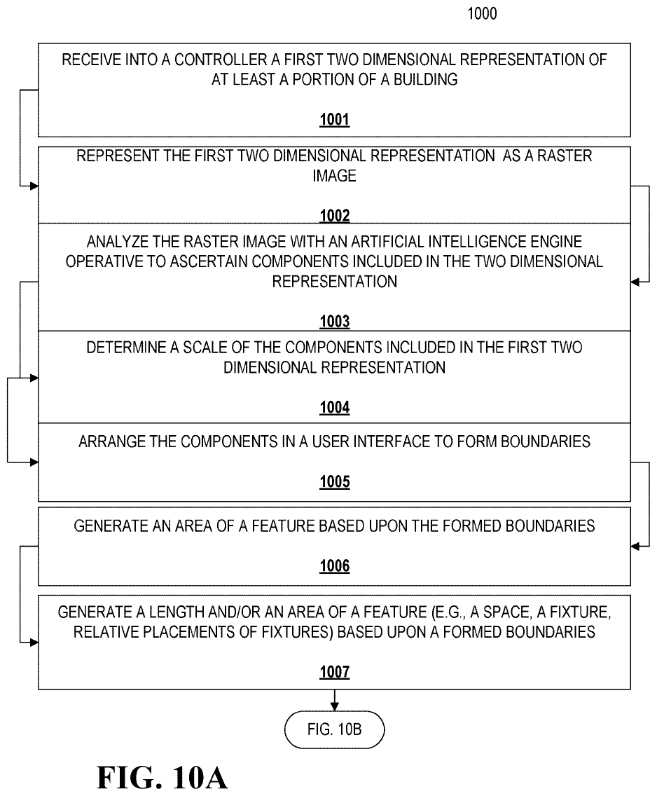

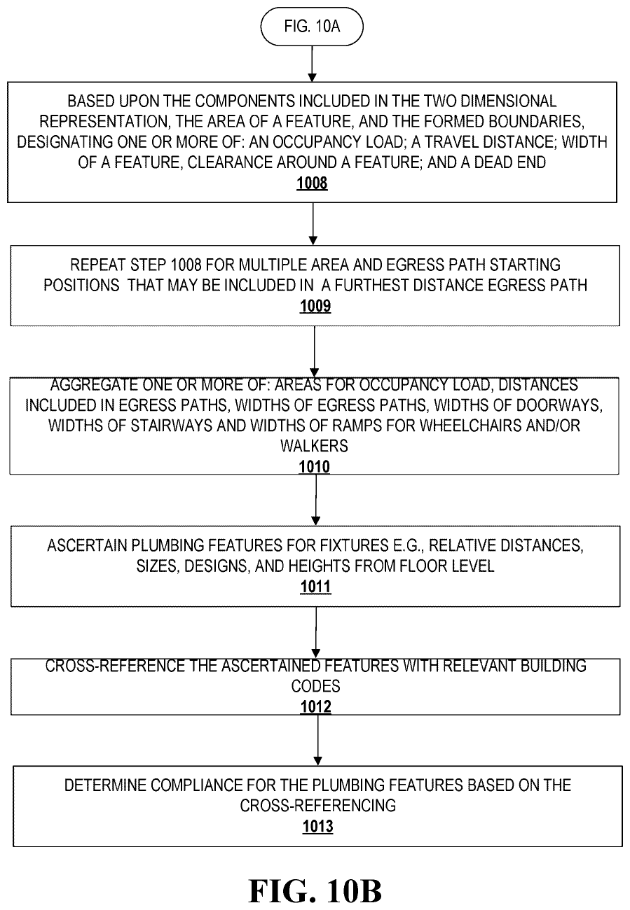

Referring now to FIGS. 10A-10B, an exemplary flowchart 1000 outlines method steps for quantifying the requirements for plumbing compliance based on an artificial intelligence (AI) analysis of a design plan. The method enables a comprehensive assessment of whether the plumbing aspects of a building's design adhere to relevant building codes, so that the final construction is safe, functional, and code-compliant.

At step 1001, the process begins with receiving a design plan into a controller, which serves as the central processing unit, including the AI engine. The design plan may include various forms of architectural drawings, floor plans, or other design documentation that depict at least a portion of a building. These documents are typically received in digital formats such as PDFs, CAD files, or images, which can be easily processed by the AI engine. The design plan provides the foundational data from which all subsequent analysis will be derived, and it must accurately represent the building's intended layout, including all plumbing fixtures and systems.

At step 1002, the received design plan is represented as a raster image or another image type conducive to AI analysis. Raster images are pixel-based and allow the AI engine to interpret the visual data in a structured format. The design plan is transformed from a static representation into a format that can be analyzed computationally. The rasterization process involves converting vector graphics or other types of design representations into a grid of pixels, each of which can be analyzed individually by the AI engine.

Once the design plan is represented as a raster image, step 1003 involves analyzing this image using the AI engine. The AI engine is programmed to recognize and identify various components within the design plan, such as walls, rooms, plumbing fixtures (e.g., toilets, sinks, showers), and associated piping systems. The AI engine uses pattern recognition and machine learning algorithms to detect these components based on their shapes, positions, and relationships within the design. For example, it can identify a toilet by recognizing the common outline and placement typically associated with such a fixture in bathroom layouts.

After identifying the components, step 1004 focuses on determining the scale of these components within the design plan. The scale is used for accurately measuring dimensions, distances, heights, and areas in the design. It may be determined by referencing a scale indicator or ruler included in the design plan or by identifying components of known dimensions, such as standard-sized fixtures. The AI engine uses this scale to convert pixel measurements into real-world units (e.g., inches, feet, meters), enabling precise calculations of space and clearance.

At step 1005, a user interface is generated that incorporates the components identified by the AI engine. The user interface is interactive, allowing users to view and manipulate the design plan within a digital environment. The user interface presents a clear visual representation of the building's layout, highlighting the plumbing systems and fixtures. Users can zoom in on specific areas, adjust views, and interact with the components to gain a deeper understanding of the design's spatial relationships and configurations.

Step 1006 involves arranging the identified components within the user interface to form boundaries. These boundaries may represent the edges of rooms, the extents of plumbing systems, or the clearances required around fixtures. The AI engine may draw a boundary around a toilet to indicate the required clearance for accessibility compliance, so that there is enough space for a wheelchair to approach and use the fixture.

Once boundaries are formed, step 1007 allows for the generation of lengths, heights, and areas based on these boundaries. For example, the AI engine can calculate the area of a bathroom, the length of a pipe run, or height of a plumbing fixture. These measurements are used for determining whether the design meets specific code requirements related to space allocation, fixture placement, and piping lengths. Accurate measurements help identify potential issues such as overcrowding in a bathroom layout or insufficient space for safe and accessible plumbing.

Step 1008 expands on this by using the components and boundaries to generate key features such as occupancy load, travel distances, clearance around fixtures, and widths of various paths (e.g., doorways, ramps). For example, the AI engine may calculate the required clearance around a sink to determine compliance with ADA standards, which dictate that there must be a minimum amount of space for wheelchair access.

At step 1009, the method allows for the repetition of the analysis process across multiple areas, units, and egress paths within the building. This provides a comprehensive review of the entire design, covering all spaces where plumbing fixtures are present. By repeating the analysis, the AI engine can verify that all areas of the building meet the required standards, not just isolated sections.

Step 1010 involves aggregating values for variables specified in relevant codes. These variables may include areas for occupancy load, distances within egress paths, and the widths of doorways, stairways, and ramps. The AI engine combines these variables to assess the overall compliance of the building's plumbing systems. For example, it may aggregate the total clearance required around all toilets in a building to determine whether the design provides sufficient space across the entire facility.

At step 1011, the AI engine focuses on plumbing features, ascertaining the relative distances, sizes, designs, and heights from the floor level for each fixture. This detailed analysis allows for verifying that every plumbing component meets the precise specifications outlined in the relevant building codes. For example, the AI engine may check that a toilet's height is within the range required for ADA compliance or that the slope of a drainage pipe is sufficient to prevent blockages.

Step 1012 involves cross-referencing the ascertained features with the relevant building codes. The AI engine uses a comprehensive database of plumbing codes to compare the design's measurements and configurations against the legal standards. This step is used for identifying any discrepancies between the design plan and the code requirements. For example, the AI engine may identify that a bathroom layout does not provide the minimum required distance between a sink and a wall, which may be a violation of local plumbing codes.

Finally, at step 1013, the AI engine determines the compliance status for the plumbing features based on the cross-referencing performed in the previous step. The AI engine generates a report that outlines areas of compliance and non-compliance, providing detailed feedback on where adjustments are needed. The report is useful for architects, engineers, and builders, as it guides them in making necessary modifications to the design before construction begins. The AI engine may recommend repositioning a fixture, adjusting the layout of a room, or altering the dimensions of a pipe run to bring the design into full compliance with the relevant codes.

In some embodiments of the present invention, the AI engine may consider occupancy load and dominance ranks of areas on the design plan as critical factors in plumbing compliance analysis and in providing automated revision suggestions to the design plan. The occupancy load, which refers to the maximum number of people that a given area is designed to accommodate, may be considered in determining the required number and type of plumbing fixtures such as toilets, sinks, and urinals. Meanwhile, dominance rank refers to the relative importance or priority of certain areas within the building, such as high-traffic zones like public restrooms or kitchen areas, which require more stringent compliance checks and may influence the design layout significantly.

For example, in a commercial office building, the AI engine may analyze a design plan that includes multiple restroom facilities spread across various floors. By calculating the occupancy load for each floor, the AI engine determines the minimum number of water closets, sinks, and urinals required to meet building codes. If a particular floor is designed to accommodate employees, the AI engine may reference the applicable plumbing code to verify that the restroom on that floor includes enough fixtures to handle peak usage periods. If the restroom does not meet these requirements, the AI engine may automatically generate revision suggestions, such as adding more fixtures or reconfiguring the space to increase capacity.

In terms of dominance rank, the AI engine may prioritize compliance checks for areas with higher traffic or greater importance within the building. For example, in a shopping mall design plan, restrooms near the food court may be considered dominant areas due to the high volume of visitors. The AI engine may assess these areas first, so that the plumbing systems are robust enough to handle large crowds. If the AI engine detects that the design lacks sufficient restroom facilities in these high-traffic areas (or highly dominant areas, may be with user provided dominance rank), it may suggest reallocating space from less critical areas, such as storage rooms, to expand the restroom facilities.

Another example involves a large residential complex where the AI engine assesses the plumbing systems based on the dominance rank of specific units. Penthouse apartments or units located on the top floors may be given a higher dominance rank due to their premium status and the expectation of better amenities. The AI engine may suggest upgrading the plumbing fixtures in these units to higher-end models or increasing the water pressure to accommodate luxurious features like multi-head showers or jacuzzi tubs. Conversely, for standard units with lower dominance ranks, the AI engine may focus on basic compliance without recommending costly upgrades, thereby balancing code compliance with cost efficiency.

Additionally, the AI engine may also consider the impact of occupancy load and dominance rank on emergency plumbing scenarios. For example, in a hospital design plan, areas like operating rooms and intensive care units (ICUs) may have the highest dominance ranks due to their critical functions. The AI engine may prioritize that these areas have redundant plumbing systems, such as backup water supply lines or emergency drainage systems, to maintain functionality even in case of a failure in the primary systems. It may suggest adding extra shutoff valves or installing pressure-boosting systems so that these critical areas maintain adequate water supply at all times.

Furthermore, the AI engine may also consider future scalability in its analysis. For example, in an office building that is expected to expand its workforce over time, the AI engine may recommend plumbing systems that can be easily upgraded or expanded. This may involve suggesting larger diameter pipes that can handle increased water flow or designing the layout in a way that additional fixtures can be added without significant alterations to the existing infrastructure.

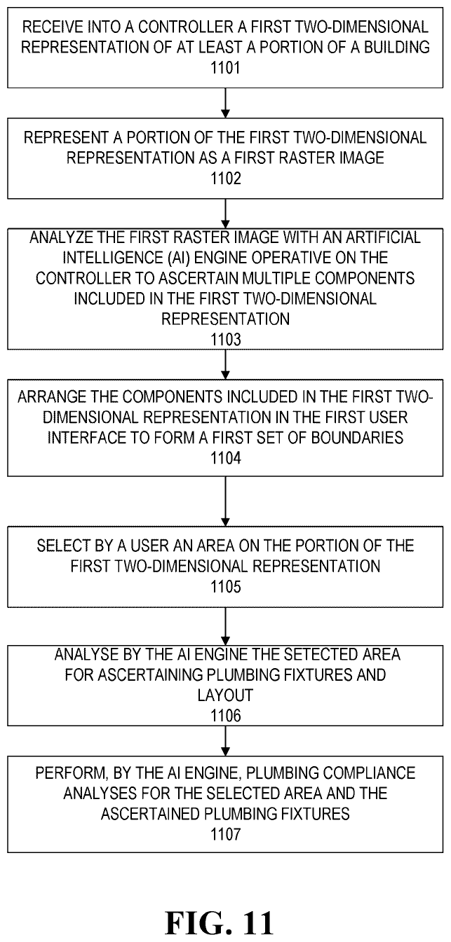

Referring now to FIG. 11, a flowchart provides an exemplary method for quantifying whether the plumbing design within a portion of a building complies with relevant codes, using an AI-driven system. The system includes one or more controllers that perform the specified operations or actions by executing software, firmware, hardware, or a combination of these. The process outlined in the flowchart leverages AI technology to analyze design plans, ascertain plumbing components, and provide compliance verification, thereby determining that the building meets all necessary plumbing regulations.

At step 1101, the method begins by receiving a two-dimensional representation of at least a portion of a building into the controller. The two-dimensional representation is typically an architectural design plan, which may include a floor plan, a blueprint, or a digital design file (e.g., CAD or Revit files). The design plan serves as an input for the AI engine's analysis, providing a detailed depiction of the building's layout, including the placement of plumbing fixtures and associated systems. For example, the design plan may show the layout of a commercial kitchen, including the locations of sinks, dishwashers, and drains, which are used for determining compliance with health and safety regulations, and relevant building codes.

At step 1102, the controller processes the design plan by converting a portion of it into a raster image. A raster image, being pixel-based, allows the AI engine to analyze the design in a structured format that facilitates pattern recognition and component identification. This step is used for transforming the static design plan into a format that the AI engine can manipulate and evaluate. For example, the raster image may represent a section of a bathroom, where the AI engine can begin identifying specific elements like toilets, sinks, and showers based on their pixel patterns.

Following the rasterization, step 1103 involves analyzing the raster image with the AI engine to ascertain multiple components included in the design. The AI engine is programmed to recognize and differentiate various plumbing components within the design, such as fixtures (e.g., water closets, sinks, urinals), piping systems, and drainage layouts. The AI engine uses sophisticated algorithms to detect these components based on their shapes, spatial relationships, and standard configurations. For example, the AI engine may identify a sink by recognizing its outline and proximity to other features like countertops and water supply lines.

Step 1104 centers on arranging the identified components into a user interface to form a first set of boundaries. These boundaries may represent zones within the design plan, such as the areas around plumbing fixtures that must meet specific clearance requirements. The user interface generated at this step is interactive, allowing users to visualize the design with clear demarcations of compliant and non-compliant areas. For example, the AI engine may outline the minimum clearance area required around a toilet for wheelchair accessibility, so that the design complies with ADA standards. Users can interact with these boundaries, making adjustments to the design as necessary to achieve compliance.

At step 1105, the system allows the user to select a specific area on the portion of the two-dimensional representation for detailed analysis. This step is particularly useful when focusing on critical or high-priority areas within the building, such as public restrooms, commercial kitchens, or mechanical rooms. By selecting a specific area, the user can direct the AI engine to perform a focused analysis, so that all aspects of the design are thoroughly evaluated. For example, in a large office building, the user may select the main lobby restroom area for detailed compliance analysis, given its high traffic and importance. In some embodiments, an area can be selected for compliance analysis using a computer mouse or similar input method for marking the desired area.

Once the area is selected, step 1106 involves the AI engine analyzing the chosen area to ascertain the plumbing fixtures and layout within that space. The AI engine examines the selected area in detail, identifying all relevant plumbing components, their placements, and their spatial relationships. This step is used for determining whether the plumbing layout (including fixtures) in the selected area adheres to the necessary codes. For example, the AI engine may analyze the spacing between multiple urinals in a public restroom, verifying that they meet the minimum separation distances required by local plumbing codes.

Finally, at step 1107, the AI engine performs a comprehensive plumbing compliance analysis for the selected area and the ascertained plumbing fixtures. This may involve cross-referencing the identified components with the relevant plumbing codes to determine whether the design meets all applicable regulations. The AI engine generates a report that highlights areas of compliance and non-compliance, providing detailed feedback on where adjustments are needed. For example, the AI engine may determine that a sink is placed too close to a door, violating the required clearance for egress, and suggest moving the sink to a different location to achieve compliance.

Throughout the process, the AI engine automates much of the compliance verification work, reducing the potential for human error and speeding up the review process. By systematically analyzing the design plan, identifying key components, and evaluating them against established codes, the AI engine provides a powerful tool for architects, engineers, and builders to determine if their designs are not only functional but also fully compliant with all relevant plumbing regulations.

Any or all of steps 1101-1107 may be repeated for different portions of the two-dimensional reference descriptive of the building.

A scale of one or more components may be determined and a parameter of one or both of a polygon and a line segment may be modified based upon receipt of an instruction for a user; and a boundary may be set based upon reference to a boundary allocation hierarchy.

The steps may be performed multiple times and may include two or more two-dimensional references with results of the process be compared one against the other to ascertain when a change has been made to a two-dimensional reference that places a building in compliance with a selected code. In various embodiments, a change in subsequent two-dimensional references may be used to generate a change in one or more of a take off, labor costs, project management input or other aspects that may impact construction of a building and/or associated costs.

Implementations may include one or more of the following features. The method additionally determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the interactive user interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via an interactive user interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in the construction of the building. In addition, a type of labor associated with at least one of the items to be included in the construction of the building may be designated based upon AI analysis of the first two-dimensional reference and the second two-dimensional reference, respectively.

Methods of practice may additionally include the steps of: determining whether a design plan received into the controller includes a vector image, and if one of the first and the second design plan received into the controller includes a vector image converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of: a size and shape of at least one of the dynamic components. At least one of the dynamic components may include a polygon and the method further includes the steps of: receiving an instruction via the interactive user interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit, or other defined space. A change in area of a unit may allow for a recalculation that results in a modification of one or more of: an occupancy load; a length of a path of egress; an length and/or area of a common path; a width of a stair; a travel distance to traverse a dead end; an existence of a dead end; or other variable referenced in determination of compliance with a set of conditions, such as a code relevant to a geopolitical locality and a building.

A dynamic component may include a line segment and/or vector, and the method may further include the steps of: receiving an instruction via the interactive user interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor.

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

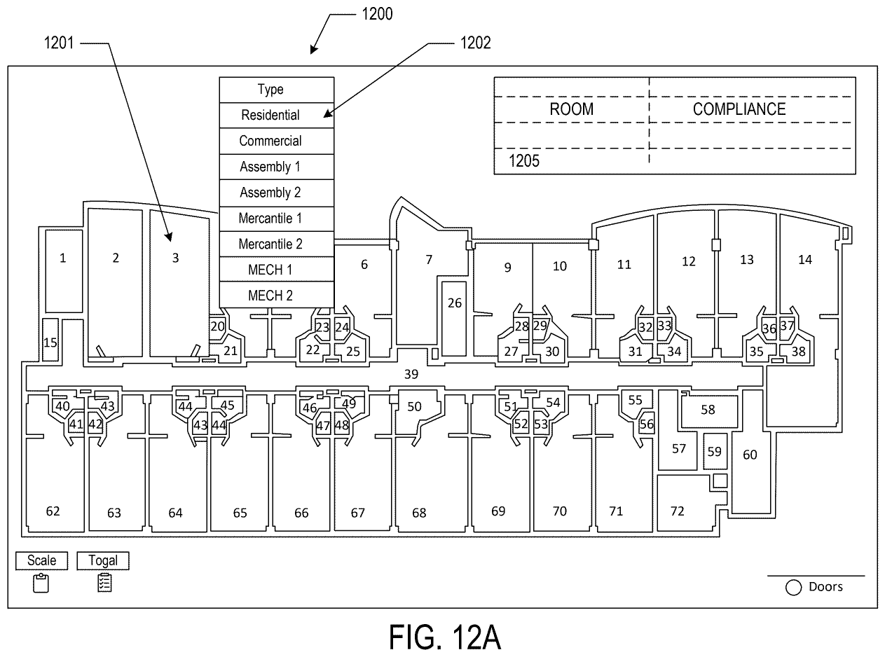

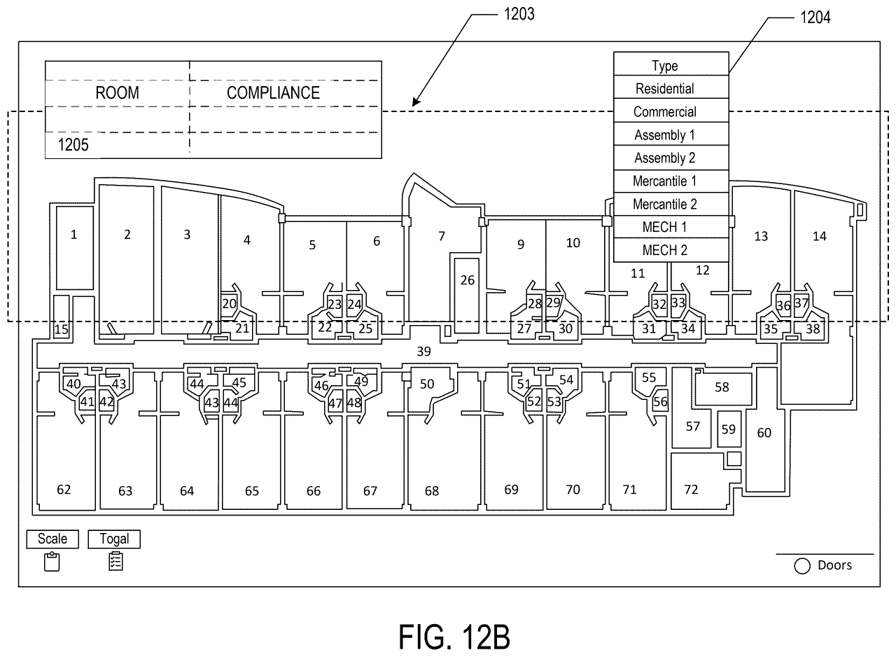

Referring now to FIG. 12A, an example of how an AI engine classifies and analyzes various spaces within a design plan, is illustrated. The AI engine processes the inputted design plan, which may include architectural plans, floor layouts, or other building schematics, and then extracts critical elements such as room spaces, walls, doors, and plumbing fixtures. These elements are subsequently modeled to create a space model that is visually represented on a display 1200 (interactive user interface). This space model allows a user to interact with and assess the design from a compliance perspective, particularly focusing on plumbing and related systems.

Individual spaces 1201 within the design are color-coded to reflect their compliance status. For example, compliant areas are displayed in green, indicating that these spaces meet all relevant building and plumbing codes. Non-compliant areas, on the other hand, are displayed in red, drawing immediate attention to spaces that require further review or modification. This color-coding system provides a quick visual reference for users, allowing them to easily identify areas that need to be addressed.

The AI engine may automatically identify and assign space types to each area based on the elements and layout detected in the design. For example, the AI engine may recognize a space containing plumbing fixtures like sinks and toilets as a restroom, or it may classify a larger area with multiple workstations and minimal plumbing as an office space. The space types can be visualized using different colors or patterns, as shown in the drop-down menu 1202, which allows users to manually adjust or confirm the space types assigned by the AI engine. The drop-down menu 1202 provides a selection of different space types such as “Residential,” “Commercial,” “Assembly,” “Mercantile,” and “Mechanical,” each represented by a specific color or symbol for easy identification.

In the scenario depicted, non-compliant areas 1201 are highlighted in red, indicating that these spaces do not meet the required plumbing codes. For example, a red area may indicate a bathroom where the fixtures are improperly spaced, failing to provide the required clearances for accessibility, or it may highlight a kitchen area where the water supply lines are not correctly configured to meet health and safety standards. The AI engine flags these areas to prompt users to take corrective action, either by revising the design directly within the interface or by consulting with experts to make necessary adjustments.

Additionally, the interactive user interface 1200 may allow users to drill down into the details of each space. By clicking on a red-highlighted area, the user can view specific information about the nature of the non-compliance, such as the exact measurements that are out of specification or the specific code requirements that are not being met. This feature empowers users to make informed decisions about how to revise the design to bring it into compliance. The system is designed to be flexible and user-friendly, enabling both automatic and manual classification of spaces. For example, if the AI engine misclassifies a space or if the user wants to override the AI's decision, the drop-down menu 1202 allows for easy reassignment of space types.

Referring now to FIG. 12B, it illustrates an example of how an AI engine, in conjunction with user input, can designate and analyze multiple spaces within a design plan for plumbing compliance. The AI engine provides a powerful tool for assessing large areas or multiple spaces simultaneously, so that the entire building design adheres to relevant plumbing codes and standards.

In some embodiments, a regional boundary 1203 is created around one or more identified spaces within the design plan. The boundary 1203 can be drawn by the user or automatically generated by the AI engine based on predefined criteria. For example, the AI engine may automatically group together all restroom facilities on a particular floor or within a specific section of a building. The creation of this regional boundary allows the AI engine to treat the enclosed spaces as a single unit for the purpose of comprehensive compliance analysis.

Once the regional boundary 1203 is established, the user or AI engine can select a space type from a predefined list of types 1204. This list includes various space types such as “Residential,” “Commercial,” “Assembly,” “Mercantile,” and “Mechanical,” each associated with specific plumbing code requirements. For example, if the selected space type is “Commercial,” the AI engine will apply the relevant commercial plumbing codes to the spaces within the boundary, checking for things like the number of required fixtures, spacing between fixtures, and accessibility features. The user also has the option to create a new space type if the predefined options do not fully capture the intended use of the space.

After the space type is selected, a tabular display 1205 presents the user with a detailed overview of the spaces within the boundary, along with their assigned types. The table 1205 provides a clear and organized summary of the analysis, showing which spaces have been classified, what types have been assigned, and any preliminary findings from the AI engine's compliance check. For example, the table 1205 may list each restroom within the boundary and indicate whether it meets the required fixture count and spacing for the “Commercial” space type. Non-compliant areas may be flagged in red, as seen in the regional boundary, prompting further investigation.

The selection of a space like 1203 within the design plan triggers the AI engine to perform a comprehensive compliance analysis. This analysis may include checking for occupancy load, which determines the number of people that can safely use the space and, consequently, the number of plumbing fixtures required. The AI engine may also analyze the spacing and configuration of fixtures to determine if they meet accessibility standards, such as those outlined by the ADA. For example, the AI engine may verify that all sinks in a commercial restroom have the appropriate knee clearance for wheelchair users. In addition to plumbing-specific checks, the AI engine may perform other types of analyses, such as dead-end and egress capacity analysis.

By combining these various analyses, the AI engine provides a holistic view of compliance for the selected spaces. If any issues are identified, the system can suggest automated revision options. For example, if a restroom does not have enough fixtures to meet the occupancy load, the AI engine may recommend adding additional toilets or sinks. Similarly, if the layout does not provide sufficient accessibility, the AI engine may suggest reconfiguring the space to include wider stalls or lower countertops.

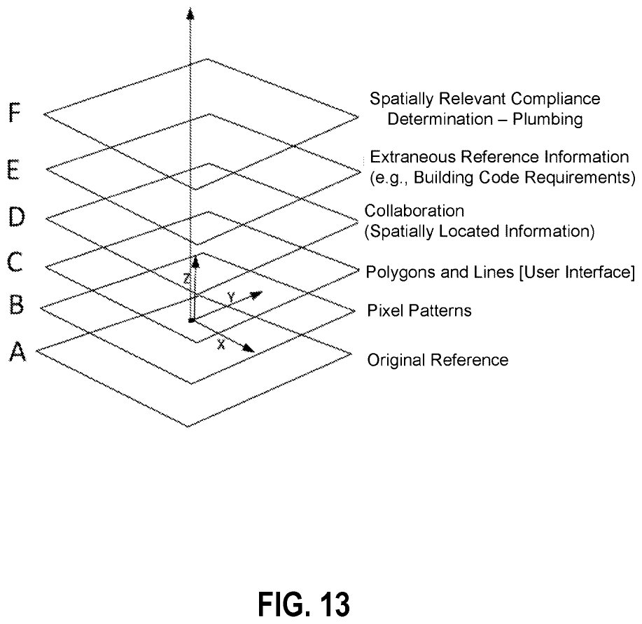

Referring now to FIG. 13, the diagram represents a conceptual framework encapsulating a multi-layered structure within an AI-powered collaborative system designed specifically for plumbing compliance analysis in design plans. The framework is divided into six distinct levels, labeled A through F, each representing a critical stage or component of the system's operation. These levels collectively lead to a comprehensive spatially relevant compliance determination, allowing for detailed and accurate analysis of plumbing systems within architectural designs.

Starting with Level A, this foundational layer signifies the intake of the original two-dimensional reference, such as an architectural drawing, floor plan, or other design documents. These references often come in static formats, such as PDFs, CAD files, or scanned images, and represent the first point of contact with the AI engine (or controller). At this stage, the AI engine begins by processing these documents, identifying key elements such as rooms, walls, water closets, sinks, drains, and other plumbing fixtures.

Moving to Level B, the system converts the original reference into pixel patterns. Each pixel within the design plan is treated as a data point, enabling the AI to detect and differentiate between various design elements, including the precise outlines of plumbing fixtures, pipelines, and water supply lines. This level is where the raw visual data begins its transformation into structured information. For example, the AI may identify the exact location and configuration of a water closet based on the pixel data, recognizing the associated drainage lines and supply connections necessary for its operation.

At Level C, the pixel patterns identified in the previous level are further organized into dynamic elements within an interactive user interface. Here, the AI engine converts the pixel data into interactive components, such as polygons, vectors, and lines, which delineate the boundaries of various plumbing fixtures and systems within the design. Users can interact with these dynamic components, adjusting and manipulating elements as necessary to explore different design scenarios. For example, a user may adjust the placement of a sink or a toilet within the design, and the AI engine may dynamically update the associated plumbing routes and compliance status in real-time.

Level D introduces a collaborative aspect to the system, transforming the design plan into a shared workspace where multiple stakeholders, such as architects, engineers, and code compliance officers, can interact with the same data in real-time. This layer is particularly beneficial in complex projects where interdisciplinary collaboration is essential. For example, a plumbing engineer may propose an adjustment to a pipe route, which the architect can immediately visualize within the overall design, while a compliance officer assesses the change against local building codes. The collaborative environment provided by this level allows for a seamless exchange of expertise, with all changes being tracked and visible to all authorized parties, thus promoting a more cohesive and integrated workflow.

Level E is where the AI engine's capabilities for compliance analysis truly come to the forefront. This level integrates various plumbing codes, safety regulations, and accessibility standards into the system's functionality. The AI cross-references the spatial data processed in the earlier levels with a comprehensive database of plumbing compliance requirements. For example, the AI may verify whether the clearance around a water closet meets the minimum code requirements or if the slope of a drain line is adequate to prevent backflow. This level can also connect to third-party databases, such as those for sourcing compliant plumbing fixtures or materials, so that all aspects of the design adhere to the relevant standards.

Finally, Level F represents the culmination of the entire process, where the AI engine generates a spatially relevant compliance determination. At this stage, the system produces a final assessment of the plumbing design's compliance status, based on the comprehensive analysis conducted in the previous levels. The output includes a detailed report that highlights areas of compliance and non-compliance, along with actionable recommendations for rectifying any issues. For example, the AI engine may detect that a bathroom does not meet ADA requirements due to inadequate clearance around a water closet and suggest specific modifications to achieve compliance. Additionally, this level allows users to visualize the compliance status in a spatial context, with compliant and non-compliant areas clearly marked within the interactive user interface, facilitating a clear and intuitive understanding of the design's compliance landscape.

In some embodiments, there may be alternative methods of receiving data from various sources that can be used to generate a design or to supplement a design created in the manners as have been described previously. For example, the system may receive an architectural file with intelligent features of various kinds which will be discussed in further detail following. The present system may operate in concert with a BIM or CAD design system for example as an add-in to these design systems and then the present system may have access to design elements, location data and the like directly. In other examples, the present system may access BIM or CAD design system data by loading datafiles from said systems. In still further examples, the present system may operate to capture data from display screens that are displaying designs from the said BIM or CAD design systems.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

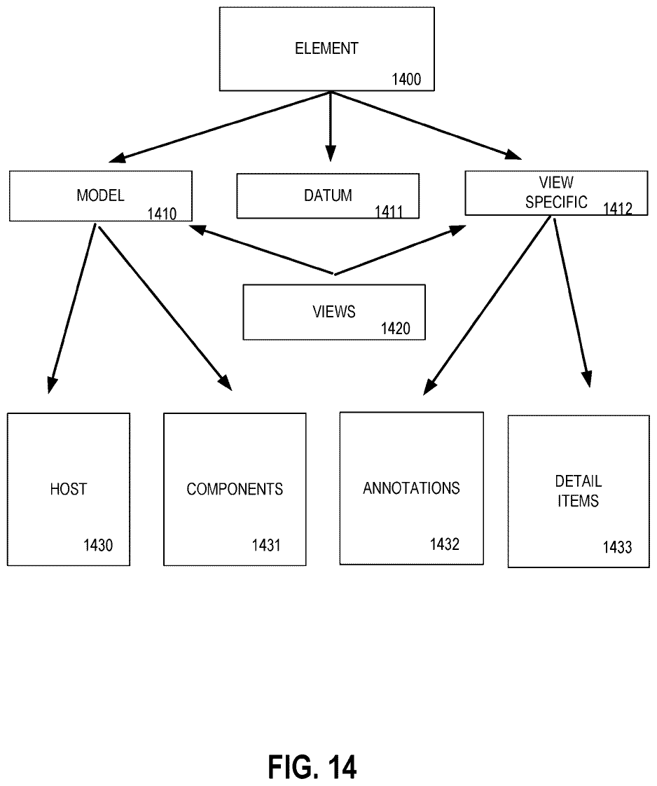

Referring now to FIG. 14, a high-level overview of the types of information that may be stored in a digital file focuses on the context of plumbing compliance analysis using an AI-powered system. FIG. 14 illustrates the hierarchical structure of elements 1400 within a design file, which may be a Revit file or a similar building information modeling (BIM) format. These elements are categorized into different types: model elements 1410, datum elements 1411, and view-specific elements 1412.

Model elements 1410 correspond to the physical components that are to be constructed within a building. These components may include foundational elements such as floors, walls, ceilings, and roofs, which may collectively be referred to as “Hosts” 1430. In the context of plumbing compliance, these hosts may provide the structural framework within which plumbing systems are integrated. For example, walls in a bathroom host the piping systems for water supply and drainage, while floors may contain the underfloor heating systems or drainage layouts. The AI engine uses these model elements to understand where and how plumbing systems are positioned within the building's framework, allowing it to assess whether these systems meet the necessary compliance standards.

The model elements also include components 1431, which are secondary but equally important features within a building. These components may consist of plumbing fixtures like sinks, toilets, bathtubs, showers, a piping layout. The AI engine can analyze these components to verify that their installation and placements are compliant with building codes. For example, AI engine may check the spacing between a toilet and a sink to determine if it meets the minimum clearance requirements, or it may assess the slope of a bathtub drain to verify that it is adequate for proper water flow. Additionally, components may include structural supports like beams and braces that may affect the routing of plumbing systems. The AI engine considers these elements to determine if plumbing lines interfere with the structural integrity of the building or not.

Datum elements 1411 are used to define the design context, providing a reference framework that organizes the model elements. This may include grids, levels, and reference planes, which are used for accurately placing and aligning components within the design. For plumbing compliance analysis, datum elements help the AI engine to determine the exact location of plumbing fixtures in relation to the overall building layout. For example, a grid system may be used to position sinks and toilets at consistent intervals across multiple bathrooms on different floors, while levels may be used to allow that all plumbing fixtures are installed at the correct heights relative to the building's floor levels. These datum elements help the AI engine maintain consistency and accuracy in the compliance analysis process.

View-specific elements 1412, on the other hand, are details and annotations that are visible only when certain views 1420 of the design are activated. These elements may include annotations 1432, such as keynotes, comments, tags, and dimensions, which provide additional context and information relevant to specific parts of the design. For example, an annotation may indicate that a particular water pipe is made of a specific material that meets local code requirements, or it may note the expected water pressure at a certain point in the system. The AI engine uses these annotations to cross-reference the design with relevant plumbing codes, so that all specified materials and configurations are compliant.

Detail items 1433, another subset of view-specific elements, include lines, fills, and other graphic details that may represent plumbing connections, insulation around pipes, or sealing materials used to waterproof certain areas. These details are critical for the AI engine's analysis, as they often contain the fine-grained information needed to assess compliance with specific plumbing standards. For example, the AI engine may examine detail lines that represent pipe connections to determine if they are properly insulated and secured, or it may also assess the fill materials around a drain to verify that they are adequate for preventing leaks.

The AI engine leverages this multi-layered structure to perform a comprehensive plumbing compliance analysis. Starting with the original reference and moving through the model, datum, and view-specific elements, the AI engine systematically evaluates each component's compliance with applicable plumbing codes. For example, it may start by assessing the overall layout of plumbing systems within the host elements to determine if they are logically and efficiently arranged. Then, it can move on to analyzing the specific components like pipes and fixtures to verify if they meet size, spacing, and material requirements or not.

Additionally, the AI engine can use this layered structure to simulate different scenarios, such as changes in water pressure or flow rates, to predict how the plumbing system will perform under various conditions. By analyzing how these factors interact within the framework of the building's design, the AI engine can provide insights into potential issues before they arise, such as identifying areas where pipes may be prone to freezing or where water pressure may be insufficient to meet demand.

In some embodiments, various elements may be loaded from exemplary files and extracted for their relevant information. Other file types in addition to the Revit® types previously mention may include in a non-limiting sense DGN, DWF, DWG, DXF, IFC, SAT, SKP, ODBC, HTML, TXT, and gbXML file types. As mentioned, systems of the present type may be configured to extract information based on defined file structure of the input file times. In addition, learned aspects may be applied to interpret the designs and assign components or alter certain information about a component. For example, a wall definition may be recognized by the present system and have aspects of it modified, and additional model aspects defined such as an appropriate center line defined, or a set of different dividing line types assigned. The wall may have a designation assigned such as whether it is an internal or external wall. Other such learned assignments may be applied after data is loaded from an external file. As mentioned, the present system may also operate in manners where it has access to objects of the BIM or CAD design system directly as an add-in, or a parallel running system with access to memory locations running in the BIM or CAD design system. Still further examples may derive from capturing design elements in displays of various kinds. Finally, such access to external file types may be used to verify models generated in the standard manners as have been described or add information such as annotations, descriptions, and other such aspects.

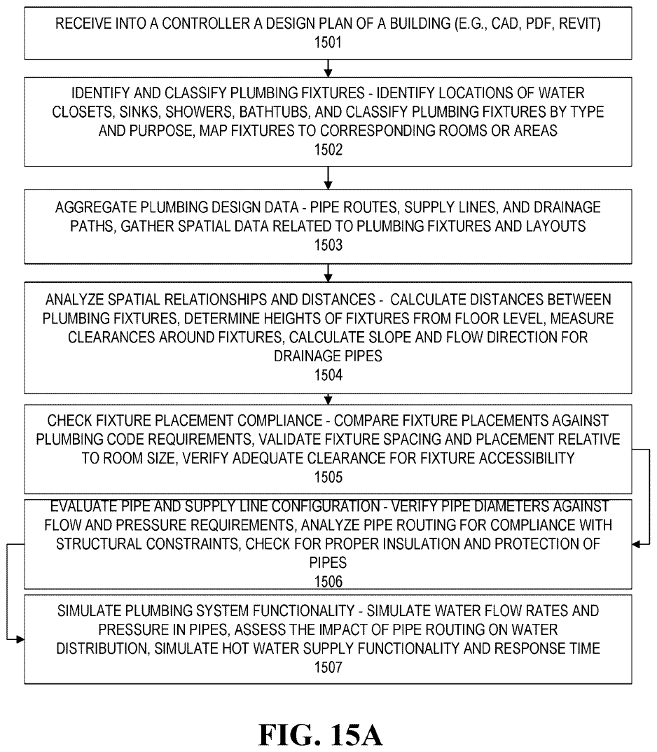

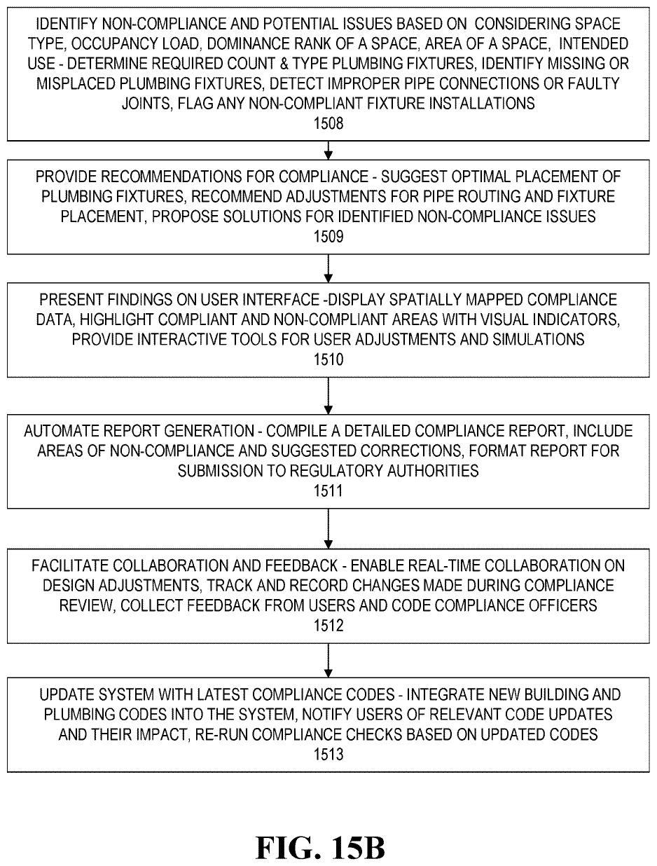

Referring now to FIGS. 15A-15B, these figures illustrate an exemplary flowchart that details the method steps for conducting a thorough plumbing compliance analysis using an AI-driven system. The method encompasses a wide range of activities, from the initial receipt of a design plan to the generation of compliance reports and the integration of updated building codes.

At step 1501, the process begins with the receipt of a design plan of a building into the controller. The design plan may be in various digital formats such as CAD, PDF, or Revit files. The design plan serves as the input for the AI engine's analysis, providing a detailed depiction of the building's layout, including the placement of plumbing fixtures and associated systems. For example, the design plan may include the layout of a large commercial kitchen, showing the locations of sinks, dishwashers, and drainage systems, which are critical for determining compliance with plumbing layouts.

In step 1502, the AI engine identifies and classifies the plumbing fixtures within the design plan. This may involve recognizing the locations of water closets, sinks, showers, bathtubs, and other fixtures, and classifying them by type and purpose. The AI engine maps these fixtures to their corresponding rooms or areas, creating a detailed inventory of the building's plumbing components. For example, the AI engine may identify all the toilets within a restroom and classify them according to their type, such as wall-mounted or floor-mounted, which is then used for determining the appropriate clearance and support structures.

Step 1503 involves aggregating the plumbing design data, which may include pipe routes, supply lines, and drainage paths. The AI engine gathers spatial data related to plumbing fixtures and layouts, so that all relevant information is consolidated for further analysis. For example, in a multi-story building, the AI engine may map out the vertical and horizontal routes of the water supply lines, to further determine that the pipes are correctly sized and routed to provide adequate pressure and flow to all fixtures.

At step 1504, the AI engine analyzes the spatial relationships and distances between the identified plumbing fixtures. This may include calculating the distances (e.g., using scale) between fixtures, calculating distances of fixtures from surrounding walls, determining their heights from the floor level, and measuring clearances around each fixture. The AI engine also calculates the slope and flow direction for drainage pipes, which is used for determining possibilities of blockages and efficiency of water flow. For example, the AI engine may verify that the slope of a drainage pipe in a commercial kitchen meets the minimum requirement to prevent water from pooling, which could lead to unsanitary conditions.

Step 1505 involves checking the fixture placement compliance against plumbing code requirements. The AI engine compares the placements of fixtures relative to the room size and verifies that there is adequate clearance for fixture accessibility. For example, in a public restroom, the AI may determine if there is sufficient space around each toilet to comply with ADA regulations, which require a minimum amount of clearance for wheelchair access. If the AI engine detects that a fixture is placed too close to a wall or another fixture, it flags this as non-compliant and suggests repositioning the fixture to achieve the necessary clearance.

In step 1506, the AI engine evaluates the pipe and supply line configuration. This includes verifying the diameters of pipes against flow and pressure requirements and analyzing the routing of pipes for compliance with structural constraints. The AI engine may also check for proper insulation and protection of pipes, so that they are not exposed to conditions that could lead to freezing or damage. For example, the AI engine may identify that a cold water supply pipe is routed too close to an exterior wall in a cold climate, which could result in freezing. The AI engine may then recommend relocating the pipe or adding insulation to prevent potential issues.

Step 1507 involves simulating the plumbing system's functionality. The AI engine simulates water flow rates and pressure in pipes, assessing the impact of pipe routing on water distribution. It also simulates the functionality and response time of the hot water supply, so that all fixtures receive hot water within an acceptable time frame. For example, in a large hotel, the AI engine may simulate the time it takes for hot water to reach the farthest shower from the water heater. If the response time is too long, the AI engine may suggest installing a recirculation pump to reduce the wait time for hot water.

At step 1508, the AI engine identifies non-compliance and potential issues by considering space type, occupancy load, space area, intended use of the building, and dominance rank of spaces. It determines the required count and type of plumbing fixtures, identifies missing or misplaced fixtures, detects improper pipe connections or faulty joints, and flags any non-compliant fixture installations. For example, the AI engine may detect that a restroom intended for a high-occupancy area lacks the required number of toilets and sinks, leading to non-compliance with local building codes. The AI engine may then recommend adding additional fixtures to meet the occupancy requirements.

Step 1509 focuses on providing recommendations for compliance. The AI engine suggests the optimal placement of plumbing fixtures, recommends adjustments for pipe routing and fixture placement, and proposes solutions for identified non-compliance issues. For example, if the AI identifies that a toilet is placed too close to a sink, it may recommend relocating the sink to provide the necessary clearance. The AI engine may also suggest rerouting a drainage pipe to improve the slope and prevent blockages.

At step 1510, the findings from the compliance analysis are presented on the interactive user interface. The AI engine displays spatially mapped compliance data, highlighting compliant and non-compliant areas with visual indicators. The user interface provides interactive tools for user adjustments and simulations, allowing users to explore different design scenarios and see the impact of changes on compliance. For example, users may be able to click on a non-compliant area and receive detailed information about the issue, along with suggested revisions to bring the area into compliance.

Step 1511 involves automating the report generation process. The AI engine compiles a detailed compliance report that includes areas of non-compliance and suggested corrections. This report may be formatted for submission to regulatory authorities, providing all the necessary documentation to demonstrate that the building's plumbing systems have been thoroughly reviewed and adjusted to meet code requirements. For example, the report may include a summary of the AI's findings, along with annotated diagrams showing where changes have been made to achieve compliance.

At step 1512, the system facilitates collaboration and feedback among users. The AI engine enables real-time collaboration on design adjustments, allowing multiple users to work together on the same project. The system tracks and records changes made during the compliance review, so that all modifications are documented. It also collects feedback from users and code compliance officers, providing a platform for continuous improvement of the design. For example, architects, engineers, and inspectors may collaborate on resolving a complex compliance issue, with the AI engine tracking their inputs and generating a final solution that meets all requirements.

Finally, step 1513 involves updating the system with the latest compliance codes. The AI engine integrates new building and plumbing codes into the system, notifying users of relevant code updates and their impact on existing designs. The system then re-runs compliance checks based on the updated codes, so that the design remains compliant with the latest standards. For example, if a new plumbing code is introduced that changes the required slope for drainage pipes, the AI engine may update its calculations and notify the user of any necessary adjustments to the design.

In some embodiments of the present invention, the AI engine may be configured to simulate projected occupancy scenarios based on the intended use of spaces within a design plan. Even before the building is constructed, the system can predict how different areas will be used during peak times, such as high traffic in commercial restrooms or communal areas in residential buildings. By analyzing these simulated scenarios, the AI engine can recommend adjustments to plumbing fixture placements to optimize flow and accessibility. For example, if the AI predicts that a restroom in a shopping mall will experience significant foot traffic during peak hours, it may suggest adding more fixtures or redistributing existing ones to avoid congestion. The system may also prioritize certain areas based on their projected importance and usage within the building, so that critical spaces are designed with optimal fixture placements and adherence to plumbing codes.

### Glossary

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Smoke” as used herein, means a concentration of an aerosol including airborne particulates and gases resulting from a material undergoing combustion or pyrolysis, combined with a quantity of air that is drawn along with the airborne particulates and gases.

“Vector File” as used herein a vector file is a computer graphic that uses mathematical formulas to render its image. In some embodiments, a sharpness of a vector file will be agnostic to size within a range of sizes viewable on smart device and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The methods and apparatus of the present invention are presented herein generally, by way of example, to actions, processes, and deliverables important to industries such as the construction industry, by generating improved determination of compliance with specified codes, based on inputted design plans, floor plans or other construction related diagrams, however, design plans may include almost any artifact that may be converted to a pixel pattern.

Some specific embodiments of the present invention include input of a design plan (e.g., a blueprint, design plan floorplan or other two-dimensional artifact) so that it may be analyzed using artificial intelligence and used to generate a determination of compliance with specified conditions included in one or multiple building codes in a short time period. However, unless expressly indicated in an associated claim, the present invention is not limited to analysis of design plans for any particular industry. The examples provided herein are illustrative in nature and show that the present invention may use controllers and/or neural networks and artificial-intelligence (AI) techniques to identify aspects of a building described by a design plan and specify quantities for variables used to generate a bid or other proposal for completion of a project (or some subset of a project) represented by the design plan. For example, aspects of a building that are identified may include one or more of: walls or other boundaries; doorways; doors; plumbing; plumbing fixtures; hardware; fasteners; wall board; flooring; a level of complexity and other variables ascertainable via analysis of the design plan. AI analysis provides values for variables used in estimations involved in a project bidding process or related activity.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### CONCLUSION

A number of embodiments of the present disclosure have been described. While this specification contains many specific implementation details, there should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood the drawings and the detailed description thereto are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

What is claimed is:

1.-30. (canceled)

31) An apparatus for automated analysis of plumbing code compliance in a building design, comprising:
a controller configured to receive a design plan of at least a portion of a building;
an artificial intelligence (AI) engine operatively coupled to the controller and configured to analyze the design plan to identify plumbing fixtures, wherein the plumbing fixtures include at least one of a water closet, a sink, a shower, a urinal, and a piping layout;
a memory storing a plurality of building codes and associated compliance conditions; and
an interactive user interface generated by the controller, the interactive user interface configured to display the design plan as a plurality of dynamic components, each dynamic component having at least one parameter changeable via the interactive user interface,
wherein the AI engine is further configured to determine, for each identified plumbing fixture, a type, quantity, and spatial relationship, and to compare the identified plumbing fixtures and their spatial relationships to the associated compliance conditions stored in the memory,
and wherein the interactive user interface is further configured to indicate, in real time, whether the design plan is in compliance with the plurality of building codes.

32) The apparatus of claim 31, wherein the controller is further configured to convert the design plan into a raster image format prior to analysis by the AI engine.

33) The apparatus of claim 31, wherein the AI engine is further configured to calculate, for each plumbing fixture, at least one of: a distance to a side wall, a height from a floor level, a clearance around the plumbing fixture, or a slope of an associated drainage pipe.

34) The apparatus of claim 31, wherein the interactive user interface is further configured to provide visual alerts or color-coded indicators to signify the compliance or non-compliance with the building codes.

35) The apparatus of claim 31, wherein the AI engine is further configured to generate automated suggestions for design modifications to address any identified non-compliance, and the interactive user interface is configured to present the suggestions to a user.

36) The apparatus of claim 31, wherein the controller is further configured to receive user input specifying a proposed use for the portion of the building, and the AI engine is configured to select a set of compliance conditions based on the proposed use.

37) The apparatus of claim 31, wherein the memory further stores a plurality of code tables specifying minimum and maximum numbers of plumbing fixtures required for different building uses and occupancies, and the AI engine is configured to cross-reference the identified plumbing fixtures with the plurality of code tables.

38) The apparatus of claim 31, wherein the interactive user interface is further configured to allow a user to modify at least one of: a location, type, height, or dimension of a plumbing fixture, and to display an updated compliance status in response to the design modification.

39) The apparatus of claim 31, wherein the AI engine is further configured to identify and analyze piping layouts, including water supply and drainage pipes, and to determine compliance with code requirements for pipe sizing, routing, and connections.

40) The apparatus of claim 31, wherein the AI engine is further configured to determine an occupancy load for the portion of the building based on the design plan, and to analyze plumbing compliance based on the determined occupancy load.

41) The apparatus of claim 31, wherein the AI engine is further configured to determine dominance ranks for spaces within the portion of the building, and to prioritize compliance analysis for spaces with higher dominance ranks.

42) The apparatus of claim 31, wherein the AI engine is further configured to analyze compliance of plumbing fixtures related to accessibility requirements, including compliance with an Americans with Disabilities Act (ADA).

43) The apparatus of claim 31, wherein the controller is further configured to receive as input a code selection corresponding to a geographic locality, and the AI engine is configured to apply compliance conditions specific to the selected geographic locality.

44) The apparatus of claim 31, wherein the interactive user interface is further configured to display, for each non-compliant area, a textual explanation of the non-compliance and a graphical highlight of an affected portion of the design plan.

45) The apparatus of claim 31, wherein the AI engine is further configured to process two-dimensional references using machine learning techniques to identify discernable components, including dimensions and placement of the plumbing fixtures, and to assign size descriptors to the identified discernable components.

46) The apparatus of claim 31, wherein the controller is further configured to generate and store a record of compliance determinations and user modifications, thereby providing an auditable trail of a compliance analysis process.

47) The apparatus of claim 31, wherein the AI engine is further configured to analyze the compliance of plumbing systems including water heaters and sprinkler systems, and to determine whether piping connections and fixture counts meet safety and efficiency standards.

48) The apparatus of claim 31, wherein the interactive user interface is further configured to allow a user to select a specific area of the design plan for detailed compliance analysis, and to display compliance results specific to the selected specific area.

49) The apparatus of claim 31, wherein the AI engine is further configured to learn from user modifications and past compliance analyses to improve accuracy and efficiency of future compliance determinations.

50) The apparatus of claim 31, wherein the controller is further configured to output a compliance report including a visual representation of the design plan, highlighted areas of compliance and non-compliance, and a list of recommended corrective actions, the compliance report being exportable in a digital format.
